(19) United States
(12) Patent Application Publication
(10) Pub. No.: US 2020/0099000 A1
(43) Pub. Date: Mar. 26, 2020

(54) ORGANIC LUMINESCENT MATERIALS CONTAINING NOVEL ANCILLARY LIGANDS

(71) Applicant: BEIJING SUMMER SPROUT TECHNOLOGY CO., LTD., Beijing (CN)

(72) Inventors: Qi Zhang, Beijing (CN); Zhihong Dai, Beijing (CN); Chi Yuen Raymond Kwong, Beijing (CN); Chuanjun Xia, Beijing (CN)

(21) Appl. No.: 16/576,384

(22) Filed: Sep. 19, 2019

(30) Foreign Application Priority Data
Sep. 20, 2018 (CN) 201811100096.3

(51) Int. Cl. H01L 51/00; C07F 15/00; C09K 11/06

(52) U.S. Cl. CPC H01L 51/0085; H01L 51/5012; C09K 11/06; C07F 15/0033

(57) ABSTRACT

Organic luminescent materials containing novel ancillary ligands are disclosed, and they are achieved by providing metal complexes which comprise a new series of acetylacetone-type ancillary ligands. The metal complexes which contain new ancillary ligands can be used as emitters in the emissive layer of an organic electroluminescent device. These novel ligands are effective in changing the sublimation properties, improving quantum efficiency and improving device performance. An electroluminescent device and a formulation are also disclosed.

This application claims the benefit of Chinese Application No. 201811100096.3, filed Sep. 20, 2018, the entire content of which is incorporated herein by reference.

### 1 FIELD OF THE INVENTION

The present invention relates to compounds for organic electronic devices, such as organic light emitting devices. More specifically, the present invention relates to a metal complex comprising novel ancillary ligands, an electroluminescent device and a formulation comprising the metal complex.

### 2 BACKGROUND ART

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This invention laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since OLED is a self-emitting solid state device, it offers tremendous potential for display and lighting applications. In addition, the inherent properties of organic materials, such as their flexibility, may make them well suited for particular applications such as fabrication on flexible substrates.

OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of a fluorescent OLED is only 25%. This limitation hindered the commercialization of OLED. In 1997, Forrest and Thompson reported phosphorescent OLED, which uses triplet emission from heave metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. Small molecule refers to any organic or organometallic material that is not a polymer. The molecular weight of a small molecule can be large as long as it has well defined structure. Dendrimers with well-defined structures are considered as small molecules. Polymer OLEDs include conjugated polymers and non-conjugated polymers with pendant emitting groups. Small molecule OLED can become a polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of an OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Auxiliary ligand for phosphorescent materials can be used to fine tune the wavelength of the light, improve the sublimation properties and enhance material efficiency. Existing ancillary ligands such as acetylacetonate type ligands, especially the acetylacetonate type ligands containing a branched alkyl branch, have achieved some effects in controlling the properties as described above, but their performance needs to be further improved to meet increasing performance demands, especially providing a more efficient mean of controlling the wavelength of the illumination and increasing the quantum efficiency of the material. The present invention provides a novel structure of an ancillary ligand which is more effective in improving sublimation properties and quantum efficiency than the ancillary ligands already reported.

### 3 SUMMARY OF THE INVENTION

The present invention aims to provide a series of new acetylacetonate type ancillary ligand to solve at least part of above problems. By combining these ligands to a metal complex, the metal complex can be used as an emitter in the emissive layer of a electroluminescent device. The use of these novel ligands enables to alter sublimation characteristics, enhance quantum efficiency, and improve device performance.

According to an embodiment of the present invention, a metal complex comprising the ligand Lₐ represented by Formula 1 is disclosed:

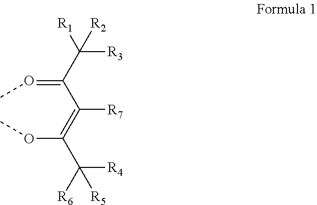

Wherein R₁ to R₇ are each independently selected from the group consisting of hydrogen, deuterium, halogen, a substituted or unsubstituted alkyl group having 1 to 20 carbon atoms, a substituted or unsubstituted cycloalkyl group having 3 to 20 ring carbon atoms, a substituted or unsubstituted heteroalkyl group having 1 to 20 carbon atoms, a substituted or unsubstituted arylalkyl group having 7 to 30 carbon atoms, a substituted or unsubstituted alkoxy group having 1 to 20 carbon atoms, a substituted or unsubstituted aryloxy group having 6 to 30 carbon atoms, a substituted or unsubstituted alkenyl group having 2 to 20 carbon atoms, a substituted or unsubstituted aryl group having 6 to 30 carbon atoms, a substituted or unsubstituted heteroaryl group having 3 to 30 carbon atoms, a substituted or unsubstituted alkylsilyl group having 3 to 20 carbon atoms, a substituted or unsubstituted arylsilyl group having 6 to 20 carbon atoms, a substituted or unsubstituted amino group having 0 to 20 carbon atoms, an acyl group, a carbonyl group, a carboxylic acid group, an ester group, a nitrile group, an isonitrile group, a thiol group, a sulfinyl group, a sulfonyl group, a phosphino group, and combinations thereof;

Two adjacent substituents can be optionally joined to form a ring or fused structure;

Wherein between the group consisting of R₁, R₂, R₃ and the group consisting of R₄, R₅, R₆, at least one group is three identical or different substituents,

Wherein the three identical or different substituents all contain at least one carbon atom,

Wherein at least one of the three identical or different substituents contains at least two carbon atoms.

According to another embodiment of the present invention, an electroluminescent device is also disclosed, which comprises an anode, a cathode, and an organic layer disposed between the anode and the cathode, the organic layer comprises a metal complex comprising the ligand Lₐ represented by Formula 1:

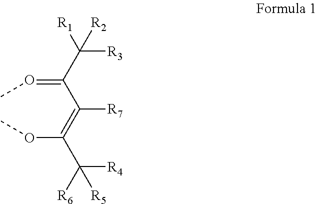

Wherein R₁ to R₇ are each independently selected from the group consisting of hydrogen, deuterium, halogen, a substituted or unsubstituted alkyl group having 1 to 20 carbon atoms, a substituted or unsubstituted cycloalkyl group having 3 to 20 ring carbon atoms, a substituted or unsubstituted heteroalkyl group having 1 to 20 carbon atoms, a substituted or unsubstituted arylalkyl group having 7 to 30 carbon atoms, a substituted or unsubstituted alkoxy group having 1 to 20 carbon atoms, a substituted or unsubstituted aryloxy group having 6 to 30 carbon atoms, a substituted or unsubstituted alkenyl group having 2 to 20 carbon atoms, a substituted or unsubstituted aryl group having 6 to 30 carbon atoms, a substituted or unsubstituted heteroaryl group having 3 to 30 carbon atoms, a substituted or unsubstituted alkylsilyl group having 3 to 20 carbon atoms, a substituted or unsubstituted arylsilyl group having 6 to 20 carbon atoms, a substituted or unsubstituted amino group having 0 to 20 carbon atoms, an acyl group, a carbonyl group, a carboxylic acid group, an ester group, a nitrile group, an isonitrile group, a thiol group, a sulfinyl group, a sulfonyl group, a phosphino group, and combinations thereof;

Two adjacent substituents can be optionally joined to form a ring or fused structure;

Wherein between the group consisting of R₁, R₂, R₃ and the group consisting of R₄, R₅, R₆, at least one group is three identical or different substituents,

Wherein the three identical or different substituents all contain at least one carbon atom,

Wherein at least one of the three identical or different substituents contains at least two carbon atoms.

According to another embodiment of the present invention, a formulation comprising the metal complex comprising the ligand Lₐ represented by Formula 1 is also disclosed.

The metal complex comprising novel ancillary ligands disclosed in the present invention can be used as an emitter in the emissive layer of an organic electroluminescent device. These novel ligands can alter the sublimation properties of luminescent materials, improve quantum efficiency and device performance.

### 4 BRIEF DESCRIPTION OF THE DRAWINGS

FIG. 1 schematically shows an organic light emitting device that can incorporate the metal complex or formulation disclosed herein.

FIG. 2 schematically shows another organic light emitting device that can incorporate the metal complex or formulation disclosed herein.

FIG. 3 shows the Formula 1 of ligand Lₐ disclosed herein.

### 5 DETAILED DESCRIPTION

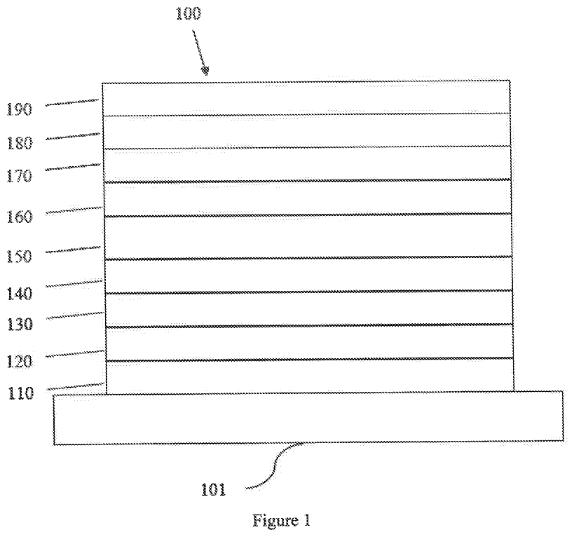

OLEDs can be fabricated on various types of substrates such as glass, plastic, and metal foil. FIG. 1 schematically shows the organic light emitting device 100 without limitation. The figures are not necessarily drawn to scale. Some of the layer in the figure can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, which are incorporated by reference in its entirety.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

The layered structure described above is provided by way of non-limiting example. Functional OLEDs may be achieved by combining the various layers described in different ways, or layers may be omitted entirely, such as an electron blocking layer. It may also include other layers not specifically described. Within each layer, a single material or a mixture of multiple materials can be used to achieve optimum performance. Any functional layer may include several sublayers. For example, the emissive layer may have a two layers of different emitting materials to achieve desired emission spectrum.

In one embodiment, an OLED may be described as having an “organic layer” disposed between a cathode and an anode. This organic layer may comprise a single layer or multiple layers.

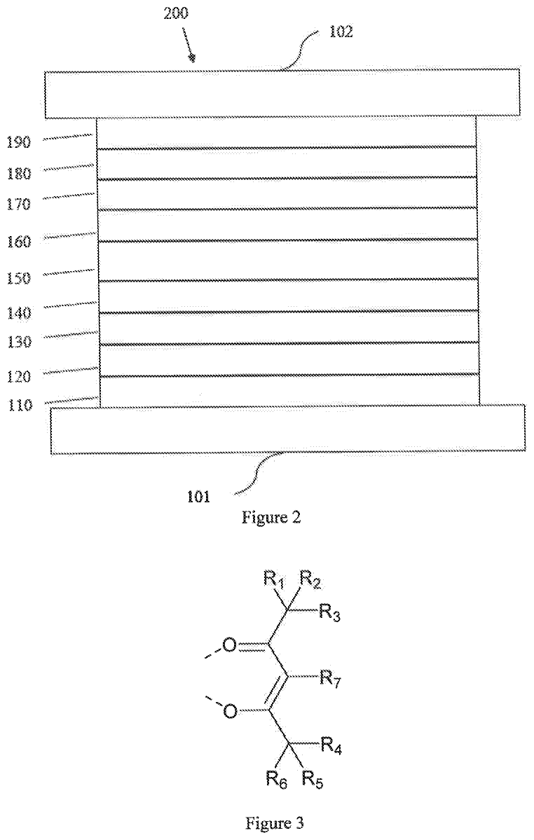

An OLED can be encapsulated by a barrier layer. FIG. 2 schematically shows the organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass and organic-inorganic hybrid layers. The barrier layer should be placed directly or indirectly outside of the OLED device. Multilayer thin film encapsulation was described in U.S. Pat. No. 7,968,146, which is herein incorporated by reference in its entirety.

Devices fabricated in accordance with embodiments of the invention can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small ΔE_{S-T}. These states may involve CT states. Often, donor-acceptor luminescent materials are constructed by connecting an electron donor moiety such as amino- or carbazole-derivatives and an electron acceptor moiety such as N-containing six-membered aromatic rings.

### Definition of Terms of Substituents

halogen or halide—as used herein includes fluorine, chlorine, bromine, and iodine.

Alkyl—contemplates both straight and branched chain alkyl groups. Examples of the alkyl group include methyl group, ethyl group, propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neopentyl group, 1-methylpentyl group, 2-methylpentyl group, 1-pentylhexyl group, 1-butylpentyl group, 1-heptyloctyl group, 3-methylpentyl group. Additionally, the alkyl group may be optionally substituted. The carbons in the alkyl chain can be replaced by other hetero atoms. Of the above, preferred are methyl group, ethyl group, propyl group, isopropyl group, n-butyl group, s-butyl group, isobutyl group, t-butyl group, n-pentyl group, and neopentyl group.

Cycloalkyl—as used herein contemplates cyclic alkyl groups. Preferred cycloalkyl groups are those containing 4 to 10 ring carbon atoms and includes cyclobutyl, cyclopentyl, cyclohexyl, 4-methylcyclohexyl, 4,4-dimethylcylcohexyl, 1-adamantyl, 2-adamantyl, 1-norbornyl, 2-norbornyl and the like. Additionally, the cycloalkyl group may be optionally substituted. The carbons in the ring can be replaced by other hetero atoms.

Alkenyl—as used herein contemplates both straight and branched chain alkene groups. Preferred alkenyl groups are those containing two to fifteen carbon atoms. Examples of the alkenyl group include vinyl group, allyl group, 1-butenyl group, 2-butenyl group, 3-butenyl group, 1,3-butandienyl group, 1-methylvinyl group, styryl group, 2,2-diphenylvinyl group, 1,2-diphenylvinyl group, 1-methylallyl group, 1,1-dimethylallyl group, 2-methylallyl group, 1-phenylallyl group, 2-phenylallyl group, 3-phenylallyl group, 3,3-diphenylallyl group, 1,2-dimethylallyl group, 1-phenyll-butenyl group, and 3-phenyl-1-butenyl group. Additionally, the alkenyl group may be optionally substituted.

Alkynyl—as used herein contemplates both straight and branched chain alkyne groups. Preferred alkynyl groups are those containing two to fifteen carbon atoms. Additionally, the alkynyl group may be optionally substituted.

Aryl or aromatic group—as used herein contemplates noncondensed and condensed systems. Preferred aryl groups are those containing six to sixty carbon atoms, preferably six to twenty carbon atoms, more preferably six to twelve carbon atoms. Examples of the aryl group include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Additionally, the aryl group may be optionally substituted. Examples of the non-condensed aryl group include phenyl group, biphenyl-2-yl group, biphenyl-3-yl group, biphenyl-4-yl group, p-terphenyl-4-yl group, p-terphenyl-3-yl group, p-terphenyl-2-yl group, m-terphenyl-4-yl group, m-terphenyl-3-yl group, m-terphenyl-2-yl group, o-tolyl group, m-tolyl group, p-tolyl group, p-t-butylphenyl group, p-(2-phenylpropyl)phenyl group, 4′-methylbiphenylyl group, 4″-t-butyl p-terphenyl-4-yl group, o-cumenyl group, m-cumenyl group, p-cumenyl group, 2,3-xylyl group, 3,4-xylyl group, 2,5-xylyl group, mesityl group, and m-quarterphenyl group.

Heterocyclic group or heterocycle—as used herein contemplates aromatic and non-aromatic cyclic groups. Hetero-aromatic also means heteroaryl. Preferred non-aromatic heterocyclic groups are those containing 3 to 7 ring atoms which includes at least one hetero atom such as nitrogen, oxygen, and sulfur. The heterocyclic group can also be an aromatic heterocyclic group having at least one heteroatom selected from nitrogen atom, oxygen atom, sulfur atom, and selenium atom.

Heteroaryl—as used herein contemplates noncondensed and condensed hetero-aromatic groups that may include from one to five heteroatoms. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—it is represented by —O-Alkyl. Examples and preferred examples thereof are the same as those described above. Examples of the alkoxy group having 1 to 20 carbon atoms, preferably 1 to 6 carbon atoms include methoxy group, ethoxy group, propoxy group, butoxy group, pentyloxy group, and hexyloxy group. The alkoxy group having 3 or more carbon atoms may be linear, cyclic or branched.

Aryloxy—it is represented by —O-Aryl or —O-heteroaryl. Examples and preferred examples thereof are the same as those described above. Examples of the aryloxy group having 6 to 40 carbon atoms include phenoxy group and biphenyloxy group.

Arylalkyl—as used herein contemplates an alkyl group that has an aryl substituent. Additionally, the arylalkyl group may be optionally substituted. Examples of the arylalkyl group include benzyl group, 1-phenylethyl group, 2-phenylethyl group, 1-phenylisopropyl group, 2-phenylisopropyl group, phenyl-t-butyl group, alpha.-naphthylmethyl group, 1-alpha.-naphthylethyl group, 2-alpha-naphthylethyl group, 1-alpha-naphthylisopropyl group, 2-alpha-naphthylisopropyl group, beta-naphthylmethyl group, 1-beta-naphthylethyl group, 2-beta-naphthylethyl group, 1-beta-naphthylisopropyl group, 2-beta-naphthylisopropyl group, p-methylbenzyl group, m-methylbenzyl group, o-methylbenzyl group, p-chlorobenzyl group, m-chlorobenzyl group, o-chlorobenzyl group, p-bromobenzyl group, m-bromobenzyl group, o-bromobenzyl group, p-iodobenzyl group, m-iodobenzyl group, o-iodobenzyl group, p-hydroxybenzyl group, m-hydroxybenzyl group, o-hydroxybenzyl group, p-aminobenzyl group, m-aminobenzyl group, o-aminobenzyl group, p-nitrobenzyl group, m-nitrobenzyl group, o-nitrobenzyl group, p-cyanobenzyl group, m-cyanobenzyl group, o-cyanobenzyl group, 1-hydroxy-2-phenylisopropyl group, and 1-chloro2-phenylisopropyl group. Of the above, preferred are benzyl group, p-cyanobenzyl group, m-cyanobenzyl group, o-cyanobenzyl group, 1-phenylethyl group, 2-phenylethyl group, 1-phenylisopropyl group, and 2-phenylisopropyl group.

The term “aza” in azadibenzofuran, aza-dibenzothiophene, etc. means that one or more of the C—H groups in the respective aromatic fragment are replaced by a nitrogen atom. For example, azatriphenylene encompasses dibenzo[f,h]quinoxaline,dibenzo[f,h]quinoline and other analogues with two or more nitrogens in the ring system. One of ordinary skill in the art can readily envision other nitrogen analogs of the aza-derivatives described above, and all such analogs are intended to be encompassed by the terms as set forth herein.

The alkyl, cycloalkyl, alkenyl, alkynyl, aralkyl, heterocyclic group, aryl, and heteroaryl may be unsubstituted or may be substituted with one or more substituents selected from the group consisting of deuterium, halogen, alkyl, cycloalkyl, arylalkyl, alkoxy, aryloxy, amino, cyclic amino, silyl, alkenyl, cycloalkenyl, heteroalkenyl, alkynyl, aryl, heteroaryl, an acyl group, a carbonyl group, a carboxylic acid group, an ether group, an ester group, a nitrile group, an isonitrile group, a thioalkyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In the compounds mentioned in this disclosure, the hydrogen atoms can be partially or fully replaced by deuterium. Other atoms such as carbon and nitrogen, can also be replaced by their other stable isotopes. The replacement by other stable isotopes in the compounds may be preferred due to its enhancements of device efficiency and stability.

In the compounds mentioned in this disclosure, multiple substitutions refer to a range that includes a double substitution, up to the maximum available substitutions. When a substitution in the compounds mentioned in this disclosure represents multiple substitutions (including di, tri, tetra substitutions etc.), that means the substituent can exist at a plurality of available substitution positions on its linking structure, the substituents present at a plurality of available substitution positions can be the same structure or different structures.

In the compounds mentioned in this disclosure, the expression that two adjacent substituents can be optionally joined to form a ring is intended to be taken to mean that two radicals are linked to each other by a chemical bond. This is illustrated by the following scheme:

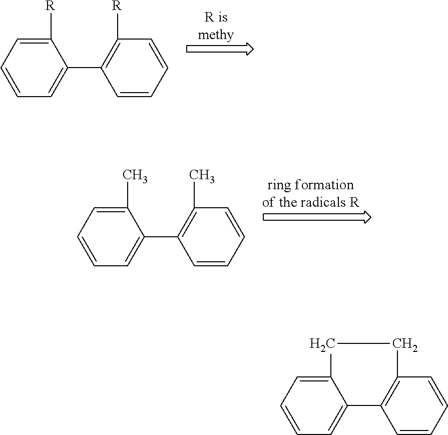

Furthermore, the expression that two adjacent substituents can be optionally joined to form a ring is also intended to be taken to mean that in the case where one of the two radicals represents hydrogen, the second radical is bonded at a position to which the hydrogen atom was bonded, with formation of a ring. This is illustrated by the following scheme:

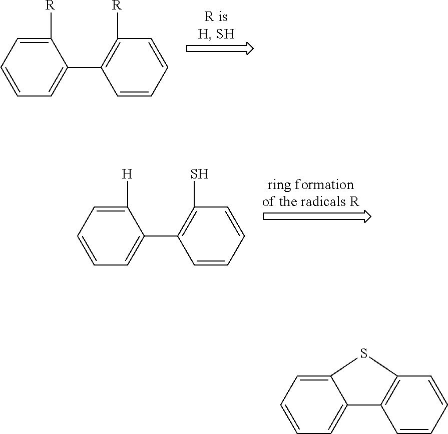

According to an embodiment of the present invention, wherein the metal complex comprising the ligand Lₐ represented by Formula 1 is disclosed:

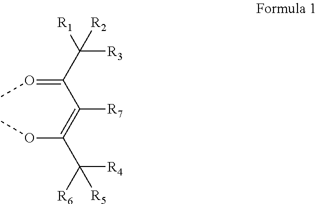

Wherein R₁ to R₇ are each independently selected from the group consisting of hydrogen, deuterium, halogen, a substituted or unsubstituted alkyl group having 1 to 20 carbon atoms, a substituted or unsubstituted cycloalkyl group having 3 to 20 ring carbon atoms, a substituted or unsubstituted heteroalkyl group having 1 to 20 carbon atoms, a substituted or unsubstituted arylalkyl group having 7 to 30 carbon atoms, a substituted or unsubstituted alkoxy group having 1 to 20 carbon atoms, a substituted or unsubstituted aryloxy group having 6 to 30 carbon atoms, a substituted or unsubstituted alkenyl group having 2 to 20 carbon atoms, a substituted or unsubstituted aryl group having 6 to 30 carbon atoms, a substituted or unsubstituted heteroaryl group having 3 to 30 carbon atoms, a substituted or unsubstituted alkylsilyl group having 3 to 20 carbon atoms, a substituted or unsubstituted arylsilyl group having 6 to 20 carbon atoms, a substituted or unsubstituted amino group having 0 to 20 carbon atoms, an acyl group, a carbonyl group, a carboxylic acid group, an ester group, a nitrile group, an isonitrile group, a thiol group, a sulfinyl group, a sulfonyl group, a phosphino group, and combinations thereof;

Two adjacent substituents can be optionally joined to form a ring or fused structure;

Wherein between the group consisting of R₁, R₂, R₃ and the group consisting of R₄, R₅, R₆, at least one group is three identical or different substituents;

Wherein the three identical or different substituents all contain at least one carbon atom;

Wherein at least one of the three identical or different substituents contains at least two carbon atoms.

In this embodiment, the expression that two adjacent substituents can be optionally joined to form a ring, it is intended to be meant that in the formula 1, two adjacent substituents may be optionally linked to each other by a chemical bond, for example, between the substituents R₁ and R₂, between the substituents R₁ and R₃, between the substituents R₂ and R₃, between the substituents R₄ and R₅, between the substituents R₄ and R₆, or between the substituents R₅ and R₆. It should be noted that this expression does not include the case where three adjacent substituents are joined to form a ring, such as between the substituents R₁, R₂ and R₃, or between the substituents R₄, R₅ and R₆. This expression also does not include the case where anyone of the substituents R₁ to R₆ is bonded to the substituent R₁ to form a ring. In some cases, the ring formed by the connection in the expression does not include a bridge ring. Furthermore, it will be apparent to those skilled in the art that the substituents R₁ to R₇ in Formula 1 can all not joined either.

In this embodiment, R₁, R₂, R₃ form group A, R₄, R₅, R₆ form group B, the three substituents of at least one of the groups A and B may be the same or different. Note that the three substituents herein are different containing the case where only two of the substituents are the same. As for group A and group B, at least one group meets the following conditions: the three substituents in the group, whether the same or different, all contain at least one carbon atom, and at least one of the three substituents contains at least two carbon atoms.

According to another embodiment of the present invention, wherein the metal of the metal complex is selected from the group consisting of copper (Cu), silver (Ag), gold (Au), ruthenium (Ru), rhodium (Rh), palladium (Pd), platinum (Pt), osmium (Os), and iridium (Ir).

According to another embodiment of the present invention, wherein the metal of the metal complex is selected from platinum (Pt) and iridium (Ir).

According to another embodiment of the present invention, wherein R₁ to R₇ in formula 1 are each independently selected from the group consisting of hydrogen, deuterium, fluorine, a substituted or unsubstituted alkyl group having 1 to 20 carbon atoms, a substituted or unsubstituted cycloalkyl group having 3 to 20 ring carbon atoms, a substituted or unsubstituted heteroalkyl group having 1 to 20 carbon atoms, and combinations thereof.

According to another embodiment of the present invention, wherein R₁ to R₇ in formula 1 are each independently selected from the group consisting of hydrogen, methyl, ethyl, isopropyl, isobutyl, neopentyl, cyclobutyl, cyclopentyl, cyclohexyl, 4,4-Dimethylcyclohexyl, norbornyl, adamantyl, fluorine, trifluoromethyl, 2,2,2-trifluoroethyl, 3,3,3-trifluoropropyl, 3,3,3-trifluoro-2,2-dimethylpropyl, and deuterated material of the each above groups.

According to another embodiment of the present invention, wherein the metal complex has the general formula of M(Lₐ)ₘ(L_{b})ₙ(L_{c})_{q}, wherein L_{b} is a second ligand and L_{c} is a third ligand coordinated to M, and L_{b} and L_{c} may be the same or different;

Lₐ, L_{b} and L_{c} can be optionally joined to form a multidentate ligand;

Wherein m is 1, 2, or 3, n is 0, 1, or 2, q is 0, 1, or 2, m+n+q is equal to the oxidation state of M;

Wherein L_{b} and L_{c} independently selected from the group consisting of:

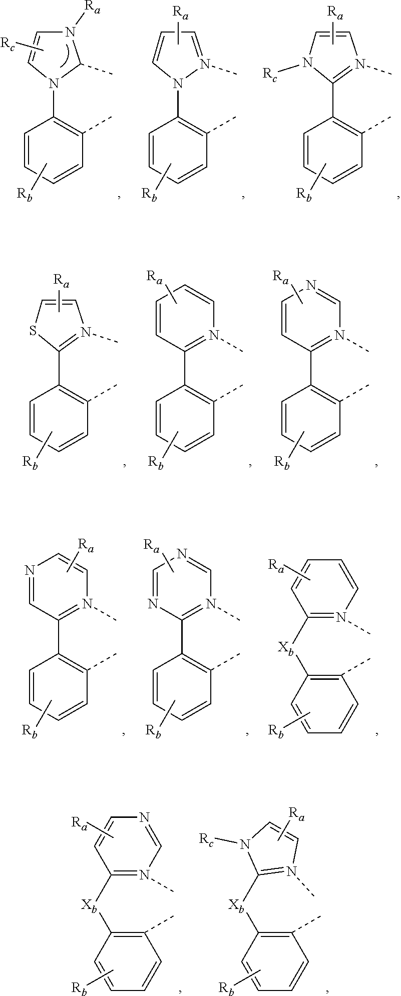

Wherein

Rₐ, R_{b}, and R_{c} can represent mono, di, tri, or tetra substitution or no substitution;

X_{b} can optionally selected from the group consisting of O, S, Se, NR_{N1}, CR_{C1}R_{C2};

Rₐ, R_{b}, R_{c}, R_{N1}, R_{C1} and R_{C2} are each independently selected from the group consisting of hydrogen, deuterium, halogen, a substituted or unsubstituted alkyl group having 1 to 20 carbon atoms, a substituted or unsubstituted cycloalkyl group having 3 to 20 ring carbon atoms, a substituted or unsubstituted heteroalkyl group having 1 to 20 carbon atoms, a substituted or unsubstituted arylalkyl group having 7 to 30 carbon atoms, a substituted or unsubstituted alkoxy group having 1 to 20 carbon atoms, a substituted or unsubstituted aryloxy group having 6 to 30 carbon atoms, a substituted or unsubstituted alkenyl group having 2 to 20 carbon atoms, a substituted or unsubstituted aryl group having 6 to 30 carbon atoms, a substituted or unsubstituted heteroaryl group having 3 to 30 carbon atoms, a substituted or unsubstituted alkylsilyl group having 3 to 20 carbon atoms, a substituted or unsubstituted arylsilyl group having 6 to 20 carbon atoms, a substituted or unsubstituted amino group having 0 to 20 carbon atoms, an acyl group, a carbonyl group, a carboxylic acid group, an ester group, a nitrile group, an isonitrile group, a thiol group, a sulfinyl group, a sulfonyl group, a phosphino group, and combinations thereof;

Two adjacent substituents can be optionally joined to form a ring.

In this embodiment, Lₐ, L_{b} and L_{c} can be optionally joined to form a multidentate ligand, such as a tetradentate ligand. It will be apparent to those skilled in the art that Lₐ, L_{b} and L_{c} also can not be joined to form a multidentate ligand.

In this embodiment, the case where two adjacent substituents in the structures shown by the ligands L_{b} and L are optionally joined to form a ring can include any of the followings: in one case, between the different numbered substituents such as Rₐ, R_{b}, R_{c}, R_{N1}, R_{C1} and R_{C2}, two adjacent substituents can be optionally joined to form a ring; in another case, when Rₐ, R_{b}, and R_{c} represent di, tri, or tetra substitution, between a plurality of identically numbered substituents present in Rₐ, R_{b}, and R_{c}, two adjacent substituents can be optionally joined to form a ring. In another case, substituents in the structures shown by the ligands L_{b} and L_{c} can all not joined either.

According to another embodiment of the present invention, wherein the metal complex has the formula of Ir(Lₐ)(L_{b})₂.

According to another embodiment of the present invention, wherein the ligand Lₐ is selected from the group consisting of:

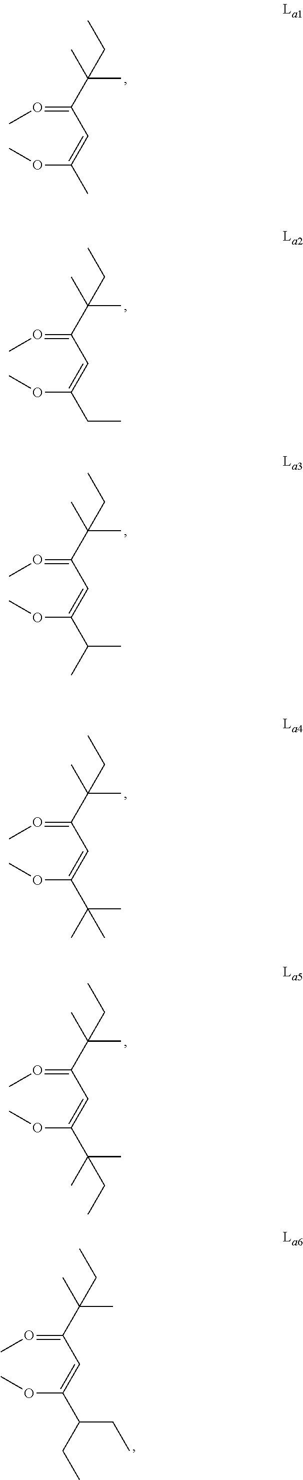

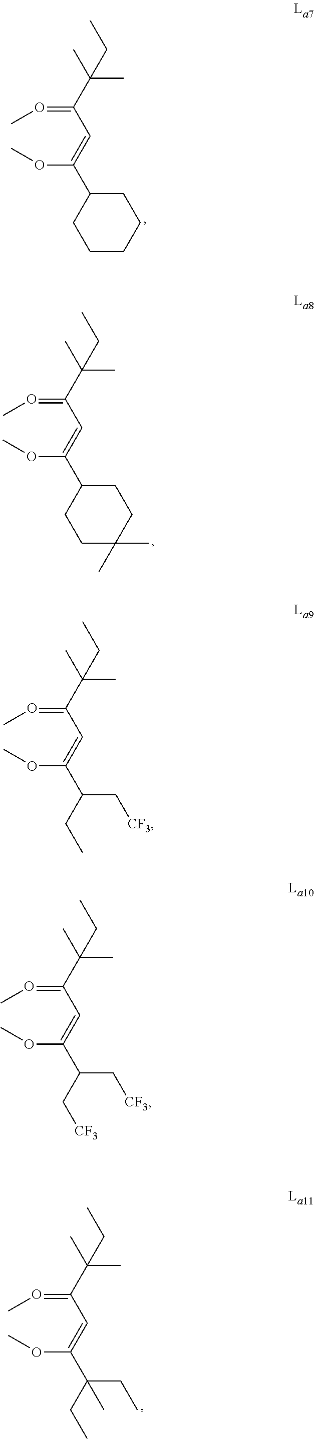

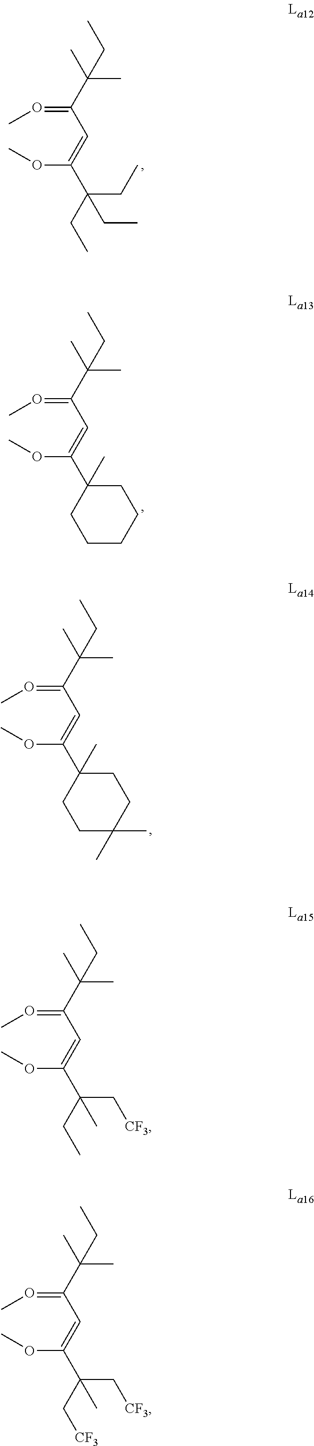

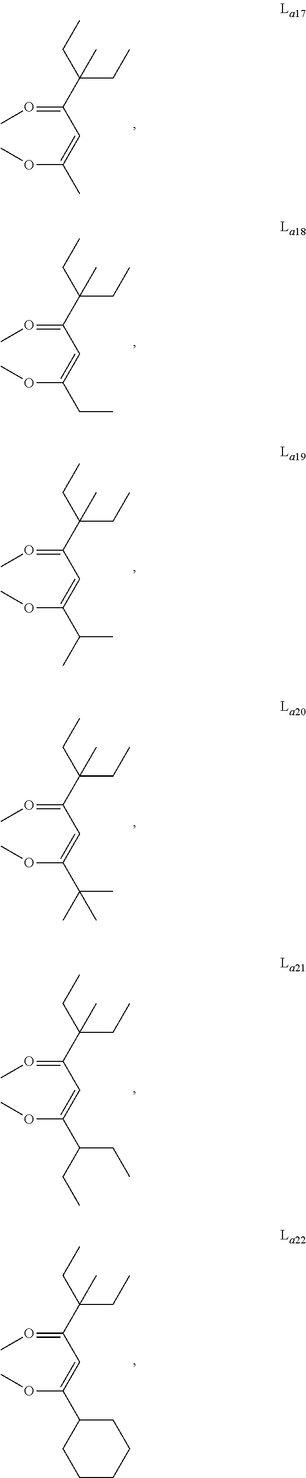

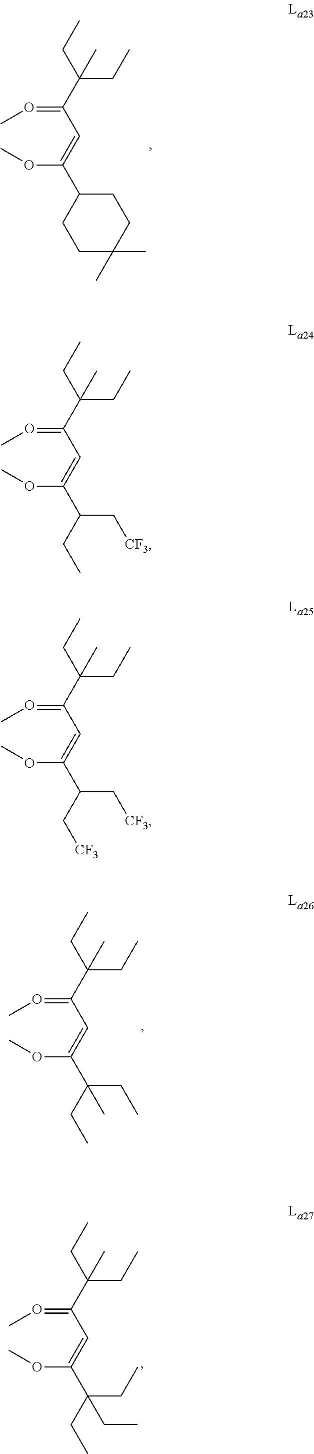

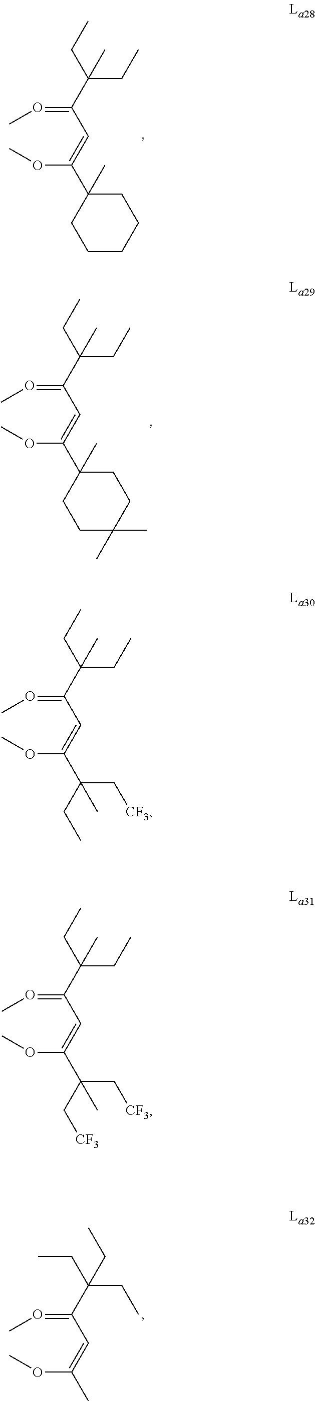

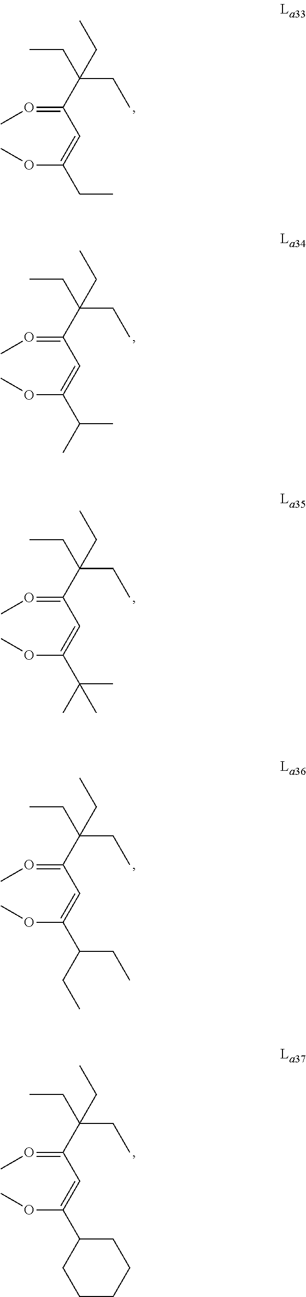

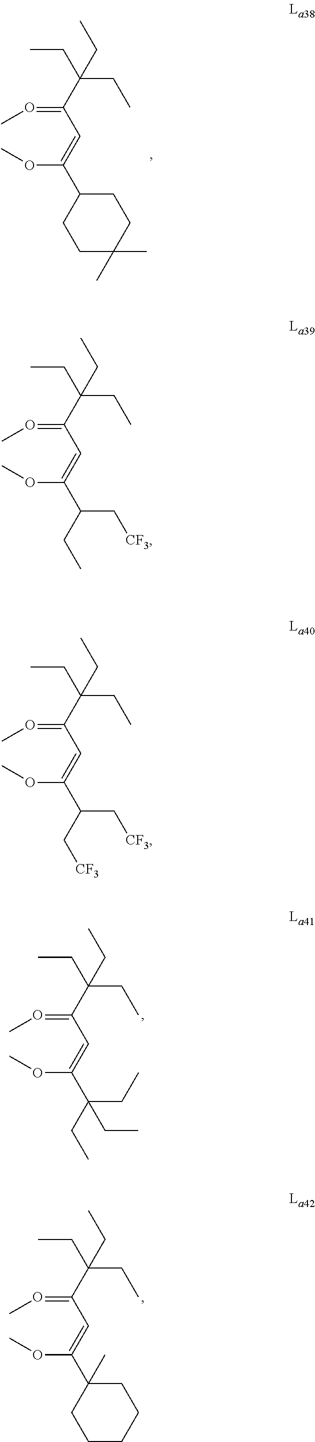

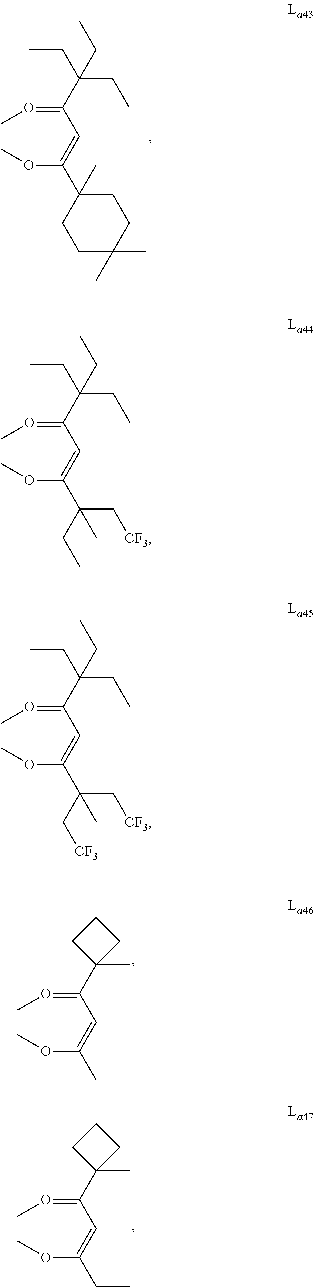

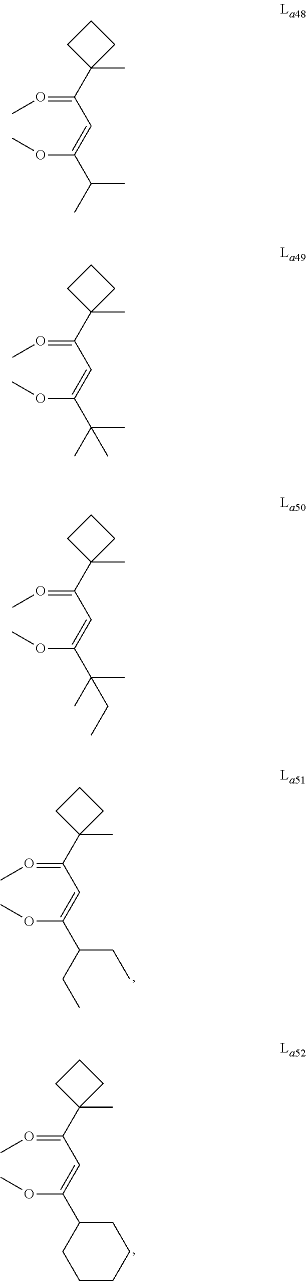

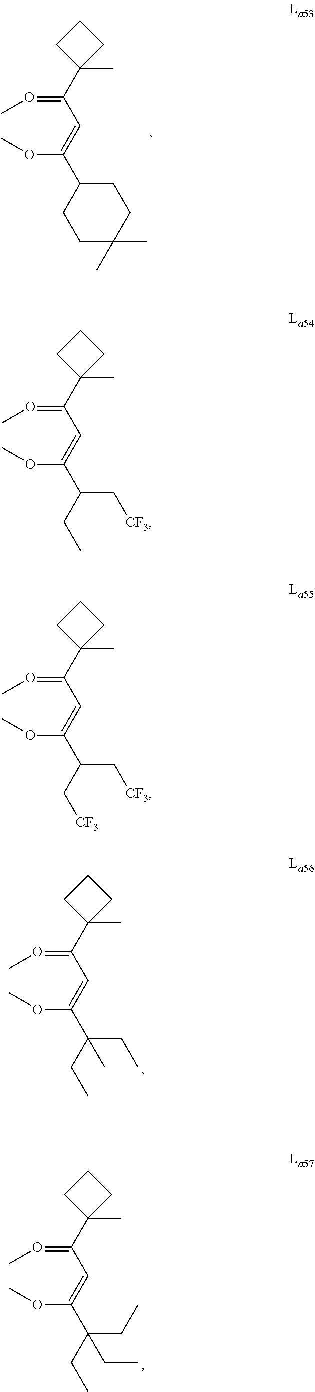

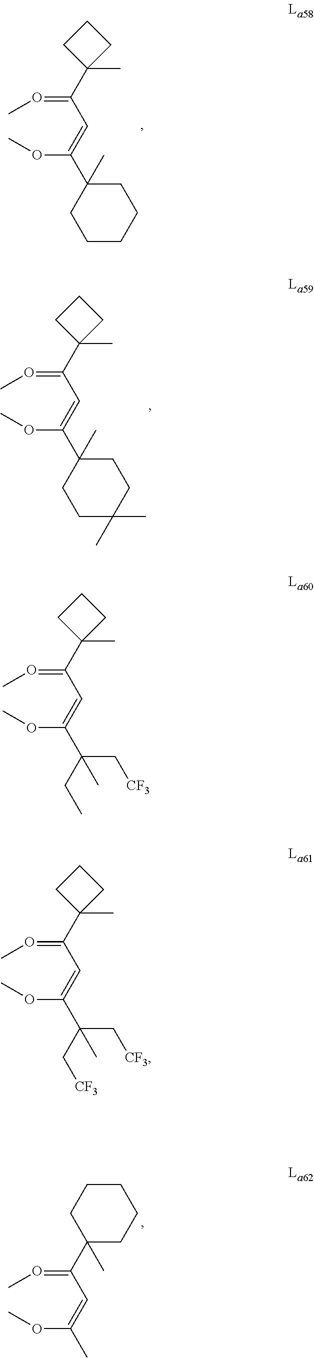

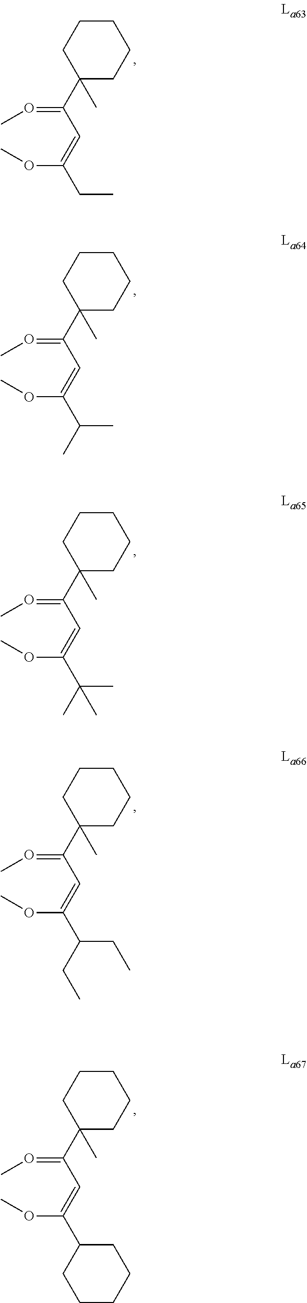

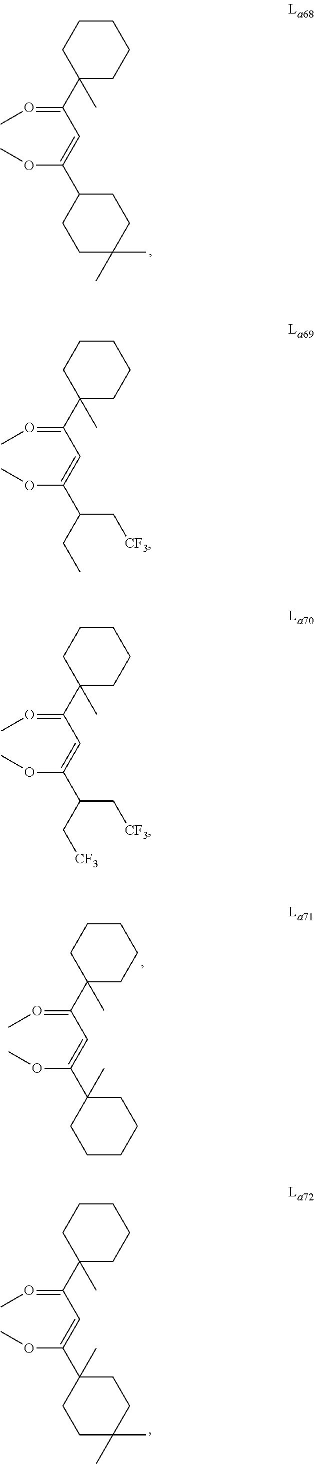

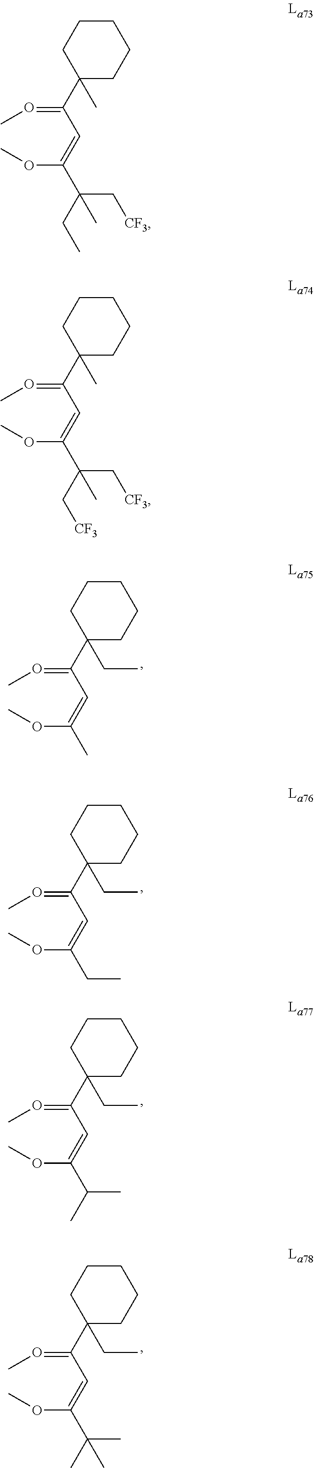

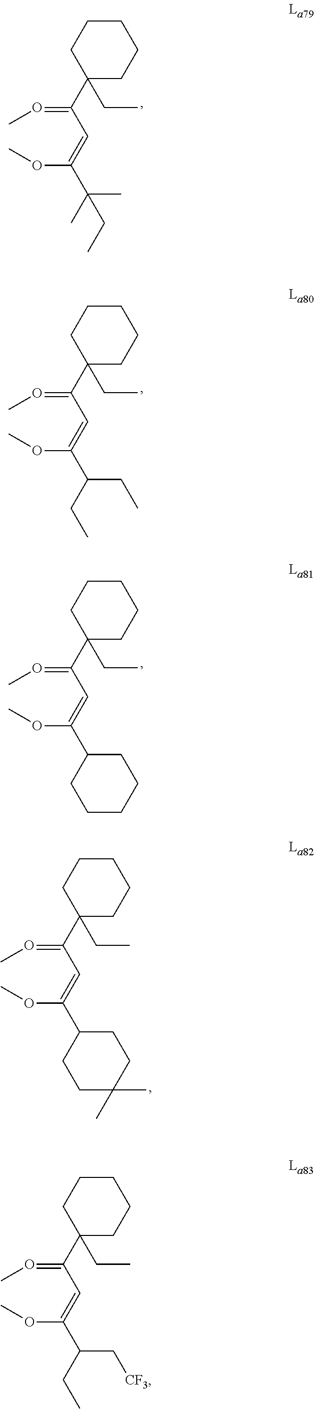

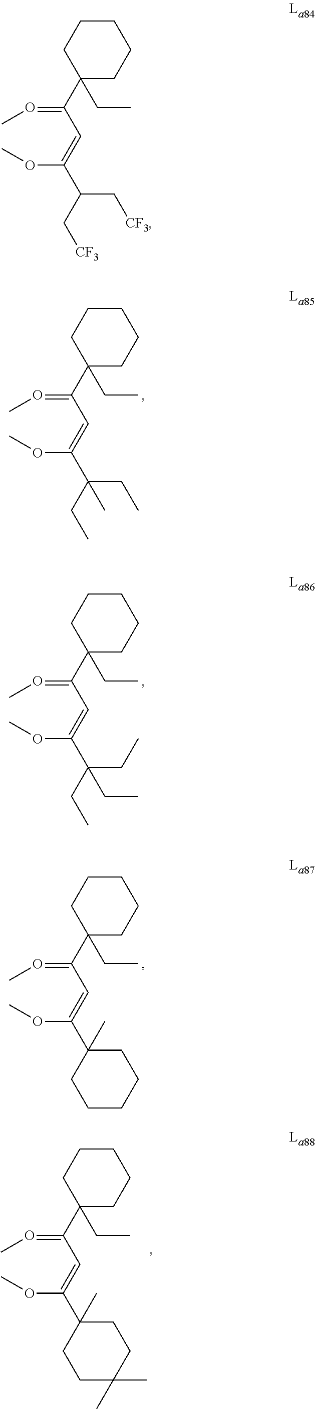

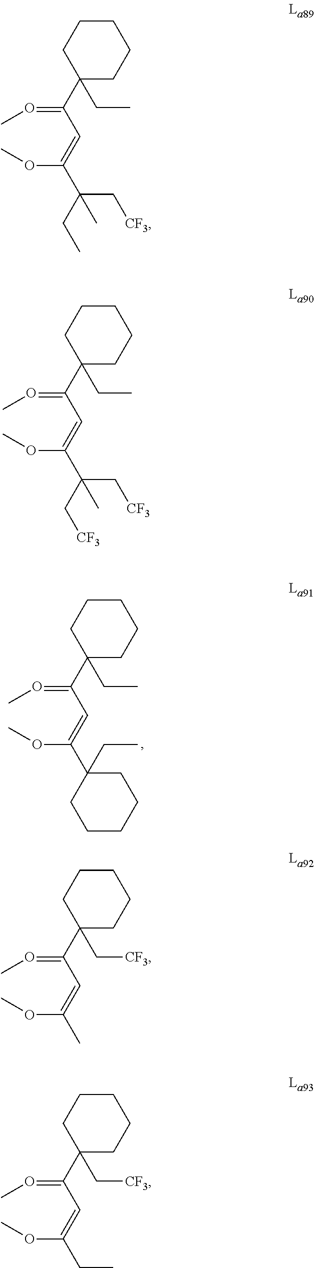

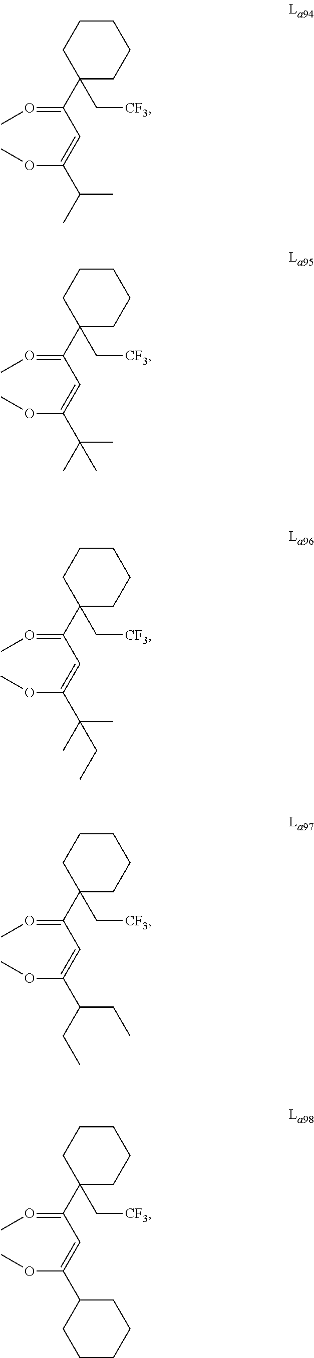

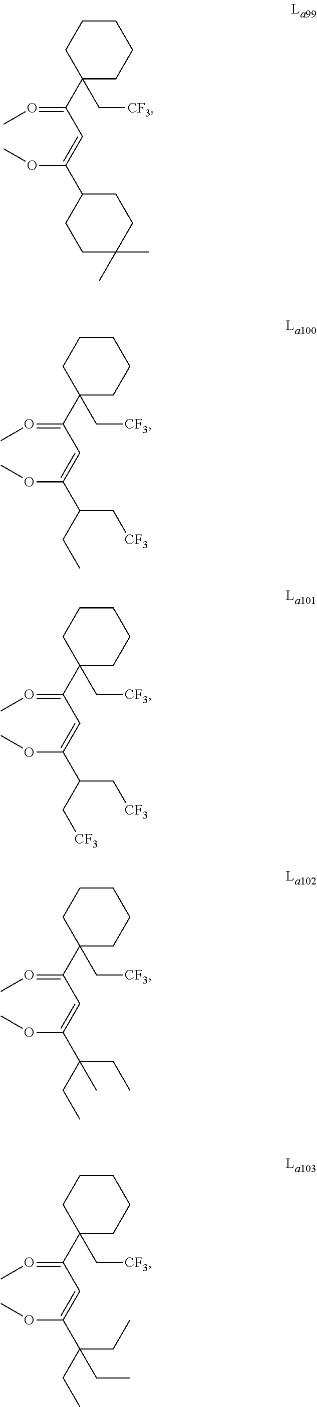

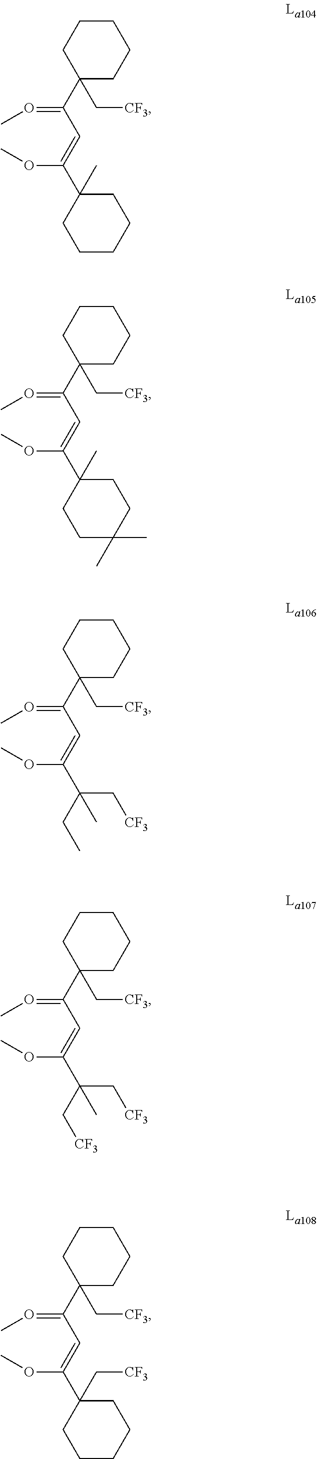

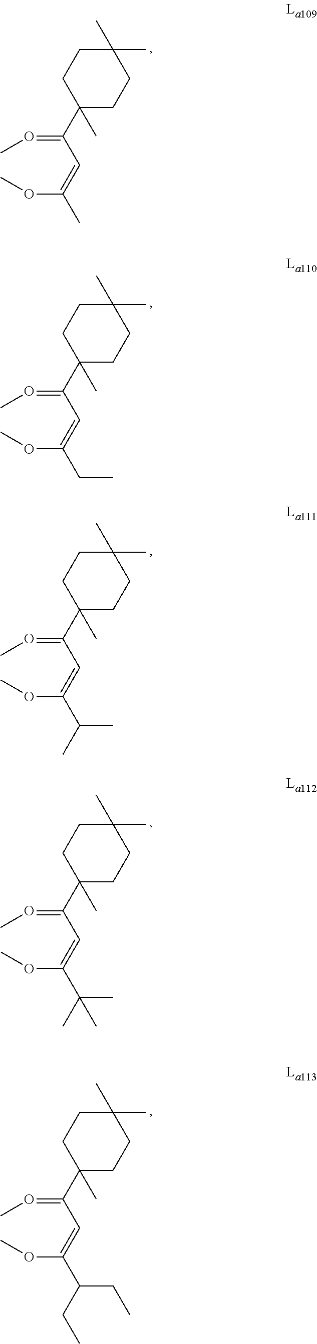

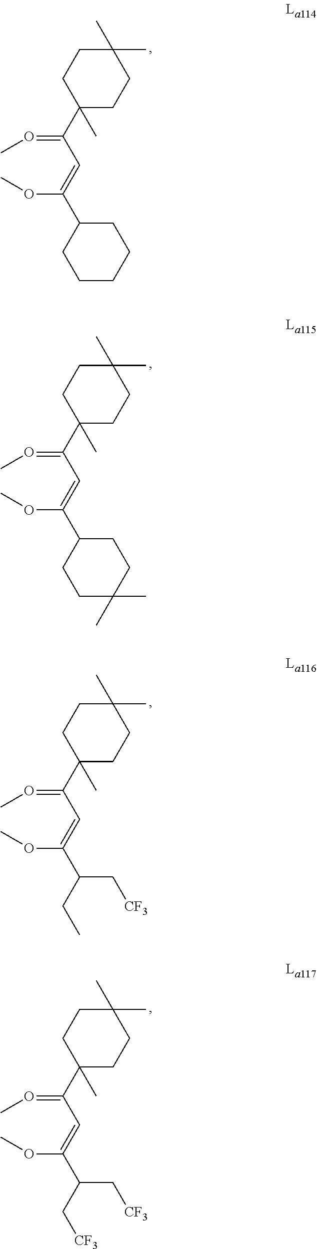

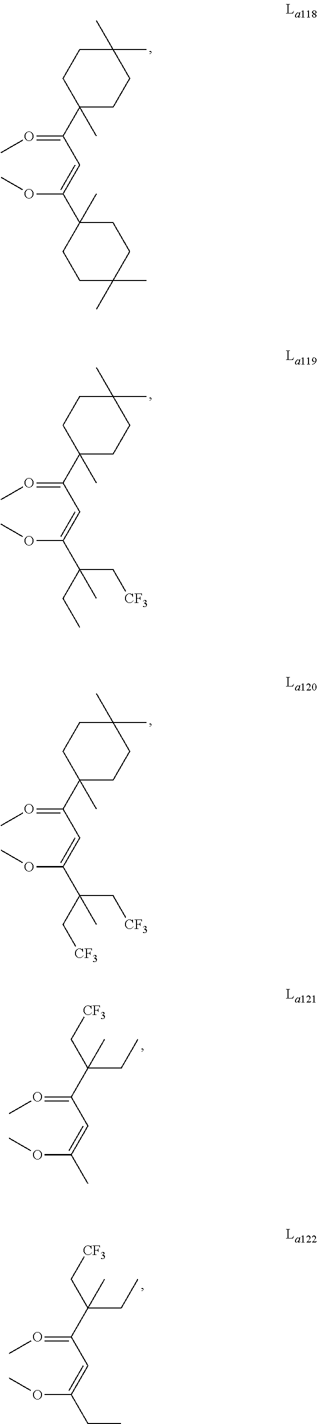

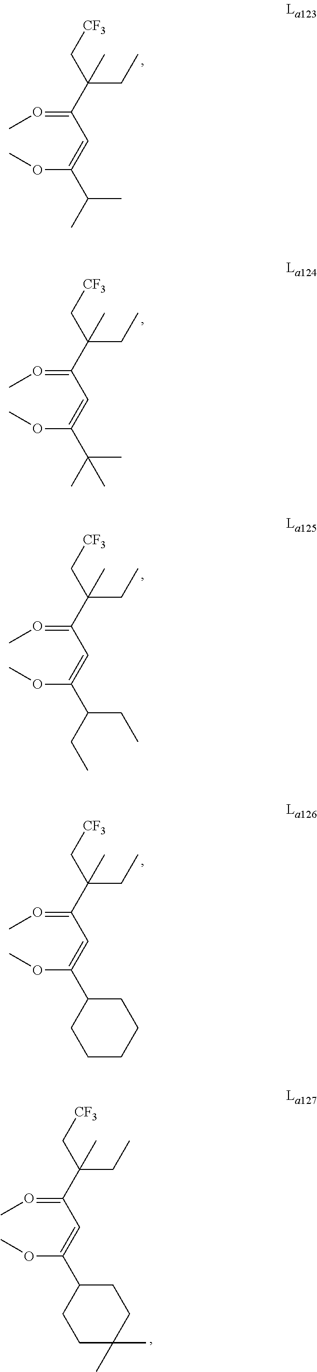

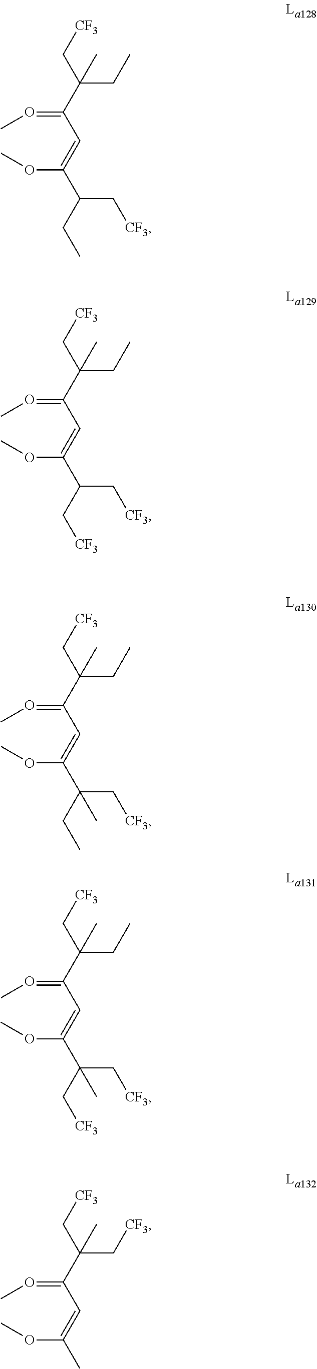

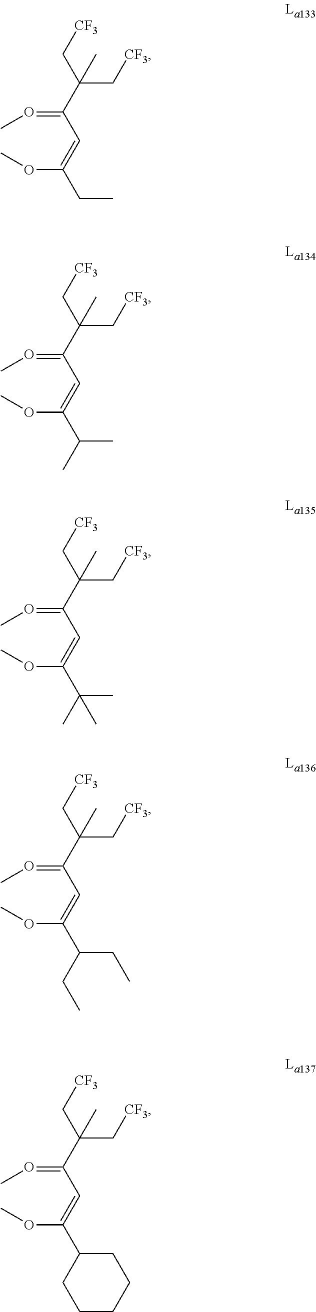

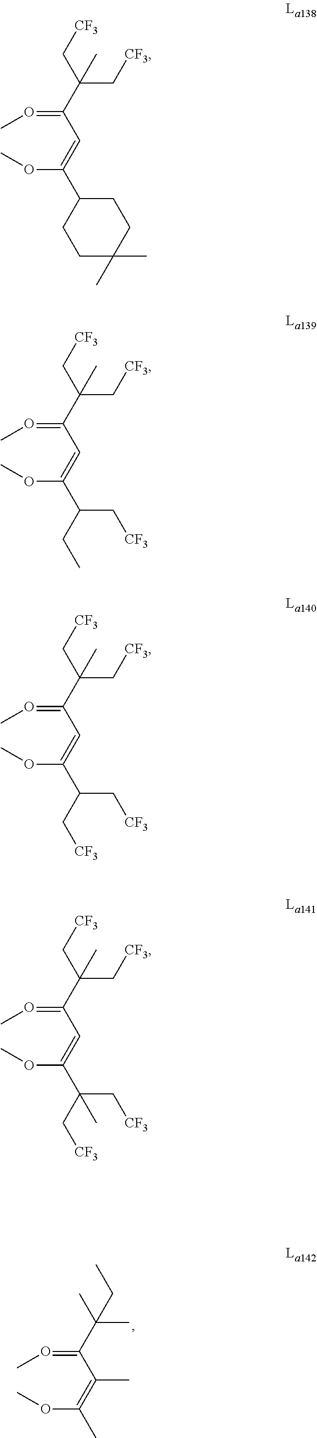

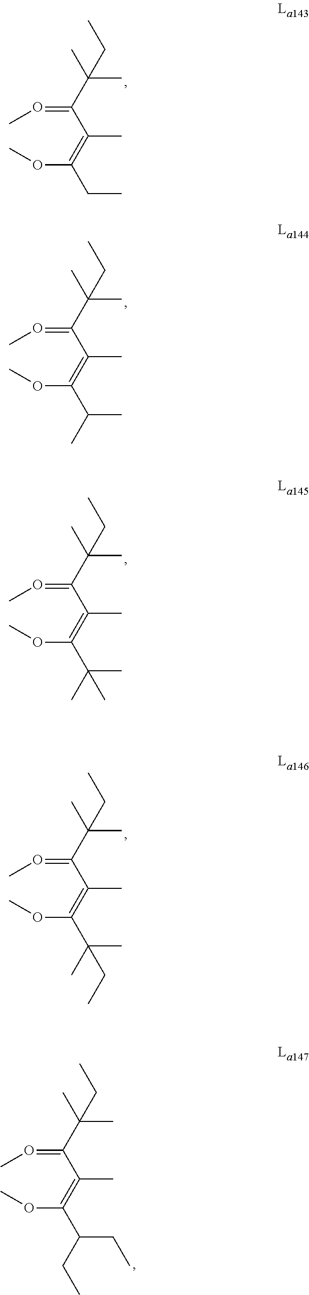

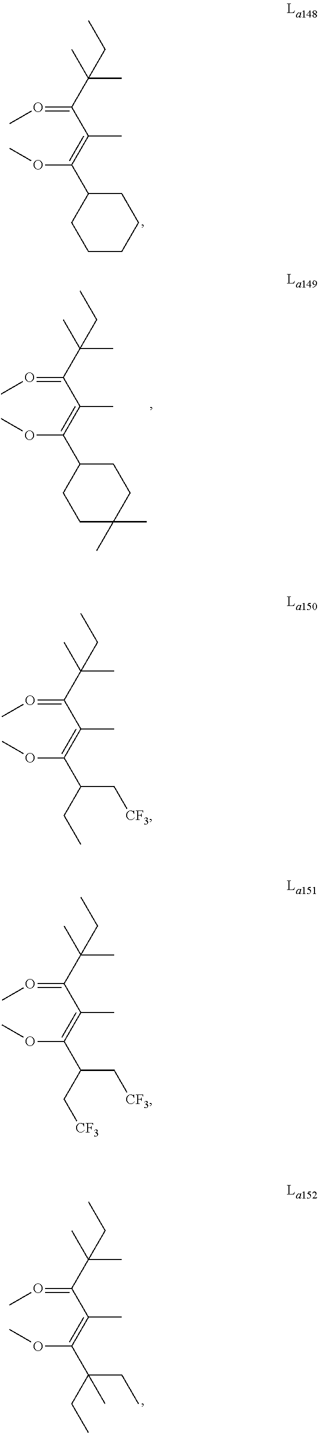

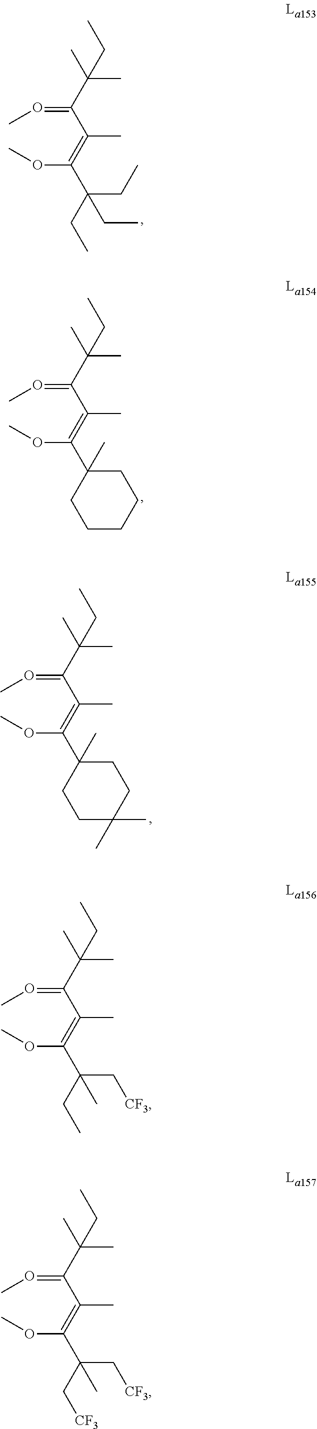

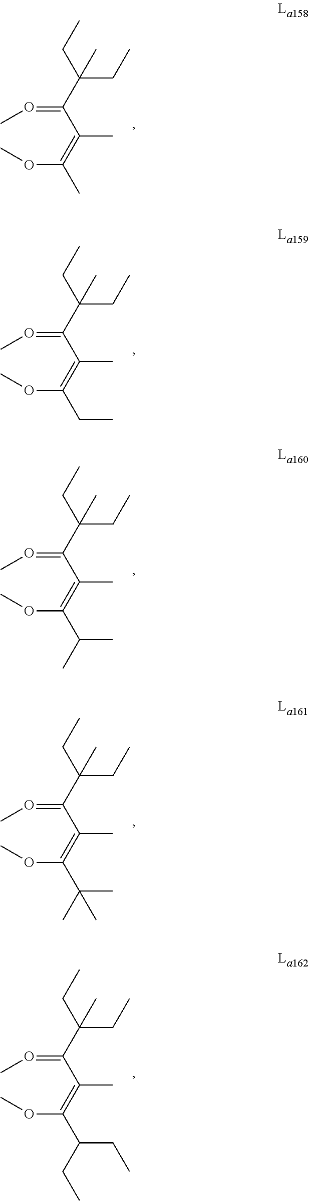

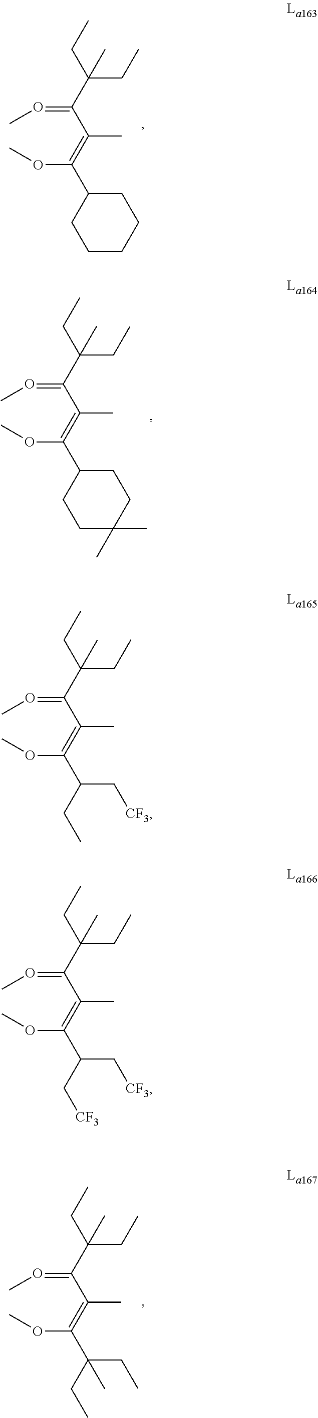

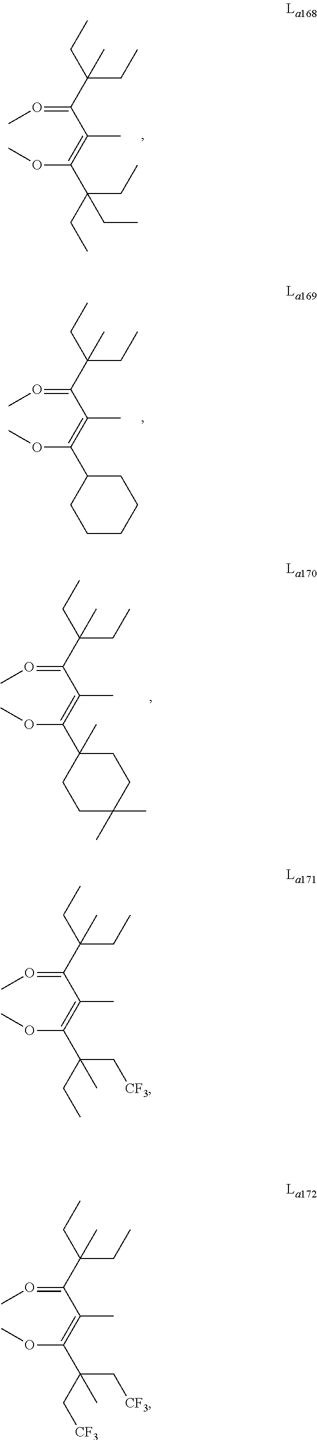

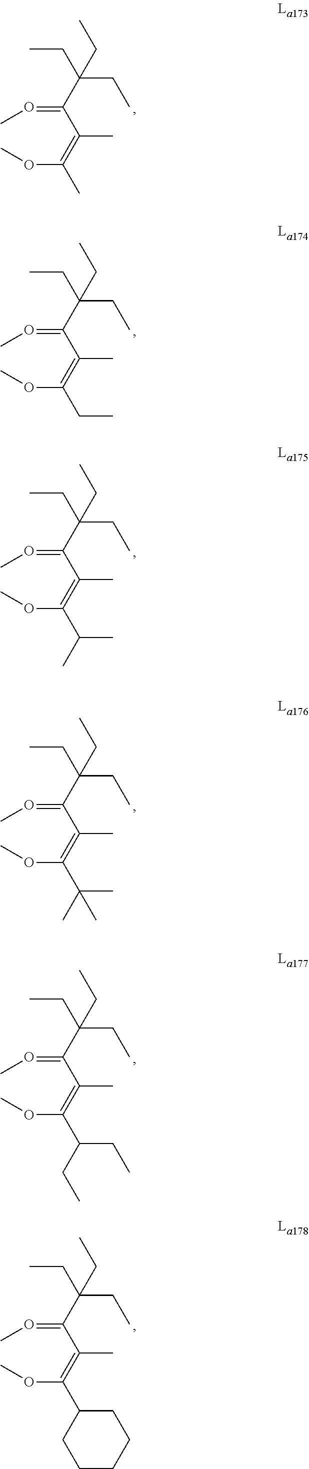

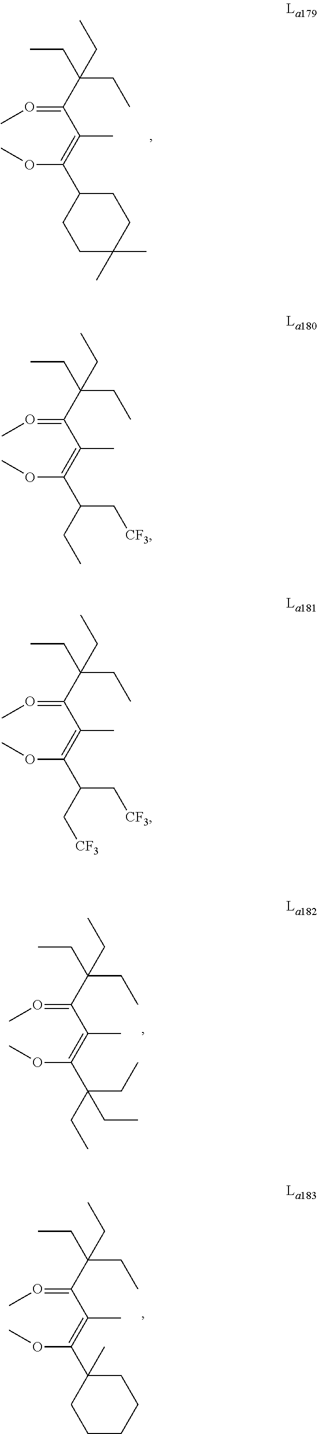

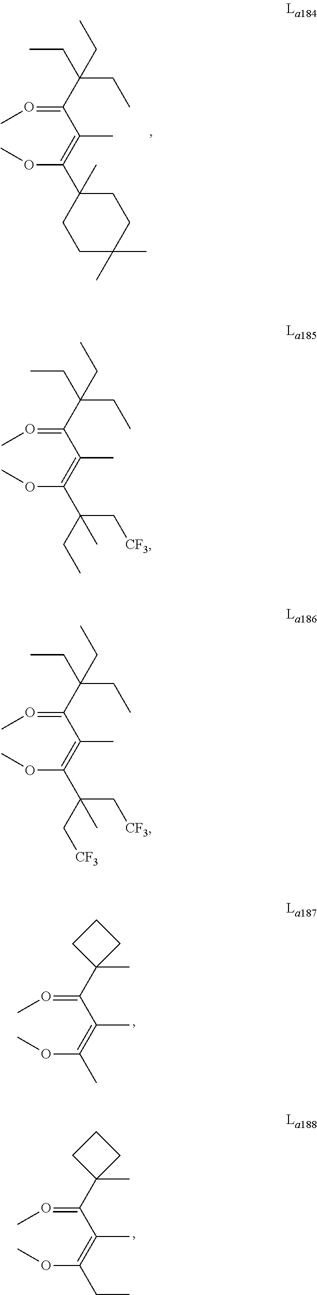

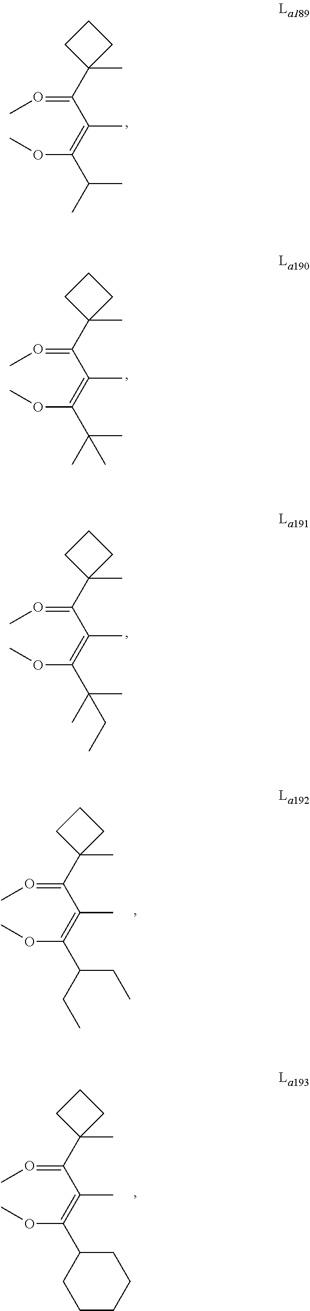

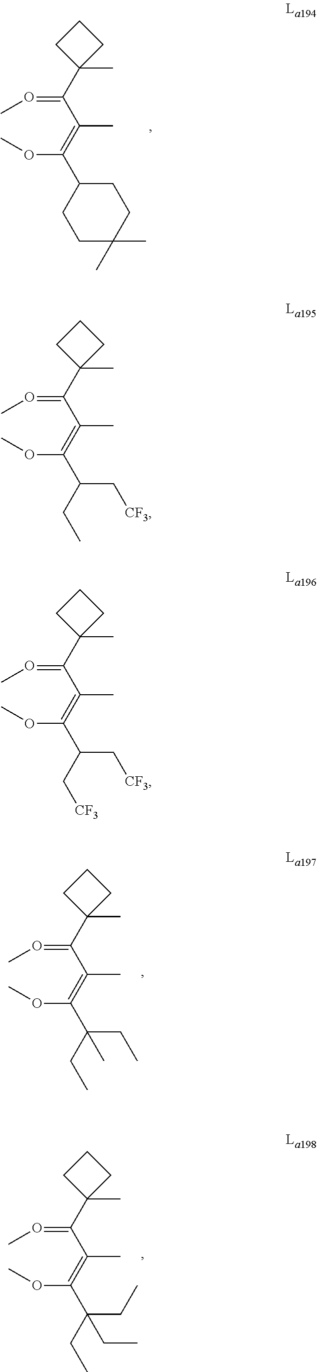

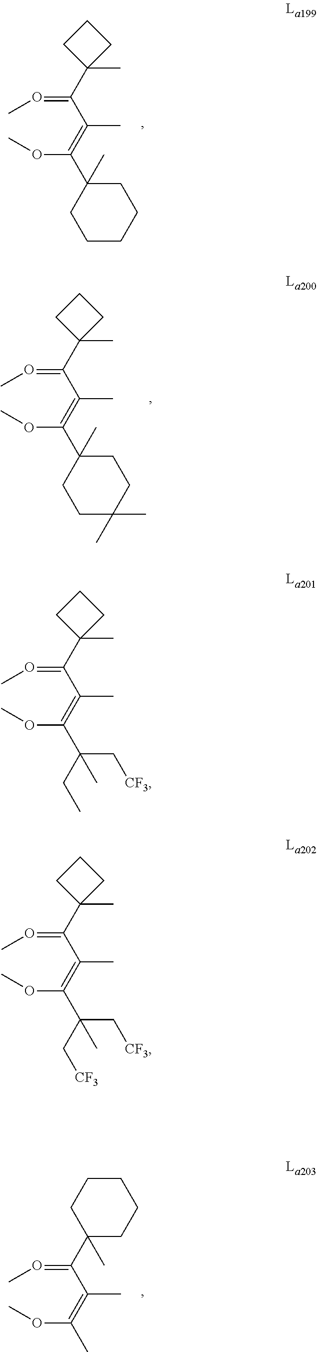

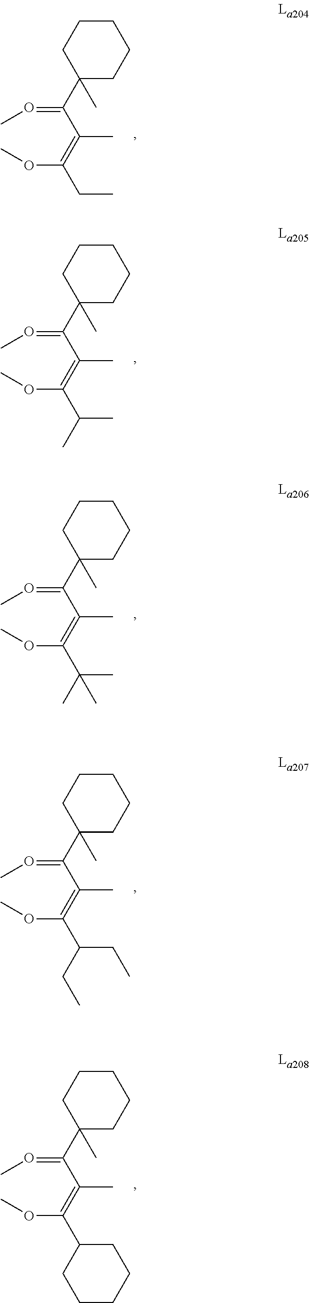

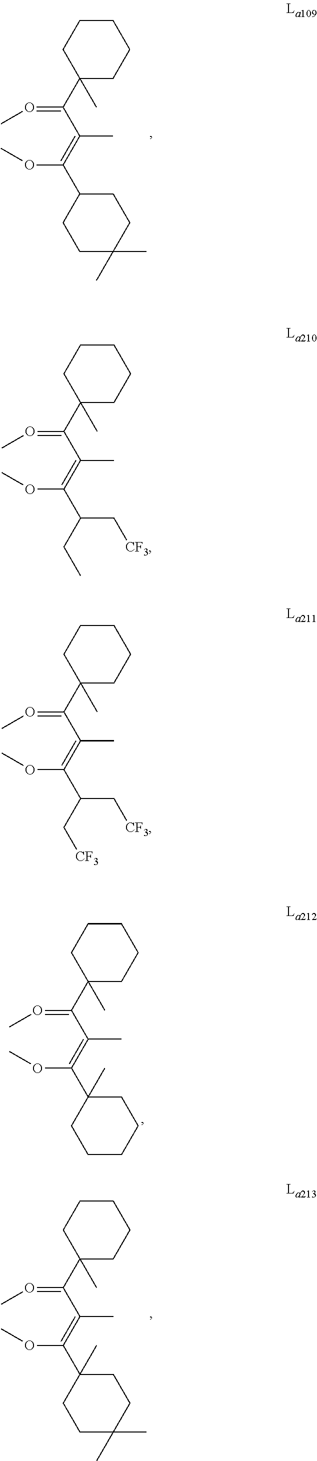

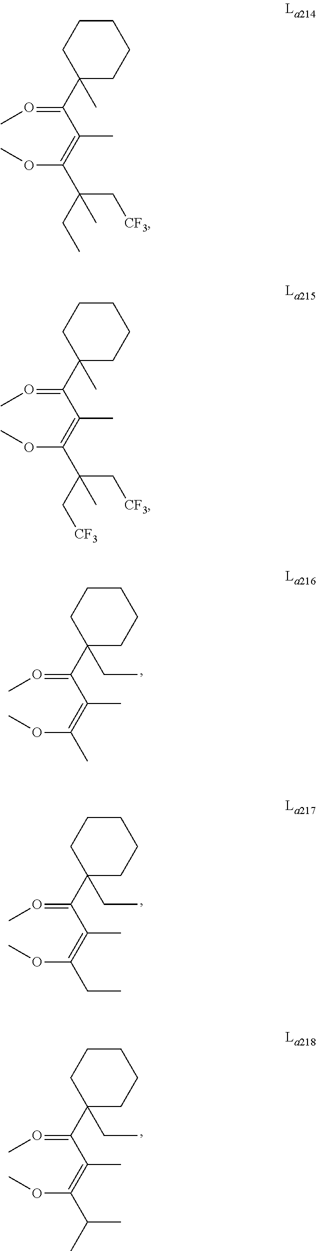

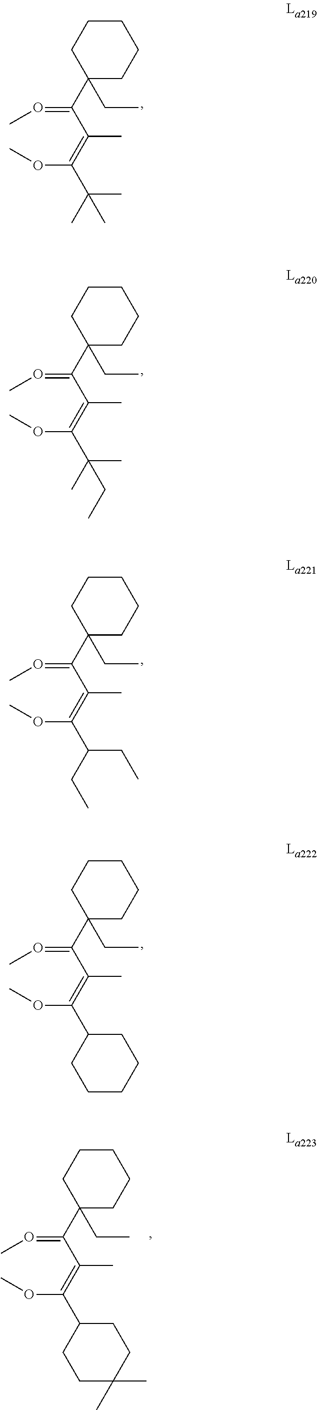

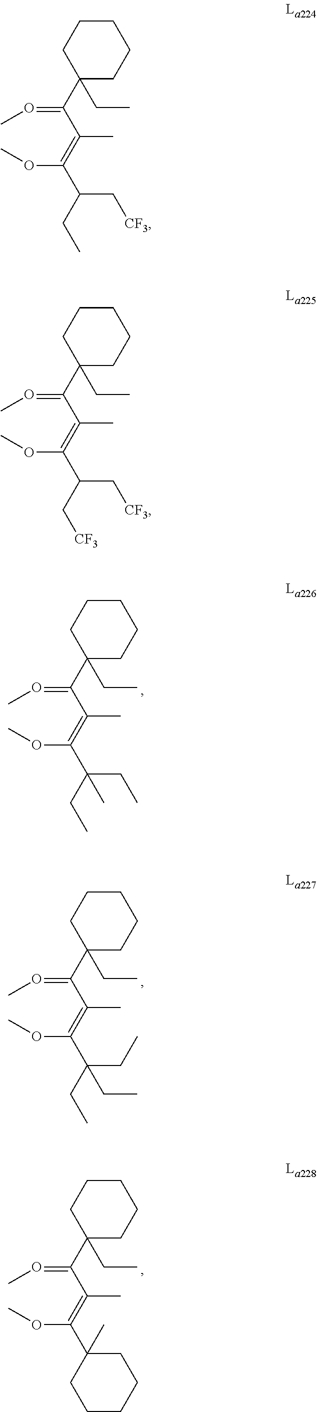

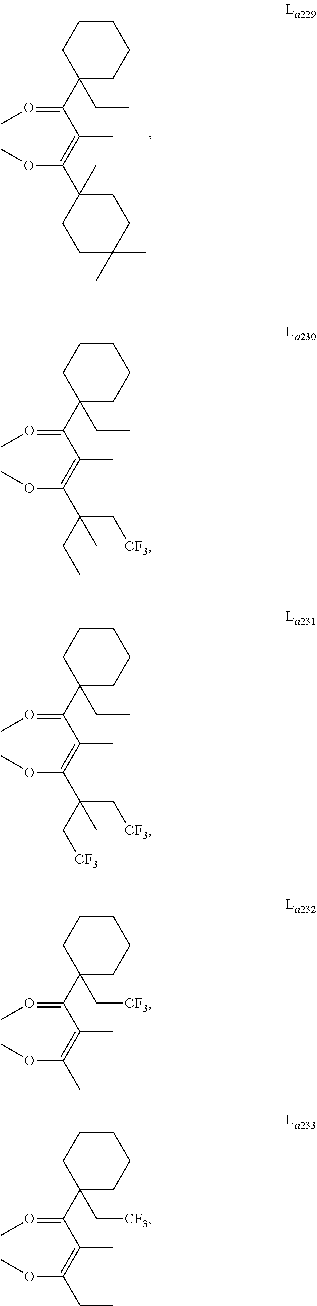

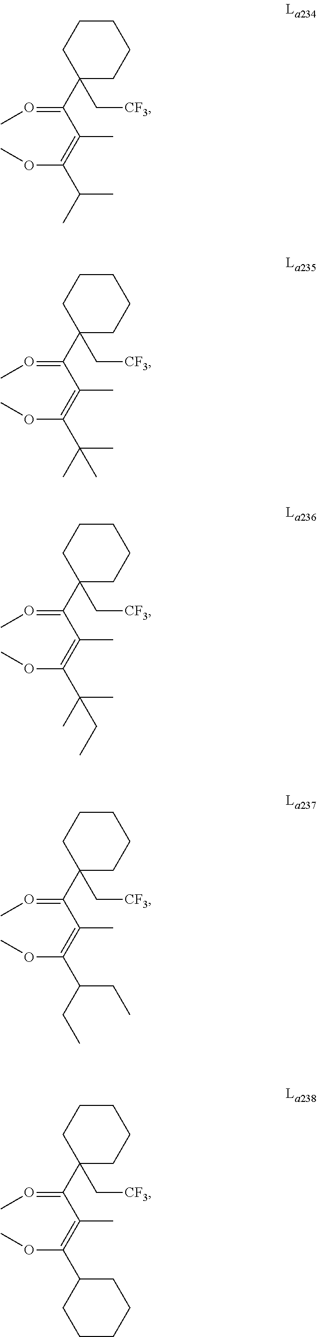

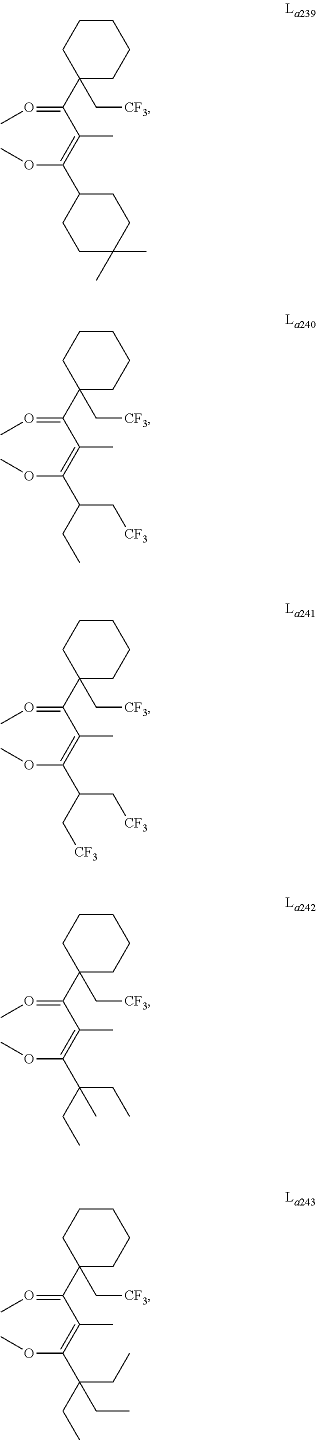

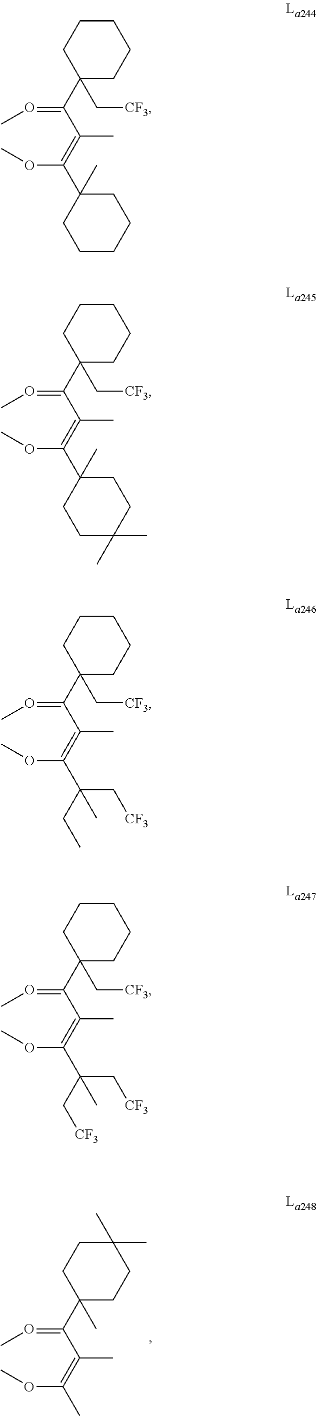

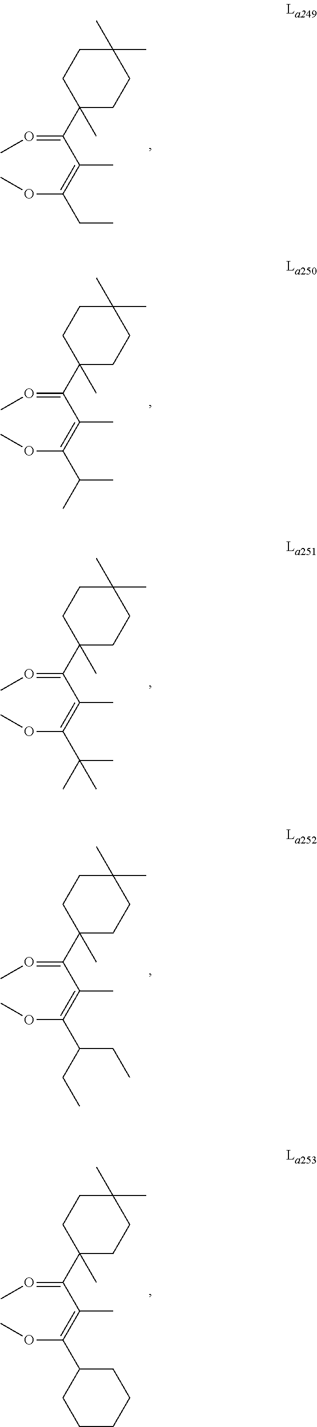

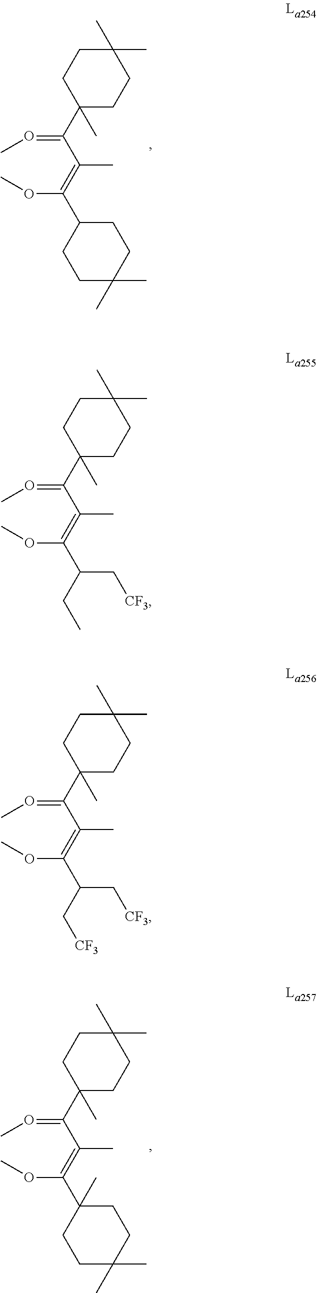

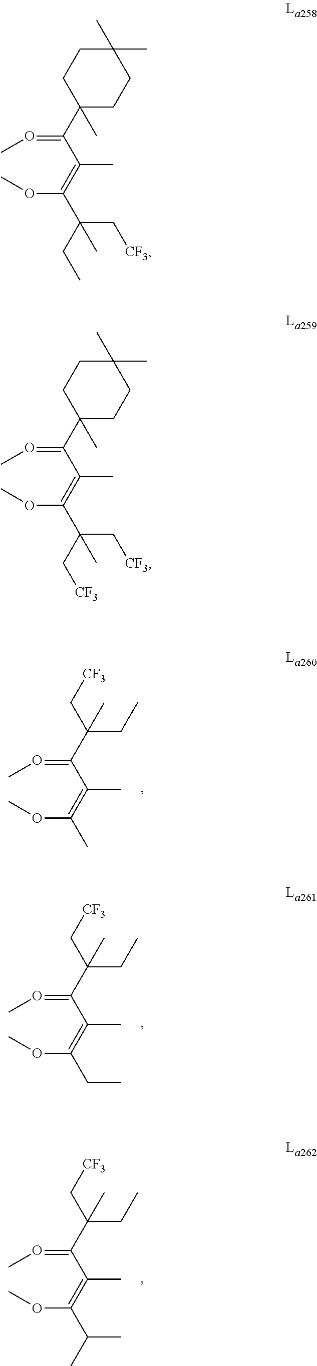

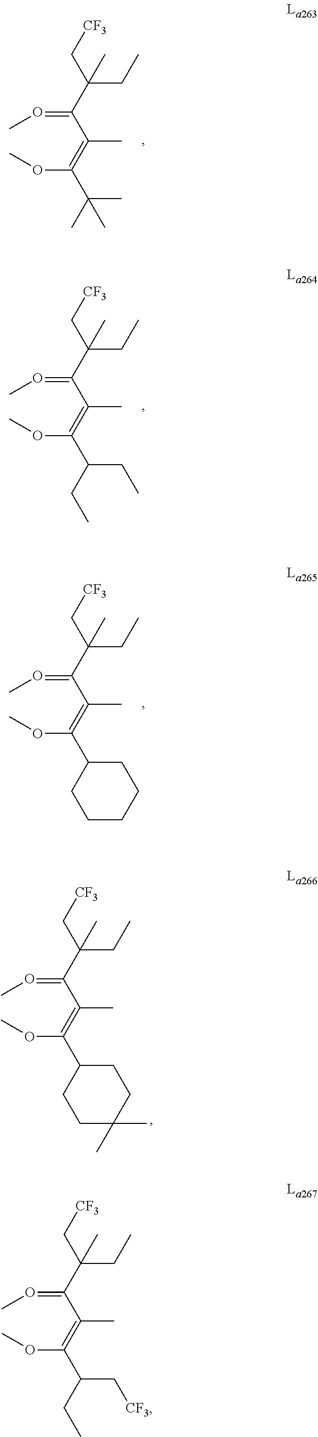

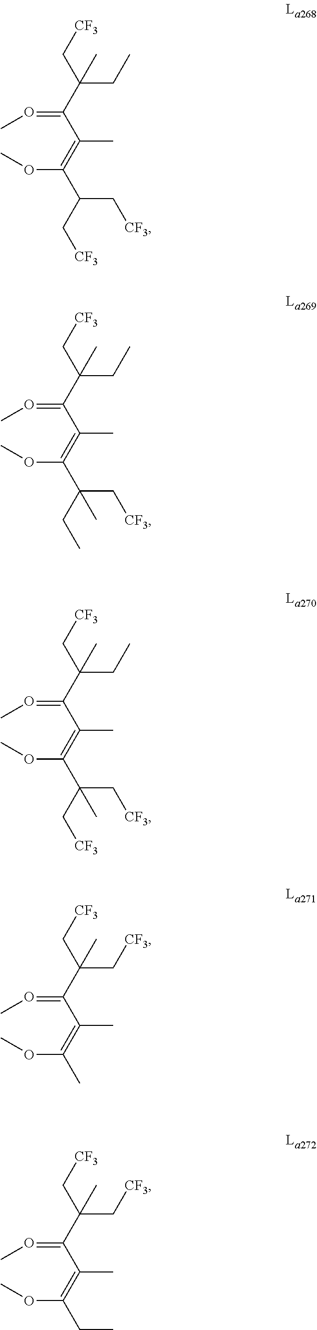

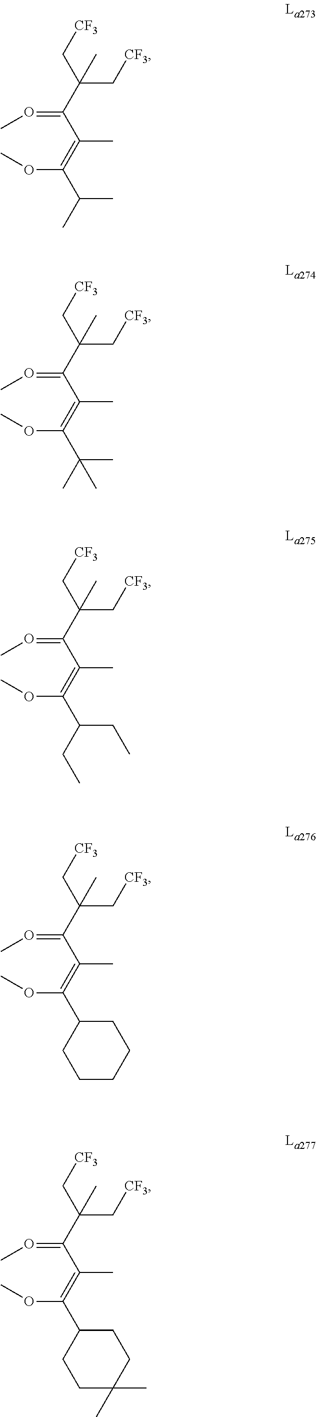

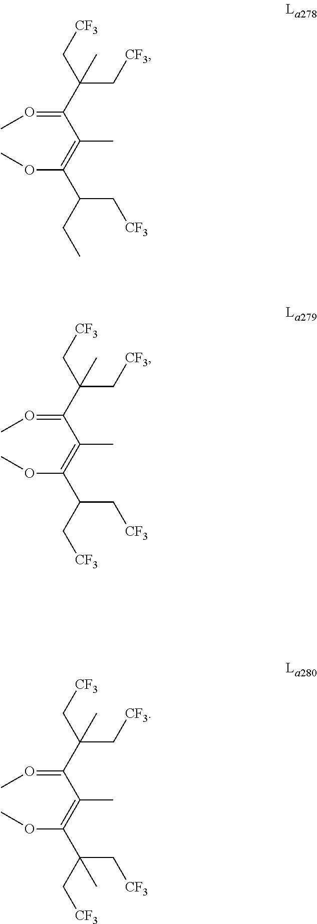

According to an embodiment of the present invention, wherein the ligand L_{b} is selected from the group consisting of:

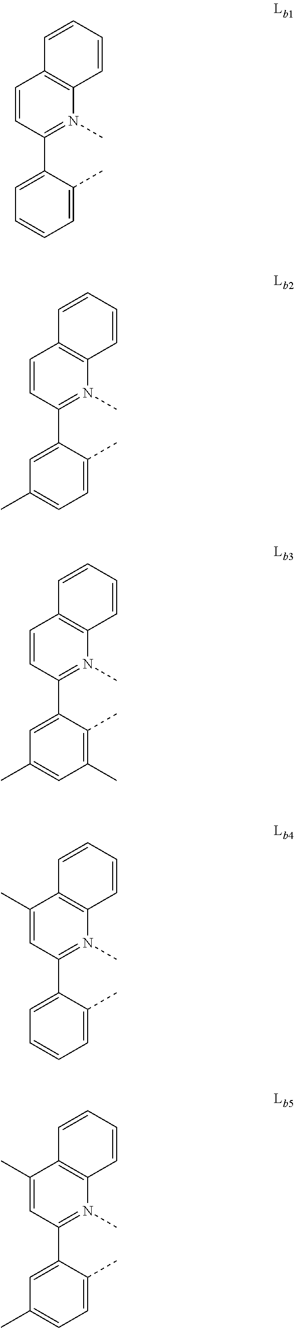

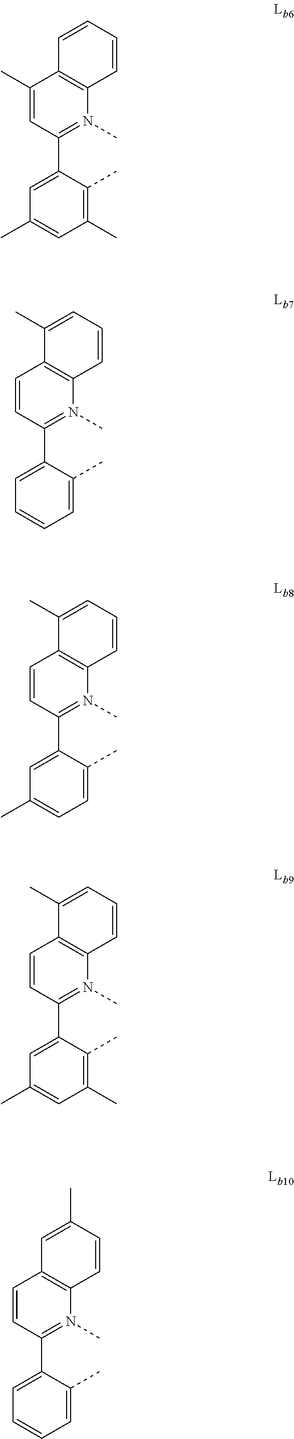

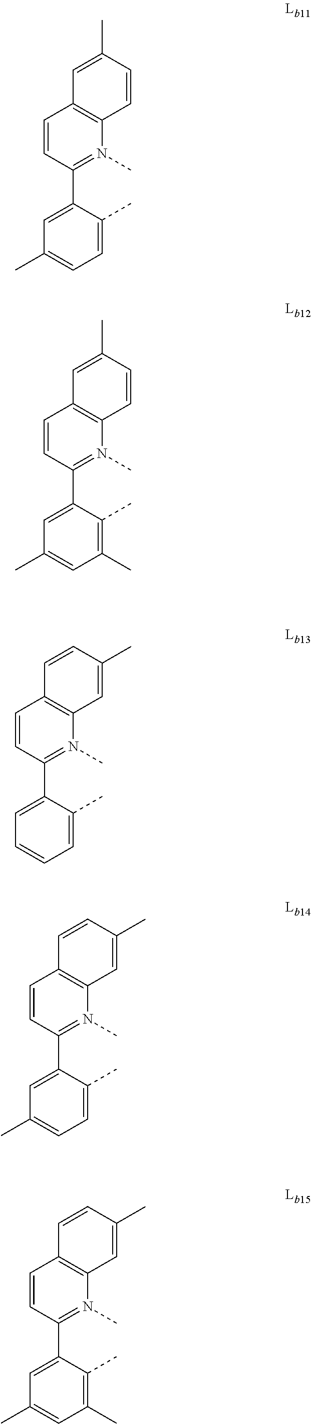

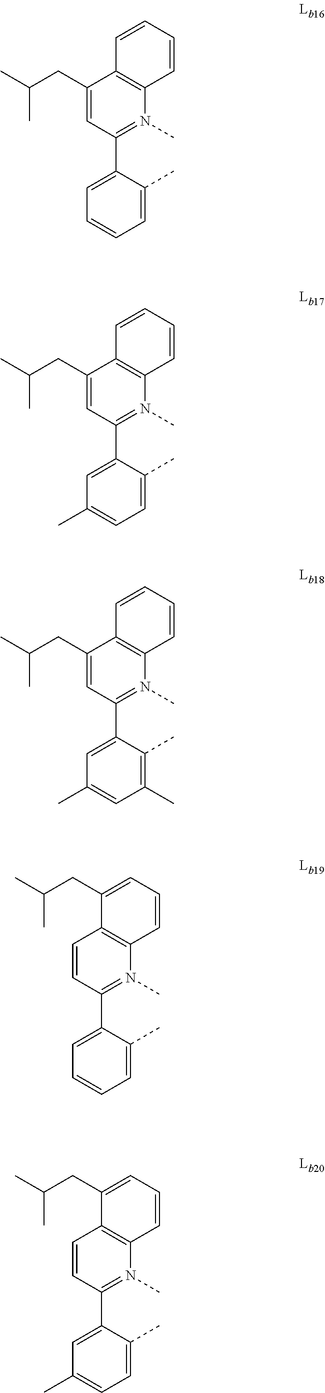

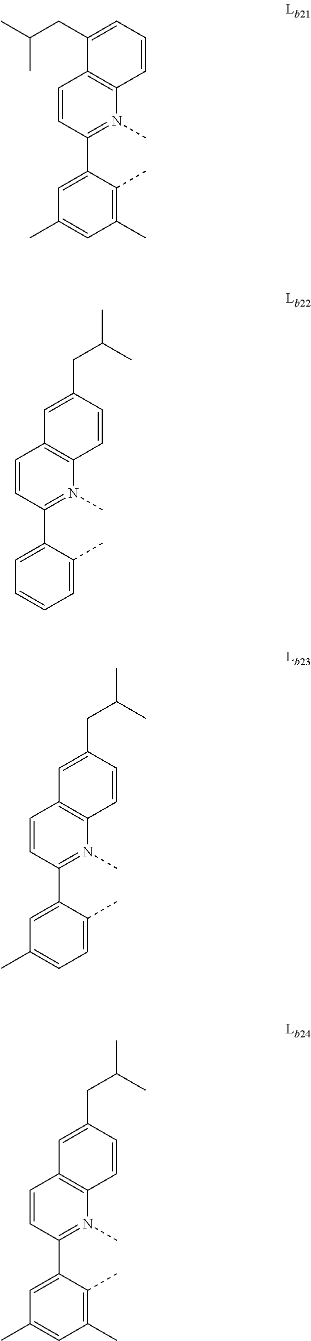

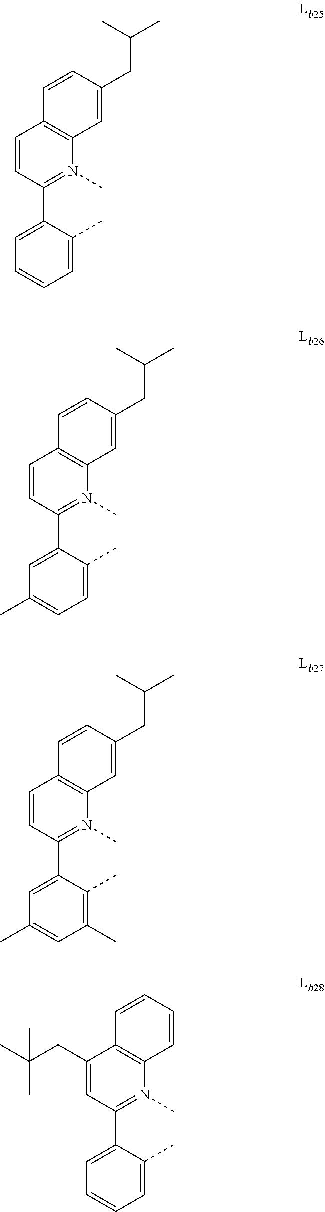

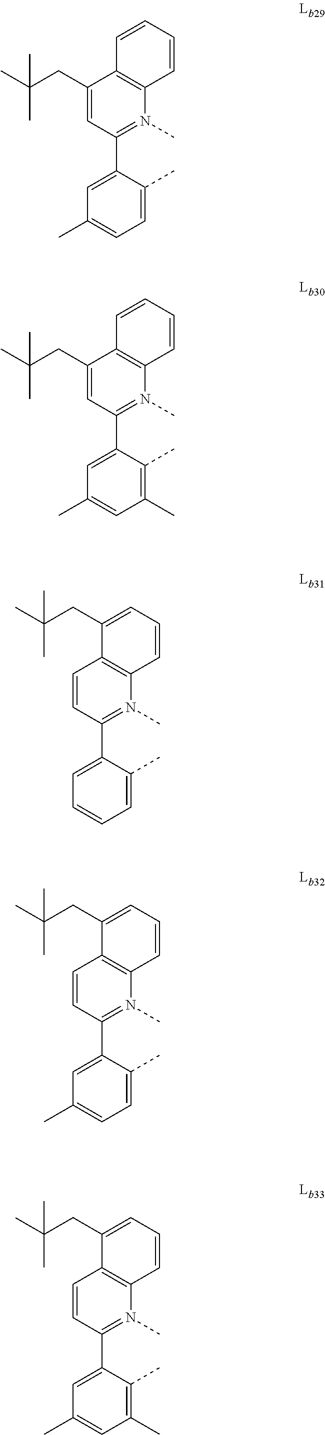

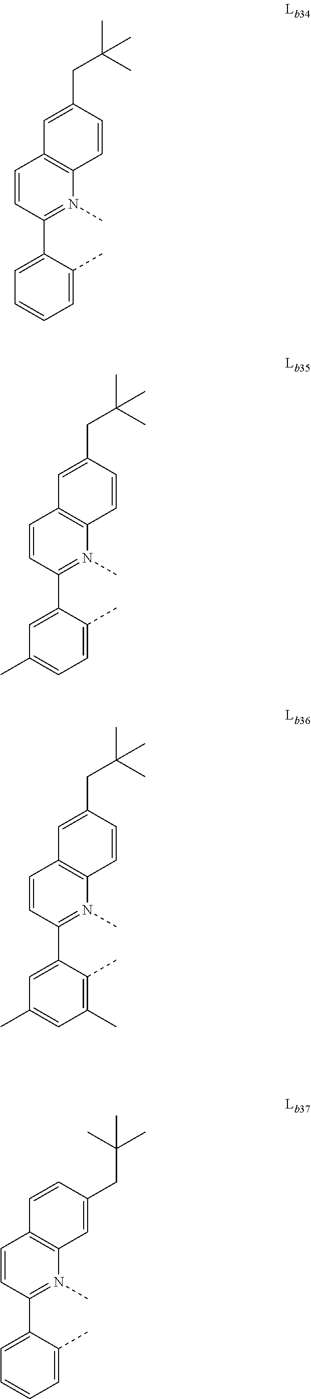

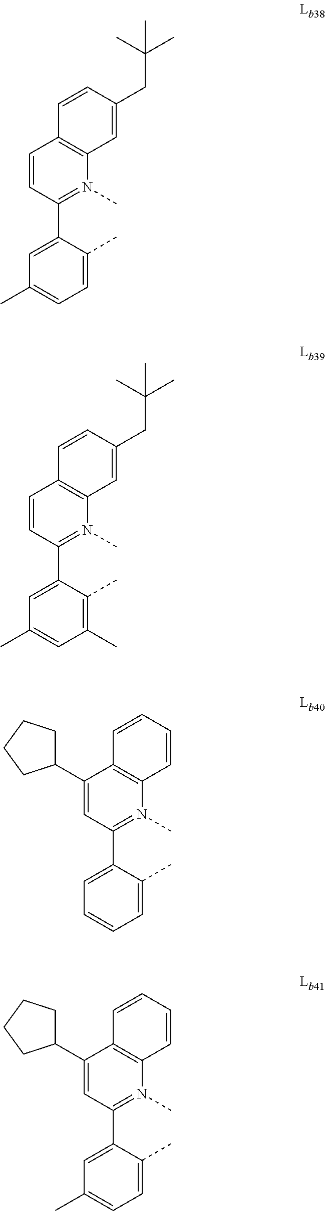

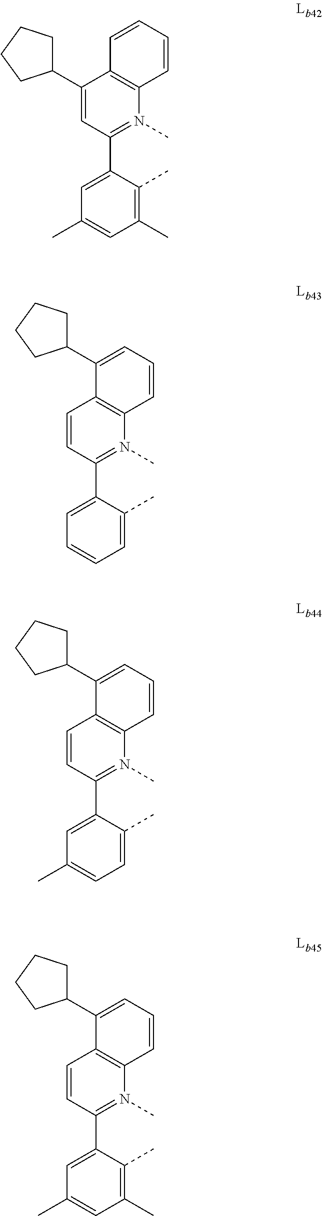

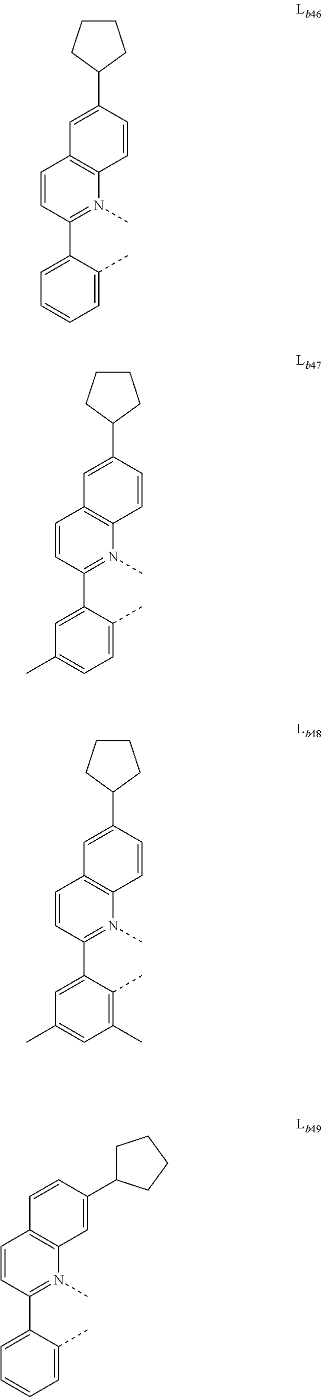

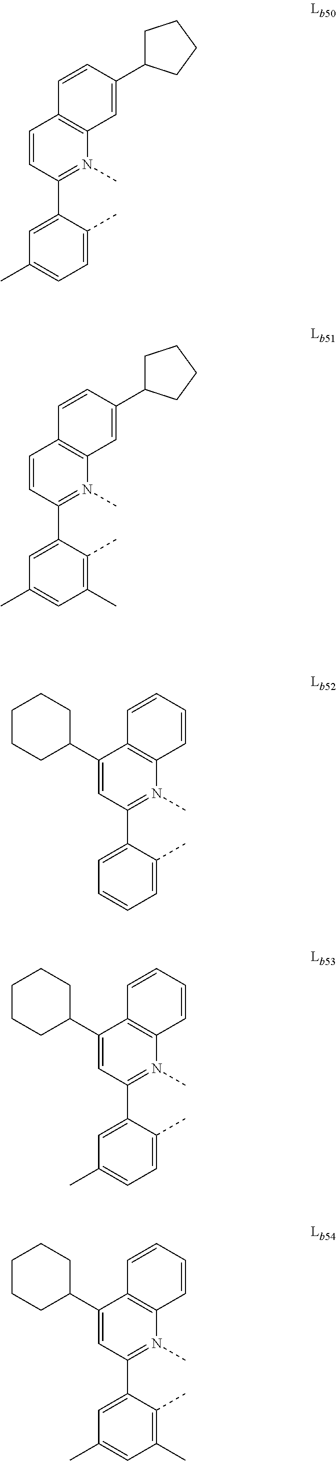

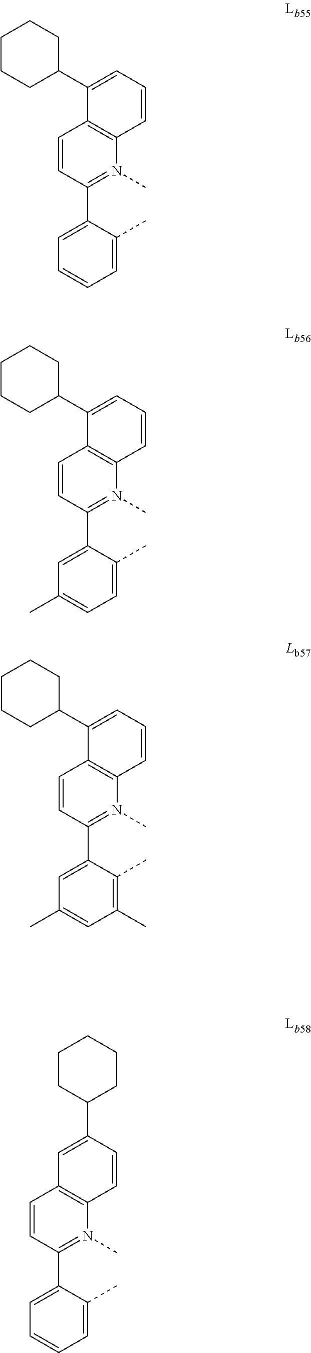

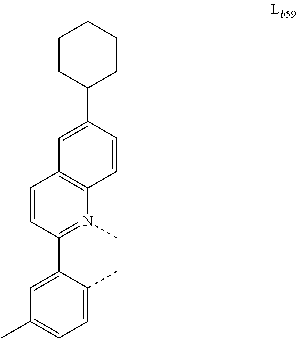

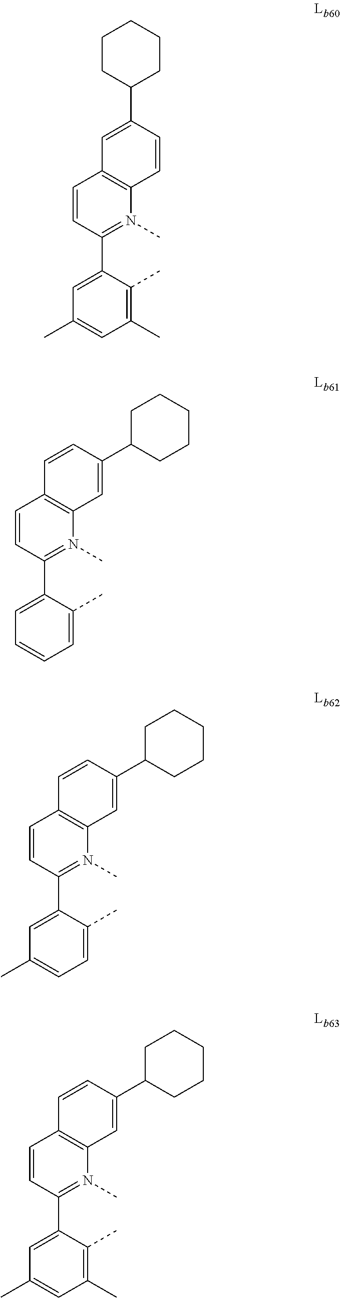

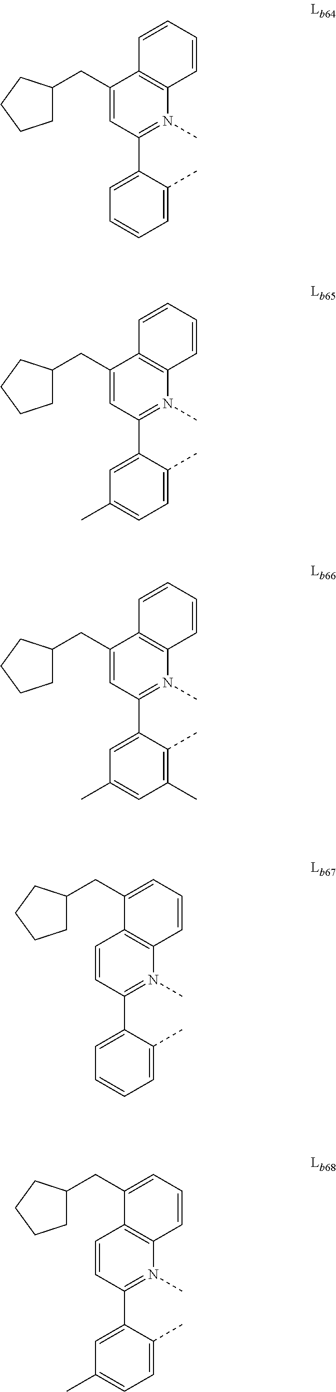

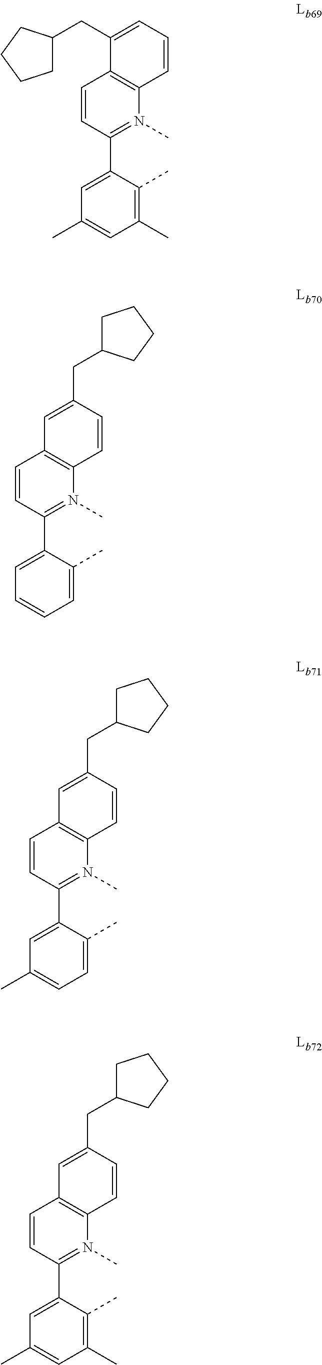

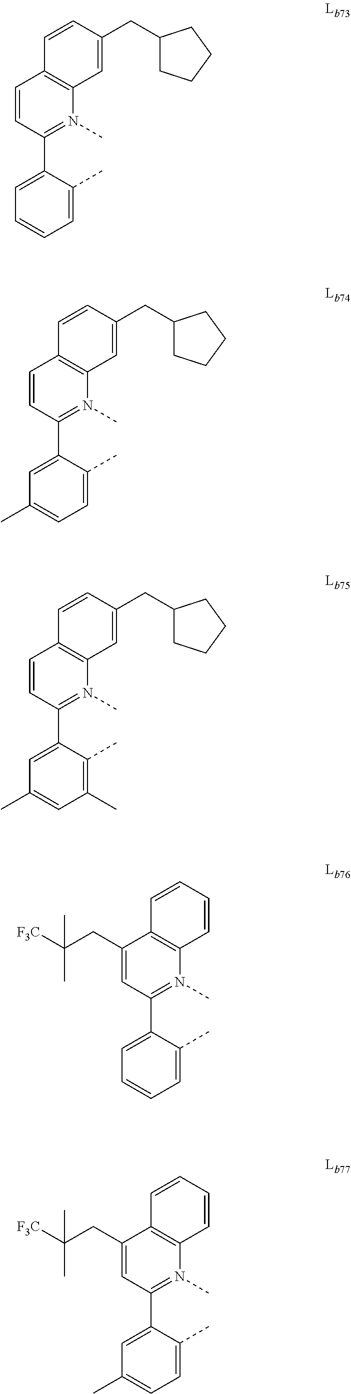

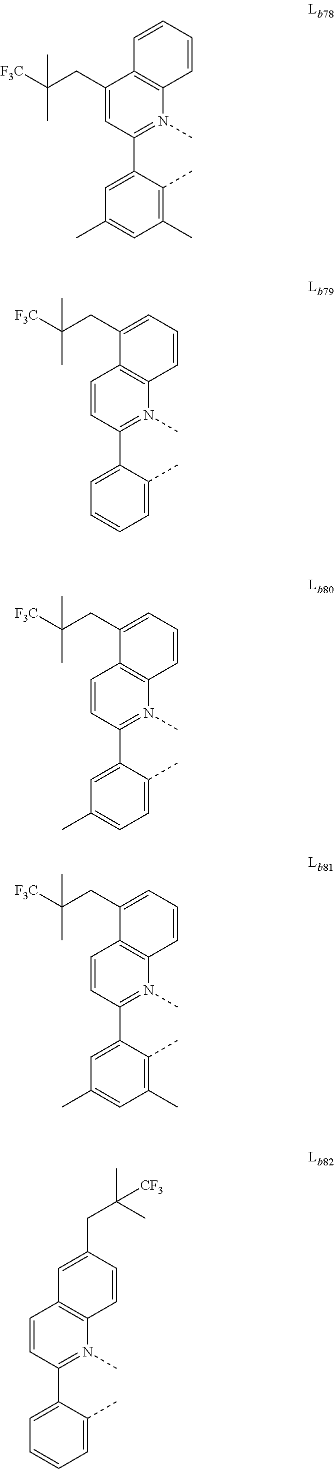

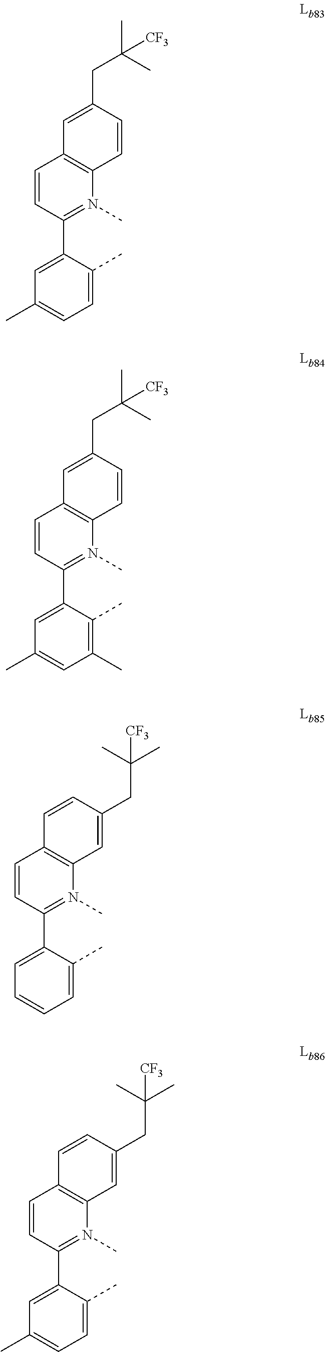

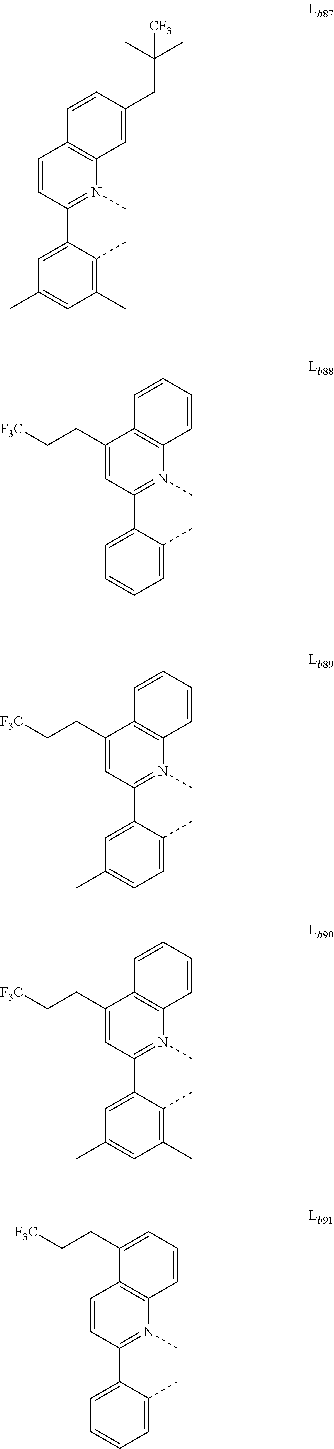

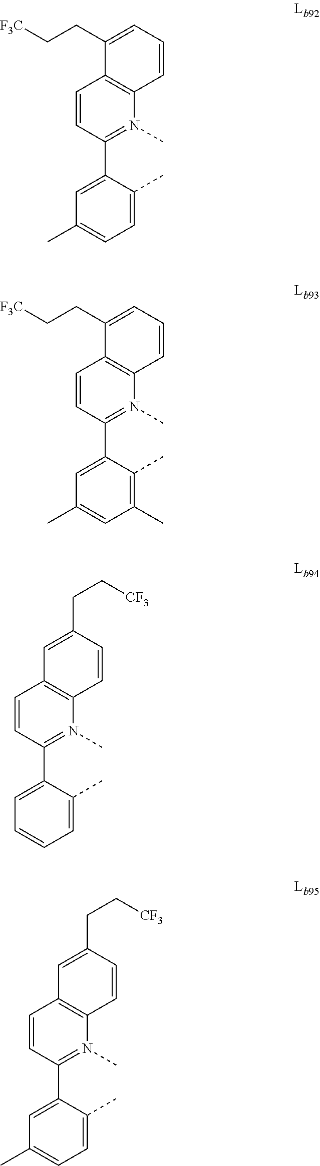

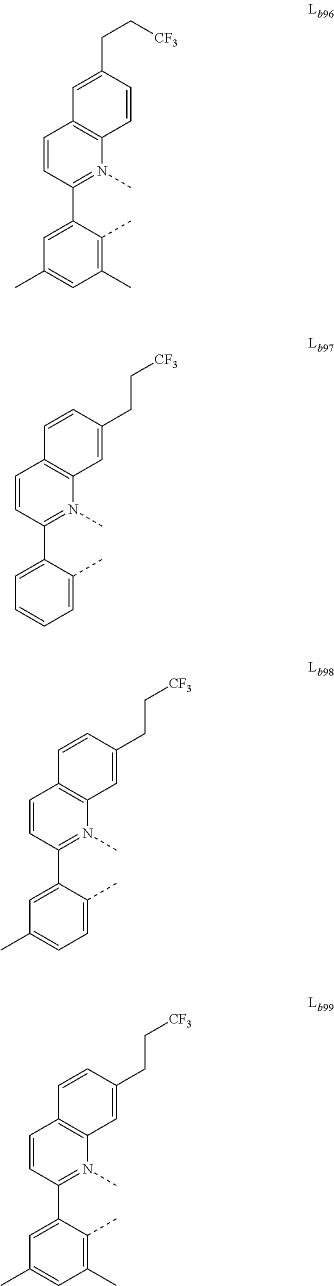

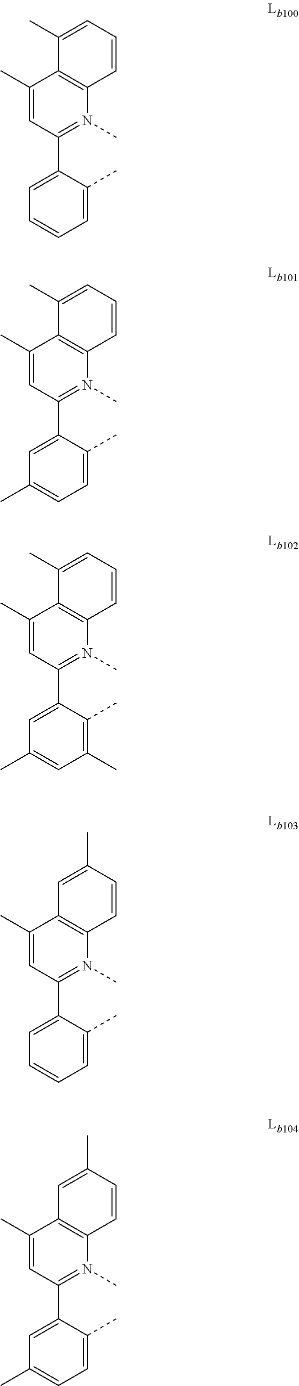

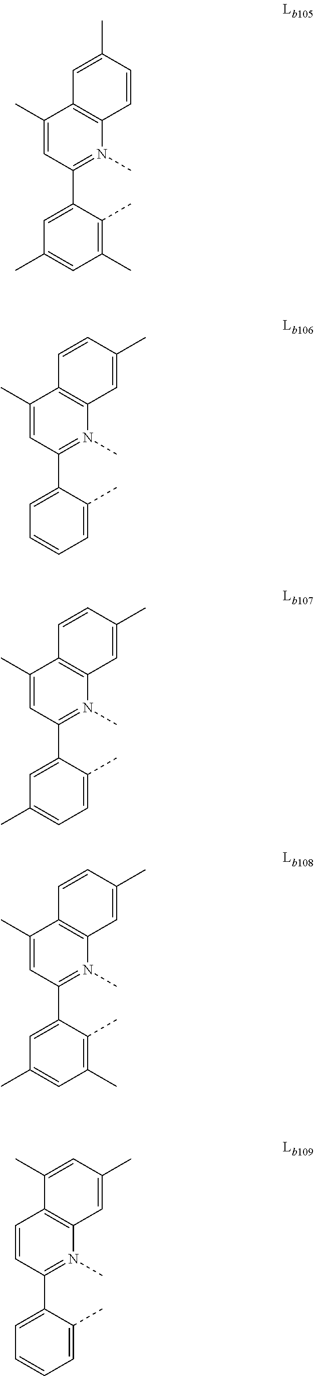

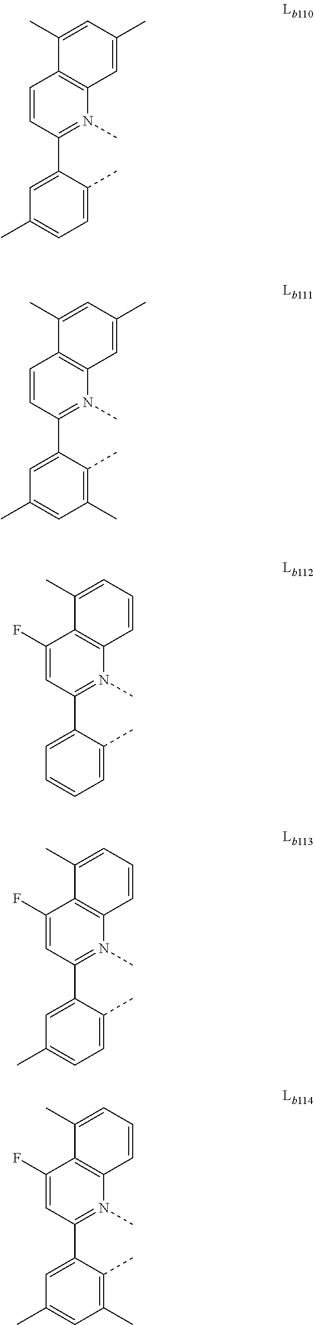

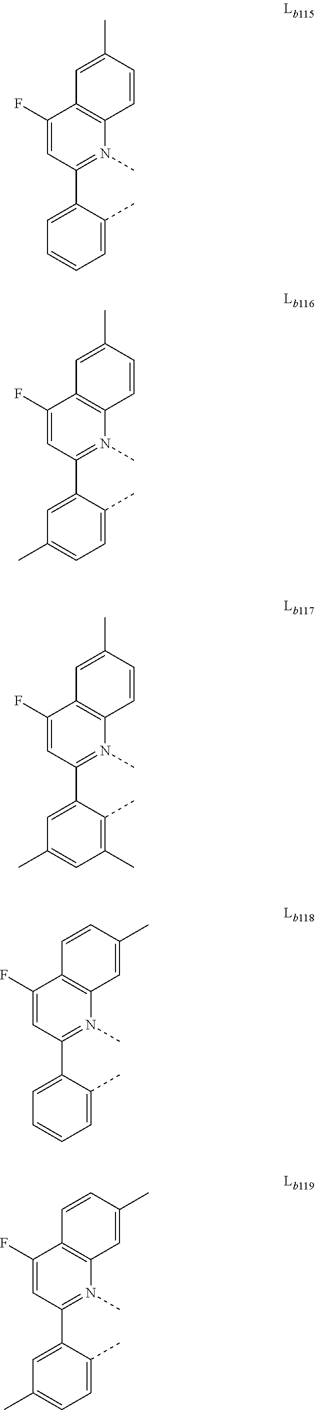

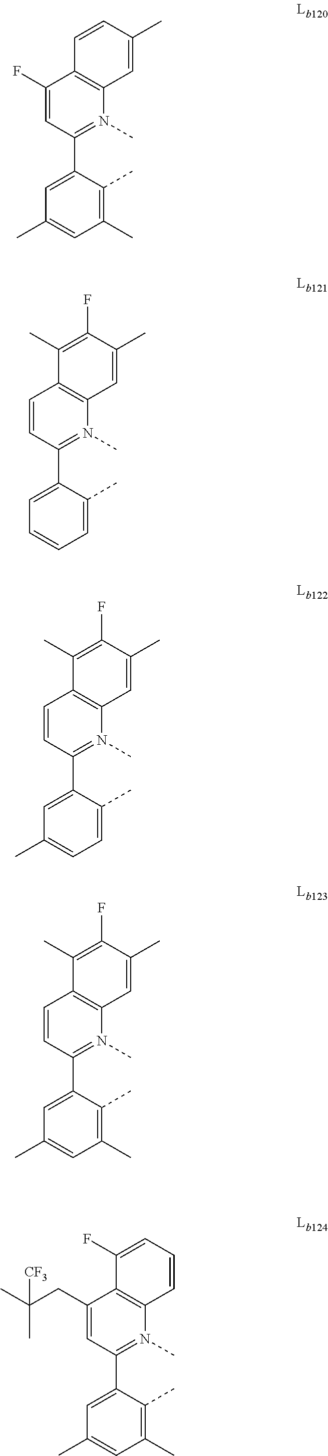

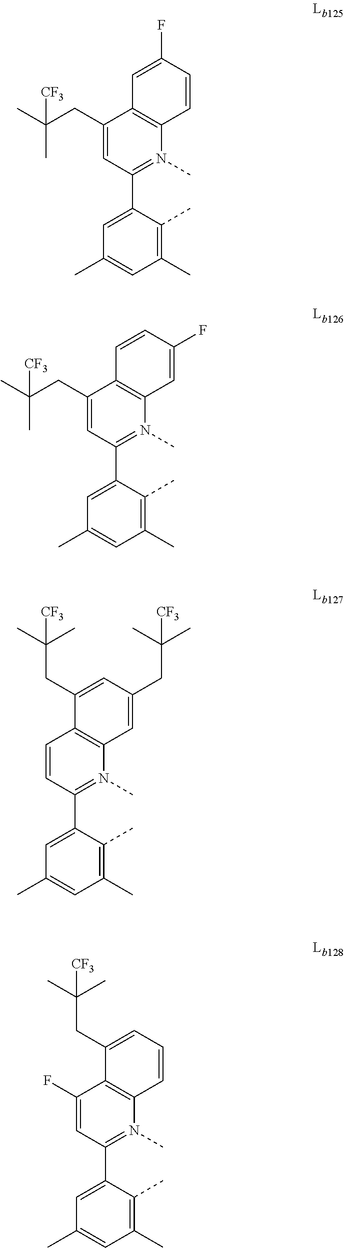

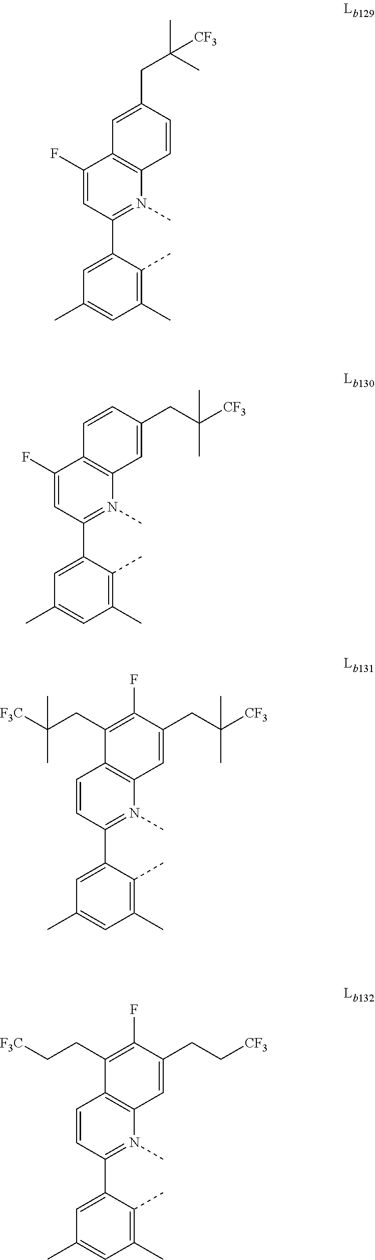

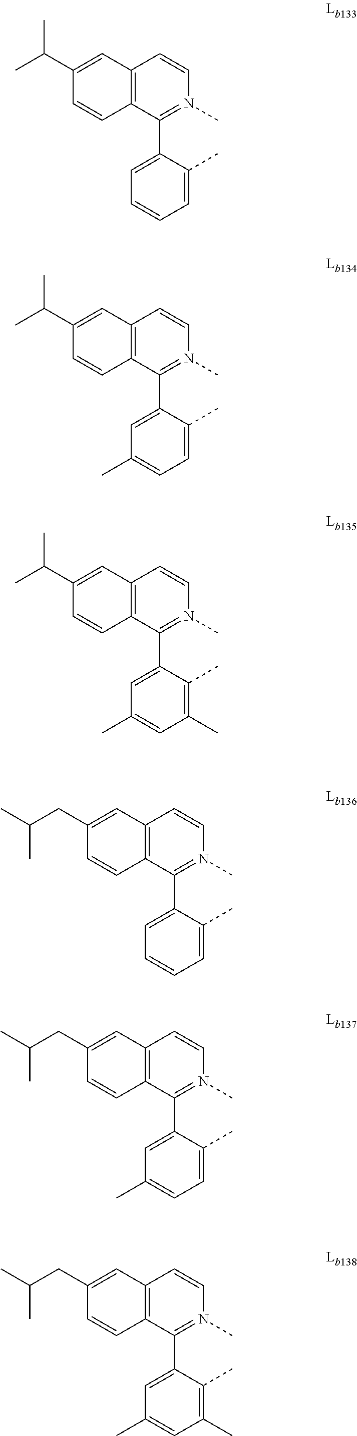

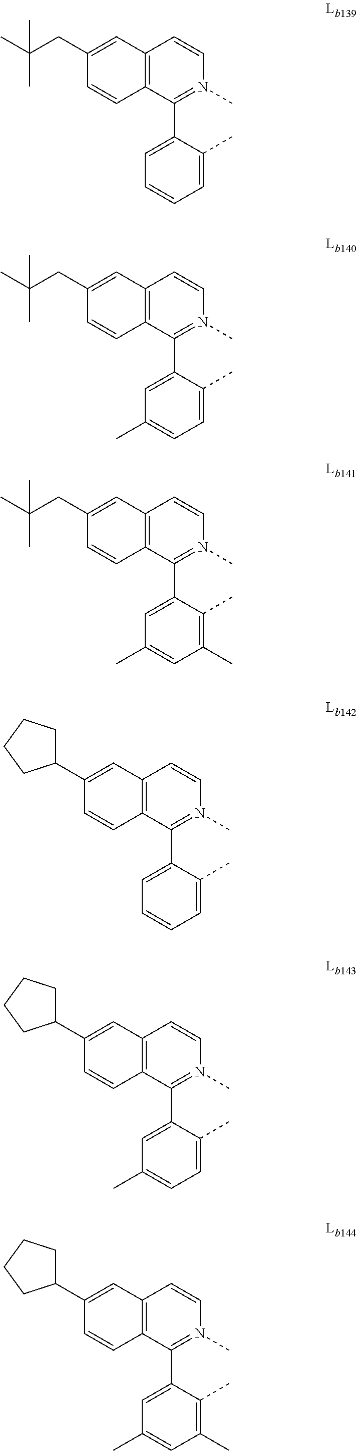

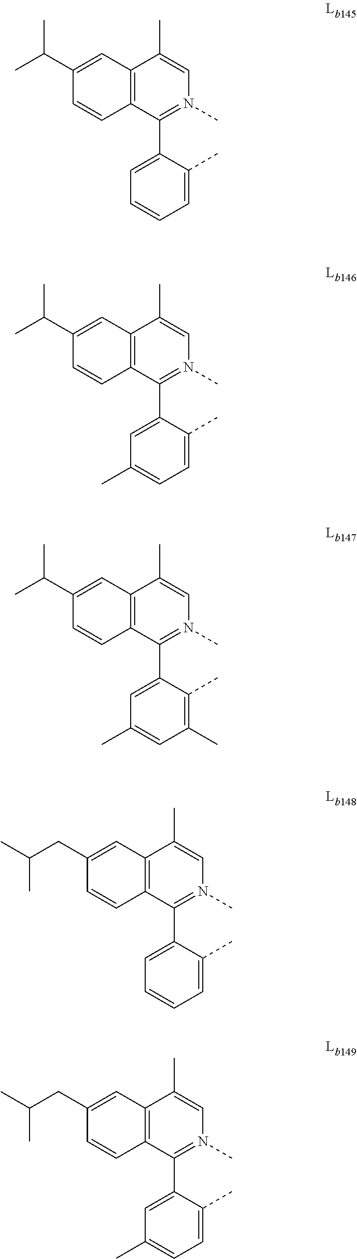

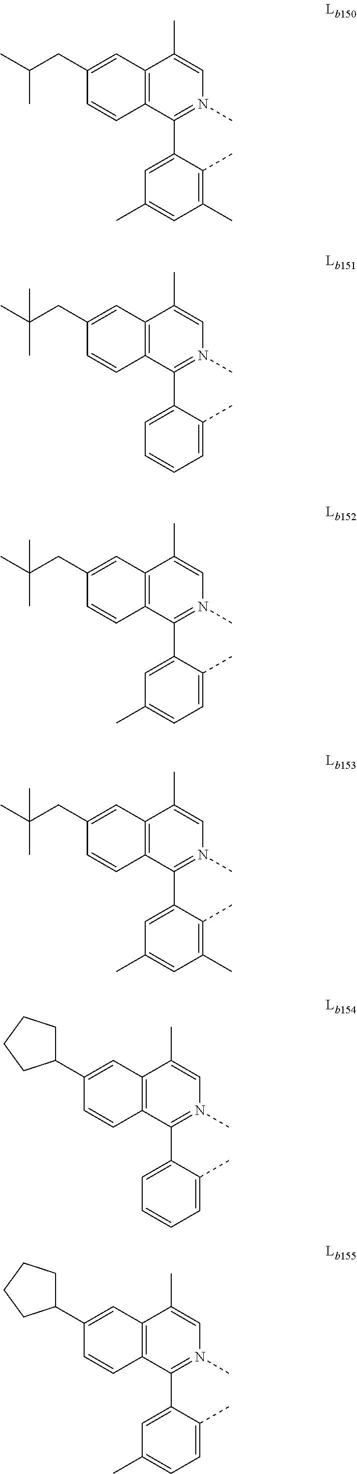

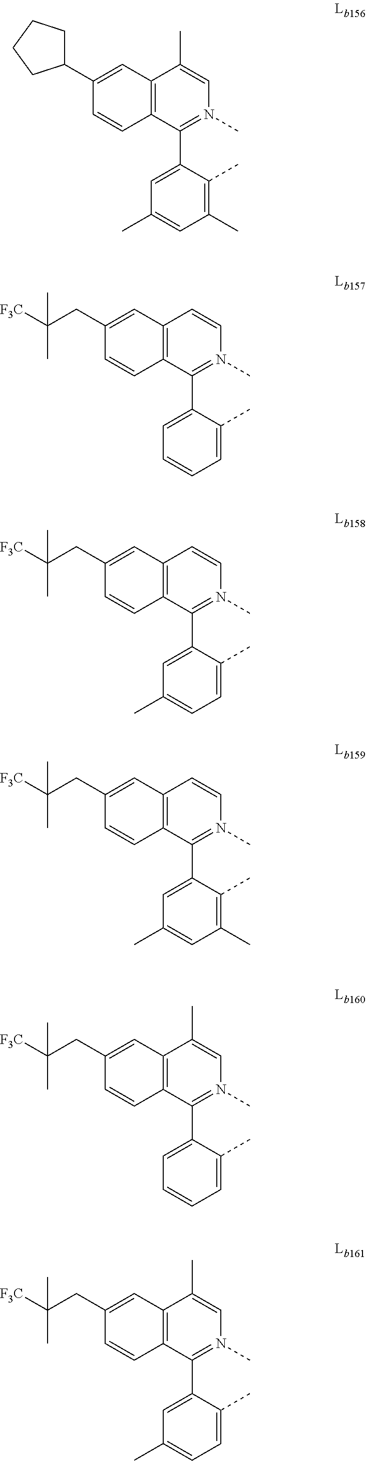

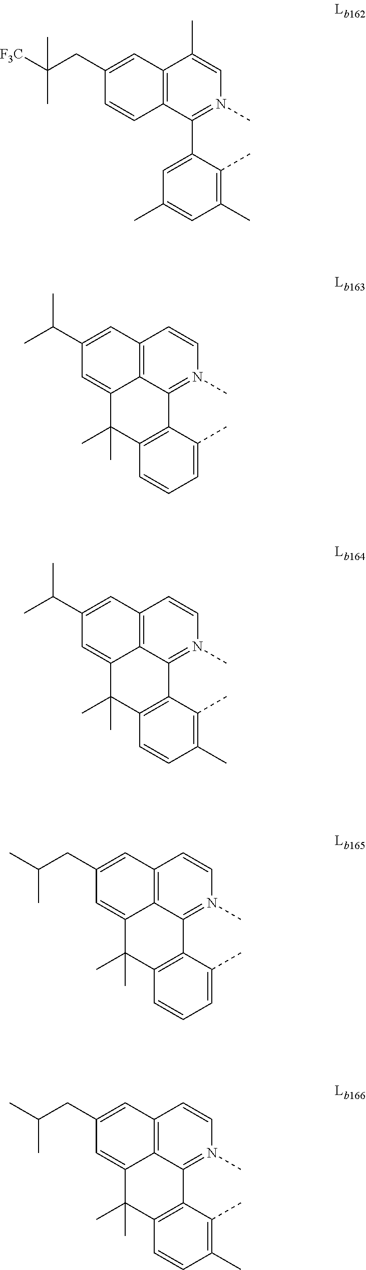

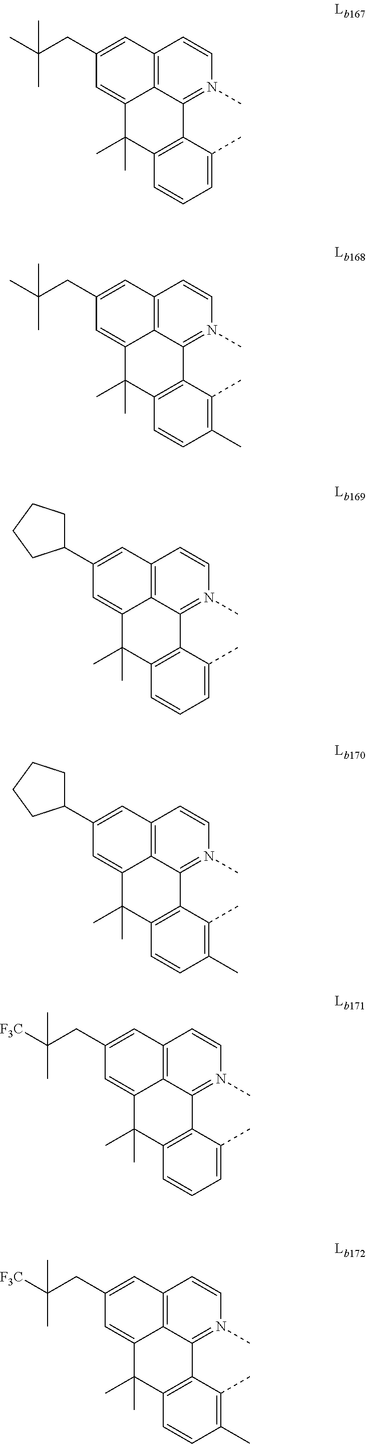

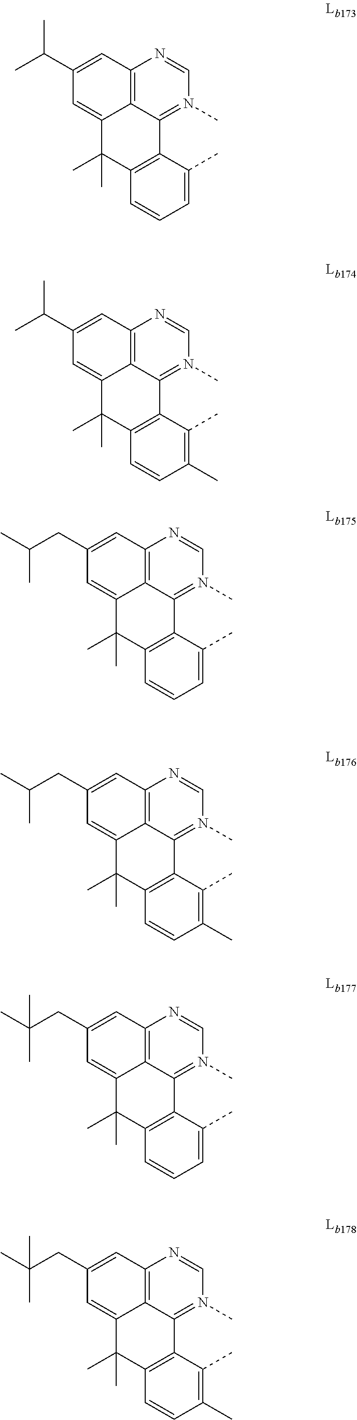

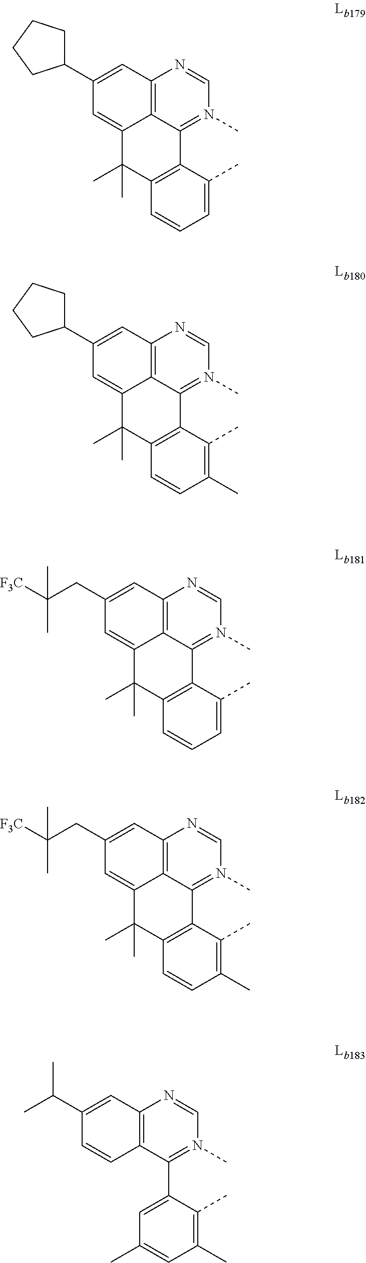

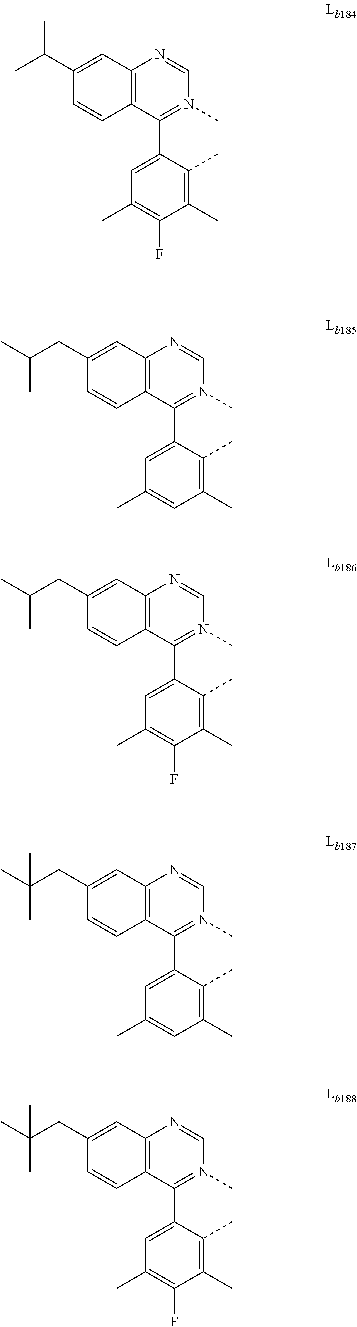

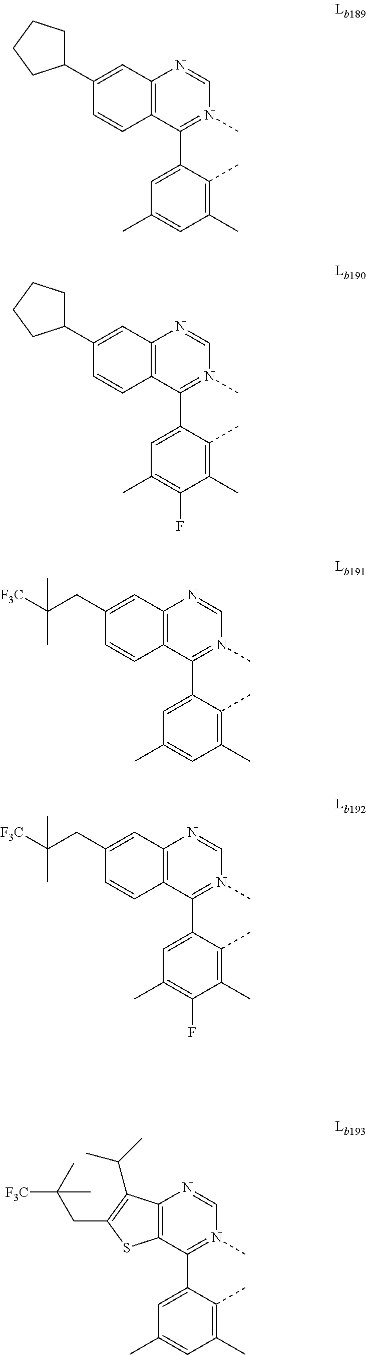

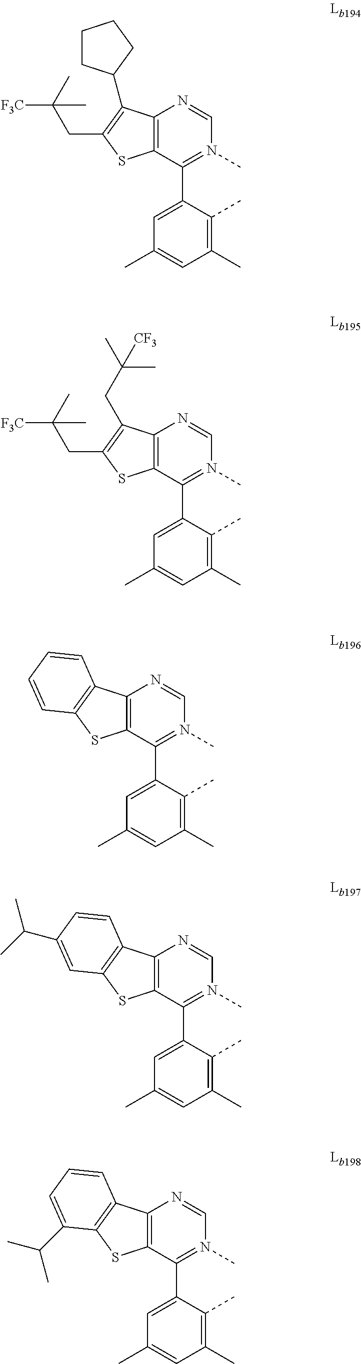

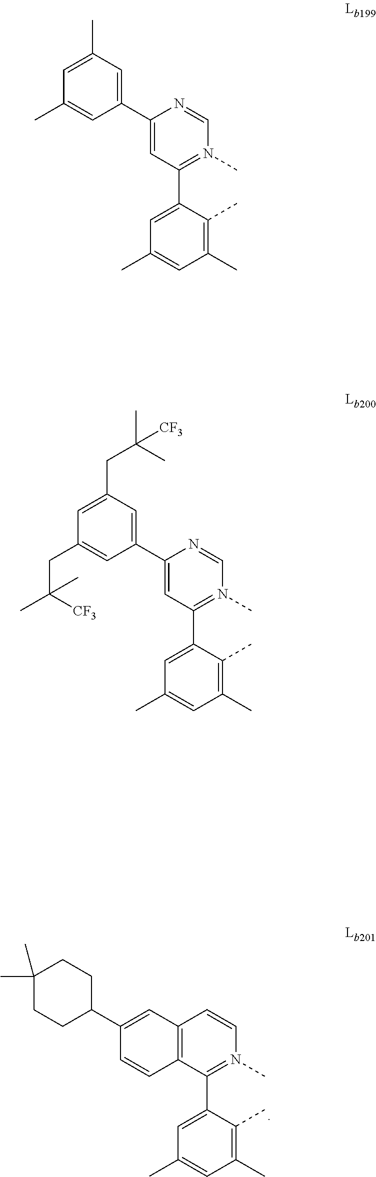

According to an embodiment of the present invention, wherein the ligand Lₐ and/or L_{b} can be partially or fully deuterated.

According to an embodiment of the present invention, wherein the metal complex has the formula of Ir(Lₐ)(L_{b})₂, wherein Lₐ is selected from anyone of the group consisting of Lₐ₁ to Lₐ₂₈₀, L_{b} is selected from anyone or both of the group consisting of L_{b1} to L_{b201}.

According to an embodiment of the present invention, an electroluminescent device is further disclosed, which comprising an anode, a cathode, and an organic layer disposed between the anode and the cathode, wherein the organic layer comprising a metal complex containing the ligand Lₐ represented by formula 1:

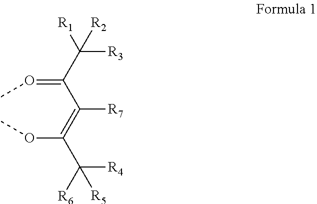

wherein R₁ to R₇ are each independently selected from the group consisting of hydrogen, deuterium, halogen, a substituted or unsubstituted alkyl group having 1 to 20 carbon atoms, a substituted or unsubstituted cycloalkyl group having 3 to 20 ring carbon atoms, a substituted or unsubstituted heteroalkyl group having 1 to 20 carbon atoms, a substituted or unsubstituted arylalkyl group having 7 to 30 carbon atoms, a substituted or unsubstituted alkoxy group having 1 to 20 carbon atoms, a substituted or unsubstituted aryloxy group having 6 to 30 carbon atoms, a substituted or unsubstituted alkenyl group having 2 to 20 carbon atoms, a substituted or unsubstituted aryl group having 6 to 30 carbon atoms, a substituted or unsubstituted heteroaryl group having 3 to 30 carbon atoms, a substituted or unsubstituted alkylsilyl group having 3 to 20 carbon atoms, a substituted or unsubstituted arylsilyl group having 6 to 20 carbon atoms, a substituted or unsubstituted amino group having 0 to 20 carbon atoms, an acyl group, a carbonyl group, a carboxylic acid group, an ester group, a nitrile group, an isonitrile group, a thiol group, a sulfinyl group, a sulfonyl group, a phosphino group, and combinations thereof;

Two adjacent substituents can be optionally joined to form a ring or fused structure;

Wherein between the group consisting of R₁, R₂, R₃ and the group consisting of R₄, R₅, R₆, at least one group is three identical or different substituents;

Wherein the three identical or different substituents all contain at least one carbon atom,

Wherein at least one of the three identical or different substituents contains at least two carbon atoms.

According to an embodiment of the present invention, wherein the organic layer in the electroluminescent device is an emissive layer and the metal complex is an emitter.

According to an embodiment of the present invention, wherein the device emits red light.

According to an embodiment of the present invention, wherein the device emits white light.

According to an embodiment of the present invention, wherein the organic layer further comprises a host compound.

According to an embodiment of the present invention, wherein the organic layer further comprises a host compound, the host compound comprises at least one of the chemical groups selected from the group consisting of benzene, biphenyl, pyridine, pyrimidine, triazine, carbazole, azacarbazole, indolocarbazole, dibenzothiophene, azadibenzothiophene, dibenzofuran, azadibenzofuran, dibenzoselenophene, azadibenzoselenophene, triphenylene, azatriphenylene, fluorene, silicon fluorene, naphthalene, quinoline, isoquinoline, quinazoline, quinoxaline, phenanthrene, azaphenanthrene, and combinations thereof.

According to another embodiment of the present invention, a compound formulation comprising a metal complex is further disclosed, wherein the metal complex comprising a ligand Lₐ represented by formula 1. The specific structure of formula 1 is described in any of the above embodiments.

Combination with Other Materials

The materials described herein as useful for a particular layer in an organic light emitting device may be used in combination with a wide variety of other materials present in the device. The combinations of these materials are described in more detail in U.S. Pat. App. No. 20160359122A1 at paragraphs 0132-0161, which are incorporated by reference in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, emissive dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which are incorporated by reference in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatography-mass spectrometer produced by SHIMADZU, gas chromatography-mass spectrometer produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### SYNTHESIS EXAMPLES

The method for preparing the metal complex of the present invention is not limited. The following compounds are exemplified as a typical but non-limiting example, and the synthesis route and preparation method are as follows:

### Synthesis Example 1: Synthesis of Ir(Lₐ₅)(L_{b3})₂

### Step 1: Synthesis of 3,3-dimethylpentan-2-one

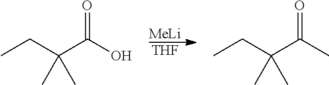

2,2-dimethylbutanoic acid (11.6 g, 100 mmol) was dissolved in 200 mL ultra-dry tetrahydrofuran, bubbling N₂ into the resulting solution for 3 mins, then cooled it to 0° C., 230 mL of 1.3 M methyllithium in diethyl ether solution was added dropwise under N₂ protection and 0° C., after the addition was completed, the reaction mixture was kept stirring for 2 h at 0° C. Then, warmed to room temperature and stirred overnight. After TLC shows the reaction was complete, quenched the reaction by slowly adding 1 M hydrochloric acid, followed by liquid separation, the organic phase was collected, the aqueous phase was extracted twice with dichloromethane, and the organic phase was combined and dried to obtain the target product 3,3-dimethylpentan-2-one (11.0 g, 94% yield).

### Step 2: Synthesis of 2,2-dimethylbutanoyl Chloride

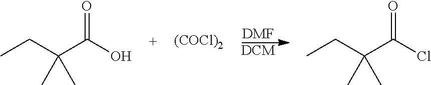

2,2-dimethylbutanoic acid (11.6 g, 100 mmol) was dissolved in 200 mL ultra-dry dichloromethane, then added one drop of ultra-dry DMF as a catalyst, bubbling N₂ into the resulting solution for 3 mins, then cooled it to 0° C. and oxalyl chloride(14.0 g, 110 mmol) was added dropwise under N₂ protection and 0° C. After the addition was completed, the solution was warmed to room temperature, when there is no gas released in the reaction system, distilled under reduced pressure, then give the crude product 2,2-dimethylbutanoyl chloride, this can be used directly in the next reaction without further purification

### Step 3: Synthesis of 3,3,7,7-tetramethylnonane-4,6-dione

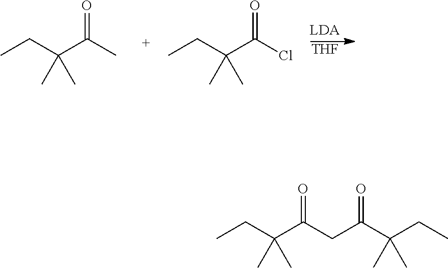

3,3-dimethylpentan-2-one (11.0 g, 96 mmol) was dissolved in 200 mL ultra-dry tetrahydrofuran, bubbling N₂ into the resulting solution for 3 mins, then cooled it to −78° C., 53 mL of 2 M lithium diisopropylamide in tetrahydrofuran solution was added dropwise under N₂ protection and −78° C., after the addition was completed, the reaction mixture was kept stirring for 30 mins at −78° C., then added 2,2-dimethylbutanoyl chloride obtained in step 2 slowly. After the addition was completed, the solution was warmed to room temperature and kept stirring for overnight. Then quenched the reaction by slowly adding 1 M hydrochloric acid, followed by liquid separation, the organic phase was collected, the aqueous phase was extracted twice with dichloromethane, and the organic phase was combined and dried to give the crude product. The crude product was purified by column chromatography (eluting with PE), then distilled under reduced pressure to the obtain target product 3,3,7,7-tetramethylnonane-4,6-dione (3.6 g, 18% yield).

### Step 4: Synthesis of Iridium Dimer

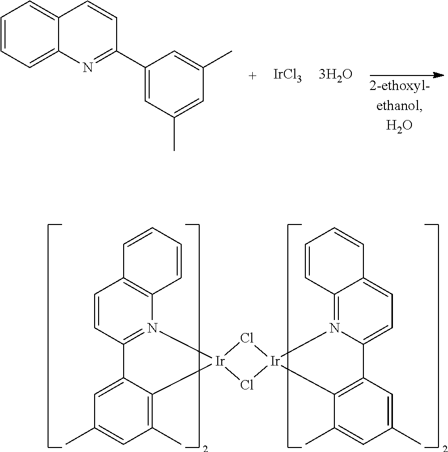

The mixture of 2-(3,5-dimethylphenyl)quinoline (2.6 g, 11.3 mmol), iridium chloride trihydrate (800 mg, 2.3 mmol), 2-ethoxyethanol (24 mL) and water (8 mL) were refluxed under a nitrogen atmosphere for 24 hours. After the reaction cooled to room temperature, distilled under reduced pressure, then give the crude product iridium dimer, this can be used directly in the next reaction without further purification.

### Step 5: Synthesis of Ir(Lₐ₅)(L_{b3})₂

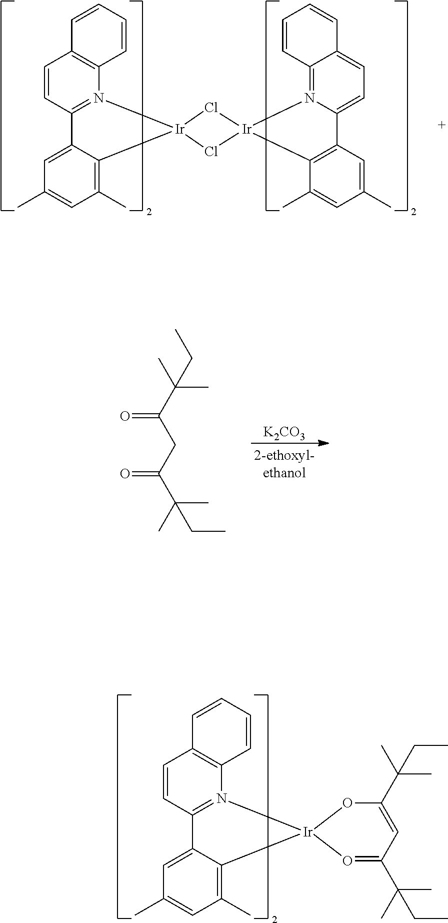

The mixture of 3,3,7,7-tetramethylnonane-4,6-dione (977 mg, 4.6 mmol), iridium dimer (1.15 mmol), potassium carbonate (1.6 g, 11.5 mmol), and 2-ethoxyethanol (32 mL) were stirring at room temperature under a nitrogen atmosphere for 24 hours. Precipitate was filtered with diatomite and washed with ethanol. Dichloromethane was added to the obtained solid and the filtrate was collected. Then added ethanol and concentrated the resulting solution, but did not concentrate dry. After filtration, 1.3 g of crude product was obtained. The crude product was further purified by column chromatography. The structure of the compound was confirmed as the target product by NMR and LC-MS, with a molecular weight of 868.

### Synthesis Example 2: Synthesis of Ir(Lₐ₂₆)(L_{b3})₂

### Step 1: Synthesis of ethyl 2-ethyl-2-methylbutanoate

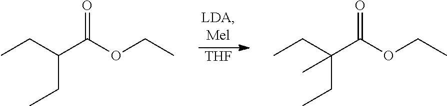

ethyl 2-ethylbutanoate (50.0 g, 346 mmol) was dissolved in 600 mL ultra-dry tetrahydrofuran, bubbling N₂ into the resulting solution for 3 mins, then cooled it to −78° C., 190 mL of 2 M lithium diisopropylamide in tetrahydrofuran solution was added dropwise under N₂ protection and −78° C., after the addition was completed, the reaction mixture was kept stirring for 30 mins at −78° C., then added methyl iodide (58.9 g, 415 mmol) slowly. After the addition was completed, the solution was warmed to room temperature and kept stirring for overnight. Then quenched the reaction by slowly adding saturated ammonium chloride solution, followed by liquid separation, the organic phase was collected, the aqueous phase was extracted twice with dichloromethane, and the organic phase was combined, dried and concentrated to give the product ethyl 2-ethyl-2-methylbutanoate (52.2 g, 95% yield).

### Step 2: Synthesis of 2-ethyl-2-methylbutanoic Acid

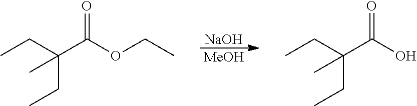

ethyl 2-ethyl-2-methylbutanoate (52.2 g, 330 mmol) was dissolved in methanol, then added sodium hydroxide (39.6 g, 990 mmol), the mixture was heated to reflux for 12 h, After the reaction cooled to room temperature, the methanol was removed under reduced pressure, adjust the pH of the reaction solution to 1 by adding 3M hydrochloric acid, then extracted with dichloromethane. The combined organic layers dried, then concentrated to obtain 2-ethyl-2-methylbutanoic acid (41.6 g, 97% yield).

### Step 3: Synthesis of 3-ethyl-3-methylpentan-2-one

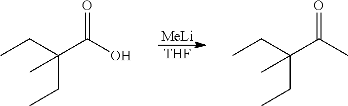

2-ethyl-2-methylbutanoic acid (13.0 g, 100 mmol) was dissolved in 200 mL ultra-dry tetrahydrofuran, bubbling N₂ into the resulting solution for 3 mins, then cooled it to 0° C., 230 mL of 1.3 M methyllithium in diethyl ether solution was added dropwise under N₂ protection and 0° C., after the addition was completed, the reaction mixture was kept stirring for 2 h at 0° C. Then, warmed to room temperature and stirred overnight. After TLC shows the reaction was complete, quenched the reaction by slowly adding 1 M hydrochloric acid, followed by liquid separation, the organic phase was collected, the aqueous phase was extracted twice with dichloromethane, and the organic phase was combined, dried and concentrated to obtain the target product 3-ethyl-3-methylpentan-2-one (11.8 g, 92% yield).

### Step 4: Synthesis of 2-ethyl-2-methylbutanoyl Chloride

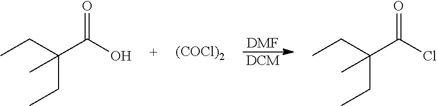

2-ethyl-2-methylbutanoic acid (13.0 g, 100 mmol) was dissolved in 200 mL ultra-dry dichloromethane, then added one drop of ultra-dry DMF as a catalyst, bubbling N₂ into the resulting solution for 3 mins, then cooled it to 0° C. and oxalyl chloride(14.0 g, 110 mmol) was added dropwise under N₂ protection and 0° C. After the addition was completed, the solution was warmed to room temperature, when there is no gas released in the reaction system, distilled under reduced pressure, then give the crude product 2-ethyl-2-methylbutanoyl chloride, this can be used directly in the next reaction without further purification.

### Step 5: Synthesis of 3,7-diethyl-3,7-dimethylnonane-4,6-dione

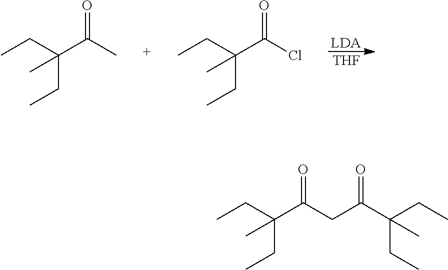

3-ethyl-3-methylpentan-2-one (11.8 g, 92 mmol) was dissolved in ultra-dry tetrahydrofuran, bubbling N₂ into the resulting solution for 3 mins, then cooled it to −78° C., 51 mL of 2 M lithium diisopropylamide in tetrahydrofuran solution was added dropwise under N₂ protection and −78° C., after the addition was completed, the reaction mixture was kept stirring for 30 mins at −78° C., then added 2-ethyl-2-methylbutanoyl chloride obtained in step 4 slowly. After the addition was completed, the solution was warmed to room temperature and kept stirring for overnight. Then quenched the reaction by slowly adding 1 M hydrochloric acid, followed by liquid separation, the organic phase was collected, the aqueous phase was extracted twice with dichloromethane, and the organic phase was combined and dried to give the crude product. The crude product was purified by column chromatography (eluting with PE), then distilled under reduced pressure to obtain the target product 3,7-diethyl-3,7-dimethylnonane-4,6-dione (4.6 g, 21% yield).

### Step 6: Synthesis of Ir(Lₐ₂₆)(L_{b3})₂

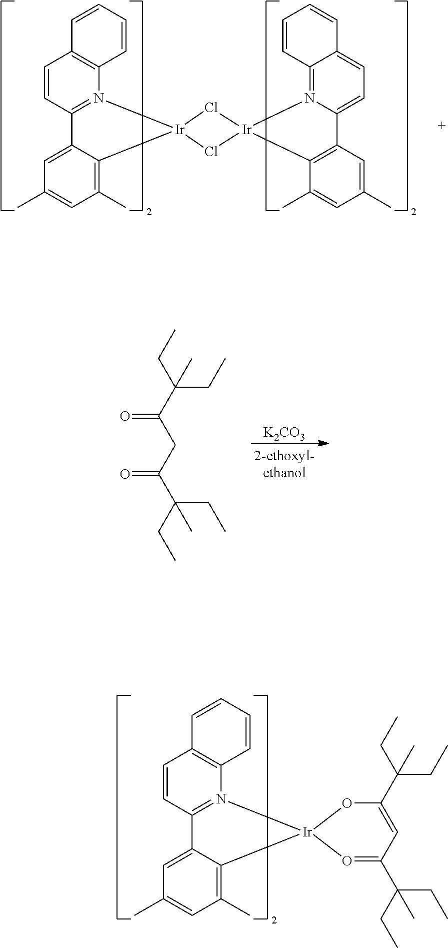

The mixture of 3,7-diethyl-3,7-dimethylnonane-4,6-dione (1.1 g, 4.6 mmol), iridium dimer (1.15 mmol), potassium carbonate (1.6 g, 11.5 mmol), and 2-ethoxyethanol (30 mL) were stirring at room temperature under a nitrogen atmosphere for 24 hours. The precipitate was filtered with diatomite and washed with ethanol. Dichloromethane was added to the obtained solid and the filtrate was collected. Then added ethanol and concentrated the resulting solution, but did not concentrate dry. After filtration, 1.4 g of crude product was obtained. The crude product was further purified by column chromatography. The structure of the compound was confirmed as the target product by NMR and LC-MS, with a molecular weight of 896.

### Synthesis Example 3: Synthesis of Ir(Lₐ₆)(L_{b3})₂

### Step 1: Synthesis of 2-ethylbutanoyl Chloride

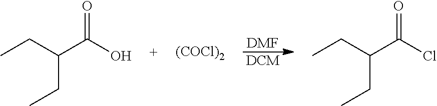

2-ethylbutanoic acid (11.6 g, 100 mmol) was dissolved in ultra-dry dichloromethane, then added one drop of ultra-dry DMF as a catalyst, bubbling N₂ into the resulting solution for 3 mins, then cooled it to 0° C. and oxalyl chloride(14.0 g, 110 mmol) was added dropwise under N₂ protection and 0° C. After the addition was completed, the solution was warmed to room temperature, when there is no gas released in the reaction system, distilled under reduced pressure, then give the crude product 2-ethylbutanoyl chloride, this can be used directly in the next reaction without further purification.

### Step 2: Synthesis of 7-ethyl-3,3-dimethylnonane-4,6-dione

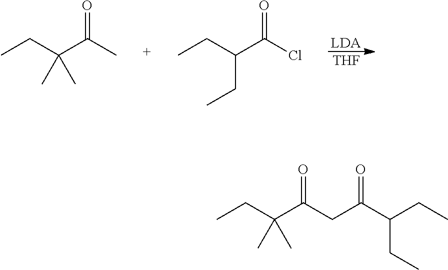

3,3-dimethylpentan-2-one (10.3 g, 90 mmol) was dissolved in 180 mL ultra-dry tetrahydrofuran, bubbling N₂ into the resulting solution for 3 mins, then cooled it to −78° C., 53 mL of 2 M lithium diisopropylamide in tetrahydrofuran solution was added dropwise under N₂ protection and −78° C., after the addition was completed, the reaction mixture was kept stirring for 30 mins at −78° C., then added 2-ethylbutanoyl chloride obtained in step 1 slowly. After the addition was completed, the solution was slowly warmed to room temperature overnight. Then quenched the reaction by slowly adding 1 M hydrochloric acid, followed by liquid separation, the organic phase was collected, the aqueous phase was extracted twice with dichloromethane, and the organic phase was combined and dried to give the crude product. The crude product was purified by column chromatography (eluting with PE), then distilled under reduced pressure to obtain the target product 7-ethyl-3,3-dimethylnonane-4,6-dione (4.2 g, 22% yield).

### Step 3: Synthesis of Ir(Lₐ₆)(L_{b3})₂

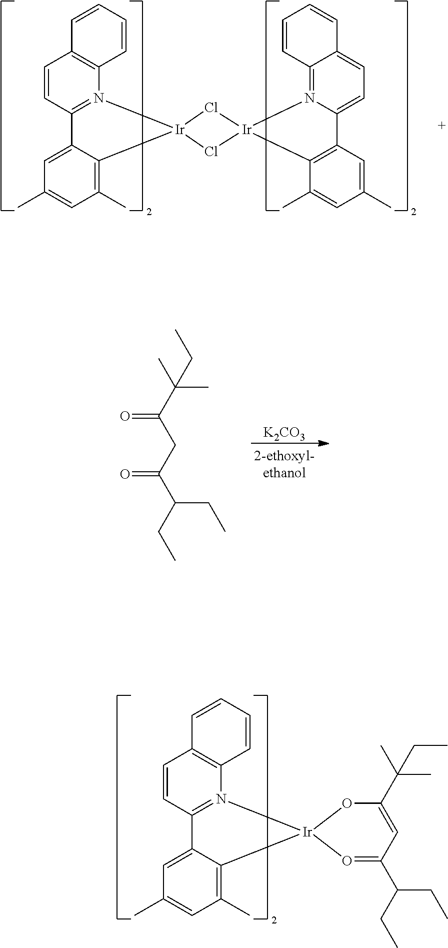

The mixture of 7-ethyl-3,3-dimethylnonane-4,6-dione (977 mg, 4.6 mmol), iridium dimer (1.15 mmol), potassium carbonate (1.6 g, 11.5 mmol), and 2-ethoxyethanol (30 mL) were stirring at room temperature under a nitrogen atmosphere for 24 hours. Precipitate was filtered with diatomite and washed with ethanol. Dichloromethane was added to the obtained solid and the filtrate was collected. Then added ethanol and concentrated the resulting solution, but did not concentrate dry. After filtration, 1.3 g of crude product was obtained. The crude product was further purified by column chromatography. The structure of the compound was confirmed as the target product by NMR and LC-MS, with a molecular weight of 868.

### Synthesis Example 4: Synthesis of Ir(Lₐ₂₁)(L_{b3})₂

### Step 1: Synthesis of 3,7-diethyl-3-methylnonane-4,6-dione

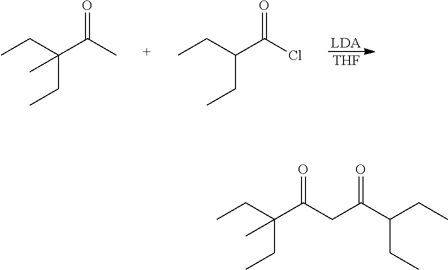

3-ethyl-3-methylpentan-2-one (11.8 g, 92 mmol) was dissolved in ultra-dry tetrahydrofuran, bubbling N₂ into the resulting solution for 3 mins, then cooled it to −78° C., 55 mL of 2 M lithium diisopropylamide in tetrahydrofuran solution was added dropwise under N₂ protection and −78° C., after the addition was completed, the reaction mixture was kept stirring for 30 mins at −78° C., then added 2-ethylbutanoyl chloride obtained in step 1 of Synthesis Example 3 slowly. After the addition was completed, the solution was slowly warmed to room temperature overnight. Then quenched the reaction by slowly adding 1 M hydrochloric acid, followed by liquid separation, the organic phase was collected, the aqueous phase was extracted twice with dichloromethane, and the organic phase was combined and dried to give the crude product. The crude product was purified by column chromatography (eluting with PE), then distilled under reduced pressure to obtain the target product 3,7-diethyl-3-methylnonane-4,6-dione (4.7 g, 23% yield).

### Step 2: Synthesis of Ir(Lₐ₂₁)(L_{b3})₂

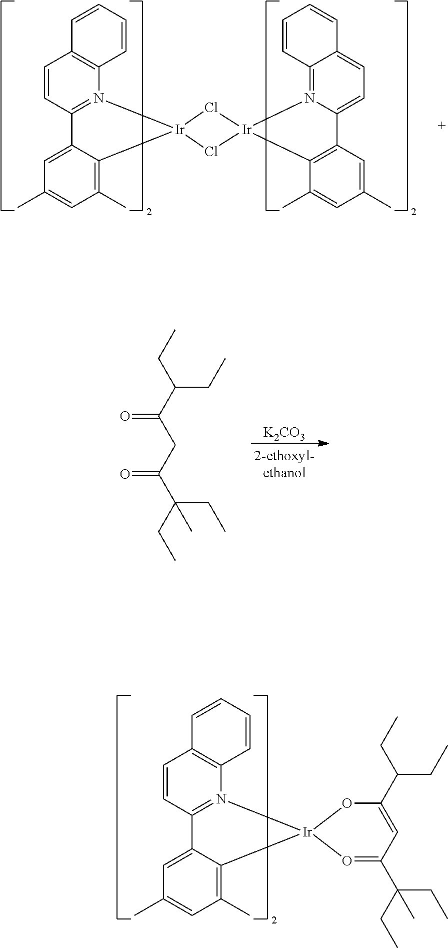

The mixture of 3,7-diethyl-3-methylnonane-4,6-dione (1.0 g, 4.6 mmol), iridium dimer (1.15 mmol), potassium carbonate (1.6 g, 11.5 mmol), and 2-ethoxyethanol (30 mL) were stirring at room temperature under a nitrogen atmosphere for 24 hours. Precipitate was filtered with diatomite and washed with ethanol. Dichloromethane was added to the obtained solid and the filtrate was collected. Then added ethanol and concentrated the resulting solution, but did not concentrate dry. After filtration, 1.5 g of crude product was obtained. The crude product was further purified by column chromatography. The structure of the compound was confirmed as the target product by NMR and LC-MS, with a molecular weight of 882.

### Synthesis Example 5: Synthesis of Ir(Lₐ₂₆)(L_{b135})₂

### Step 1: Synthesis of Iridium Dimer

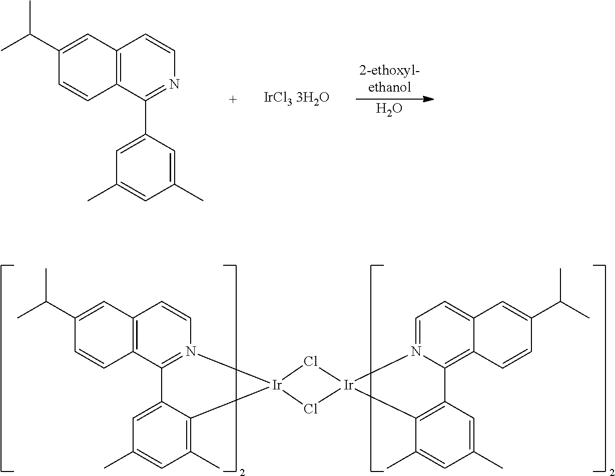

The mixture of 1-(3,5-dimethylphenyl)-6-isopropylisoquinoline (2.0 g, 7.3 mmol), iridium chloride trihydrate (854 mg, 2.4 mmol), 2-ethoxyethanol (24 mL) and water (8 mL) was refluxed under a nitrogen atmosphere for 24 hours. After the reaction cooled to room temperature, filtration, and washed the obtained solid several times with methanol, dried to obtain a iridium dimer (1.3 g, 70% yield).

### Step 2: Synthesis of Ir(Lₐ₂₆)(L_{b135})₂

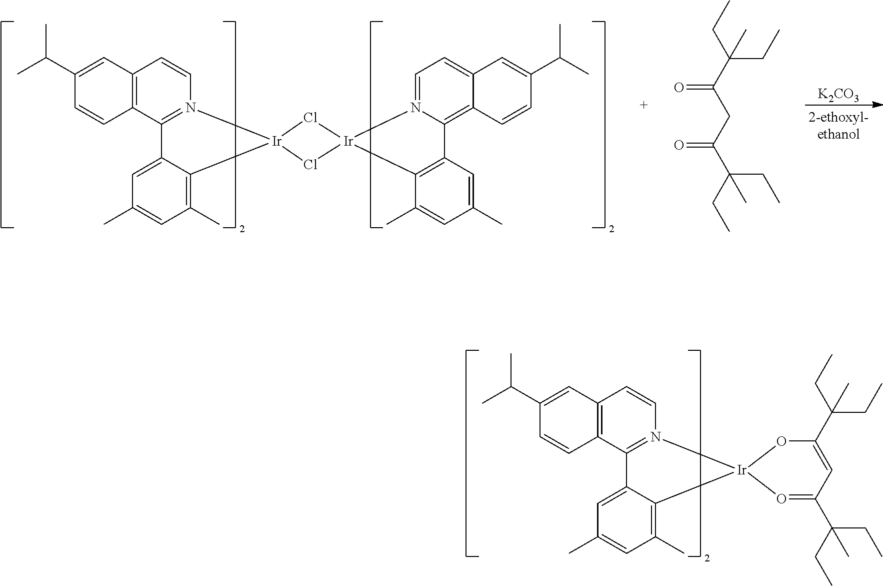

The mixture of 3,7-diethyl-3,7-dimethylnonane-4,6-dione (769 mg, 3.2 mmol), iridium dimer (1.3 g, 0.8 mmol), potassium carbonate (1.1 g, 8.0 mmol), and 2-ethoxyethanol (20 mL) were stirring at room temperature under a nitrogen atmosphere for 24 hours. Precipitate was filtered with diatomite and washed with ethanol. Dichloromethane was added to the obtained solid and the filtrate was collected. Then added ethanol and concentrated the resulting solution, but did not concentrate dry. After filtration, 1.2 g of crude product was obtained. The crude product was further purified by column chromatography. The structure of the compound was confirmed as the target product by NMR and LC-MS, with a molecular weight of 980.

The persons skilled in the art should know that the above preparation method is only an illustrative example, and the persons skilled in the art can obtain the structure of other compounds of the present invention by modifying the above preparation method.

Device Example

A glass substrate with 120 nm thick indium-tin-oxide (ITO) anode was first cleaned and then treated with oxygen plasma and UV ozone. After the treatments, the substrate was baked dry in a glovebox to remove moisture. The substrate was then mounted on a substrate holder and loaded into a vacuum chamber. The organic layers specified below were deposited in sequence by thermal vacuum deposition on the ITO anode at a rate of 0.2-2 Å/s at a vacuum of around 10⁻⁸ torr. Compound HI was used as the hole injection layer (HIL). Compound HT was used as the hole transporting layer (HTL). Compound EB was used as the electron blocking layer (EBL). Then the inventive compound or the comparative compound was doped in the host Compound RH as the emitting layer (EML). Compound HB was used as hole blocking layer (HBL). On HBL, a mixture of Compound ET and 8-Hydroxyquinolinolato-lithium (Liq) was deposited as the electron transporting layer (ETL). Finally, 1 nm-thick Liq was deposited as the electron injection layer and 120 nm of Al was deposited as the cathode. The device was then transferred back to the glovebox and encapsulated with a glass lid and a moisture getter to complete the device.

The detailed device layer structure and thicknesses are shown in the table below. In the layers in which more than one material were used, they were obtained by doping different compounds in the weight ratios described therein.

TABLE 1
Device structure of device examples

| Device ID | HIL | HTL | EBL | EML | HBL | ETL |
|---|---|---|---|---|---|---|
| Example 1 | Compound | Compound | Compound | Compound RH:Compound | Compound | Compound |
| | HI | HT | EB | Ir(Lₐ₅)(L_{b3})₂ (97:3) | HB | ET:Liq |
| | (100 Å) | (400 Å) | (50 Å) | (400 Å) | (50 Å) | (35:65) |
| | | | | | | (350 Å) |
| Example 2 | Compound | Compound | Compound | Compound RH:Compound | Compound | Compound |
| | HI | HT | EB | Ir(Lₐ₂₆)(L_{b3})₂ | HB | ET:Liq |
| | (100 Å) | (400 Å) | (50 Å) | (97:3) (400 Å) | (50 Å) | (35:65) |
| | | | | | | (350 Å) |
| Example 3 | Compound | Compound | Compound | Compound RH:Compound | Compound | Compound |
| | HI | HT | EB | Ir(Lₐ₆)(L_{b3})₂ (97:3) | HB | ET:Liq |
| | (100 Å) | (400 Å) | (50 Å) | (400 Å) | (50 Å) | (35:65) |
| | | | | | | (350 Å) |
| Example 4 | Compound | Compound | Compound | Compound RH:Compound | Compound | Compound |
| | HI | HT | EB | Ir(Lₐ₂₁)(L_{b3})₂ | HB | ET:Liq |
| | (100 Å) | (400 Å) | (50 Å) | (97:3) (400 Å) | (50 Å) | (35:65) |
| | | | | | | (350 Å) |
| Example 5 | Compound | Compound | Compound | Compound RH:Compound | Compound | Compound |
| | HI | HT | EB | Ir(Lₐ₂₆)(L_{b135})₂ | HB | ET:Liq |
| | (100 Å) | (400 Å) | (50 Å) | (98:2) (400 Å) | (50 Å) | (35:65) |
| | | | | | | (350 Å) |
| Comparative | Compound | Compound | Compound | Compound RH:Compound A | Compound | Compound |
| Example 1 | HI | HT | EB | (97:3) (400 Å) | HB | ET:Liq |
| | (100 Å) | (400 Å) | (50 Å) | | (50 Å) | (35:65) |
| | | | | | | (350 Å) |
| Comparative | Compound | Compound | Compound | Compound RH:Compound B | Compound | Compound |
| Example 2 | HI | HT | EB | (97:3) (400 Å) | HB | ET:Liq |
| | (100 Å) | (400 Å) | (50 Å) | | (50 Å) | (35:65) |
| | | | | | | (350 Å) |

Structure of the materials used in the devices are shown as below:

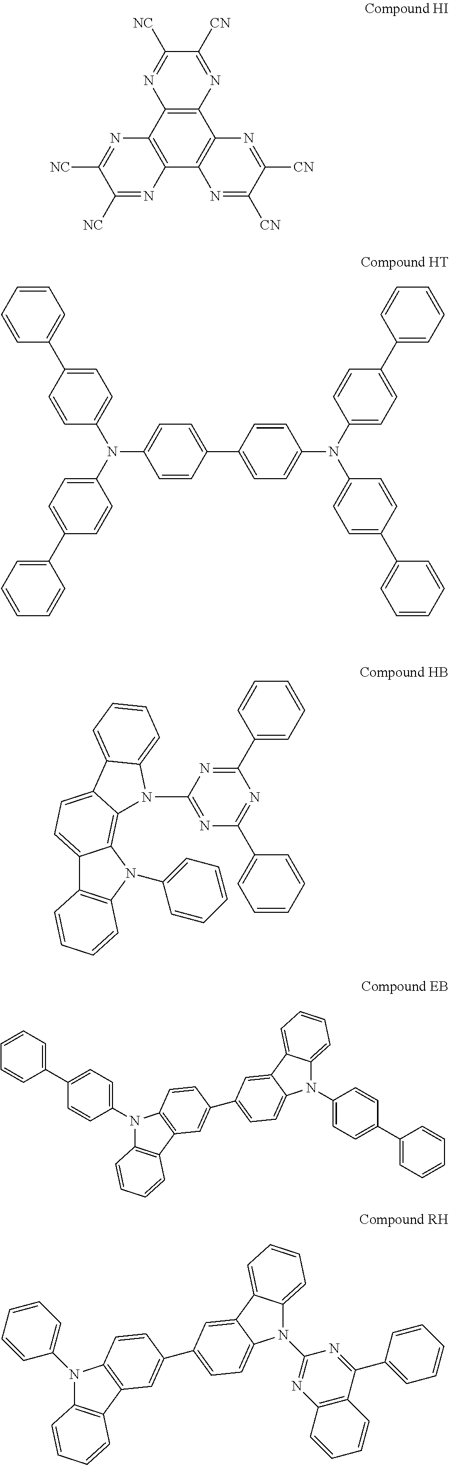 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2nc(-c3ccccc3)nc(-n3c4ccccc4c4ccc5c6ccccc6n(-c6ccccc6)c5c43)n2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-n3c4ccccc4c4cc(-c5ccc6c(c5)c5ccccc5n6-c5ccccc5)ccc43)nc3ccccc23)cc1]

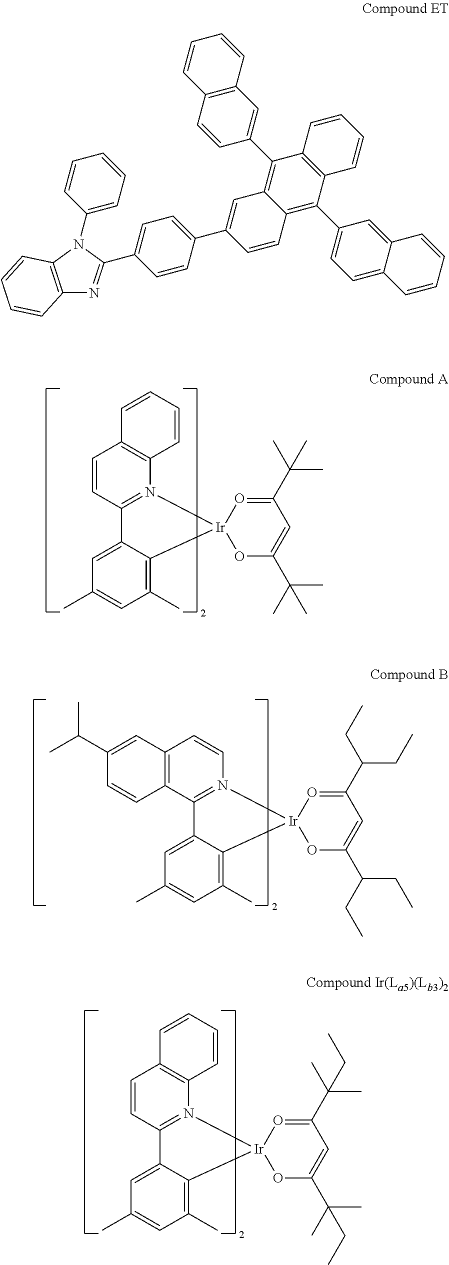

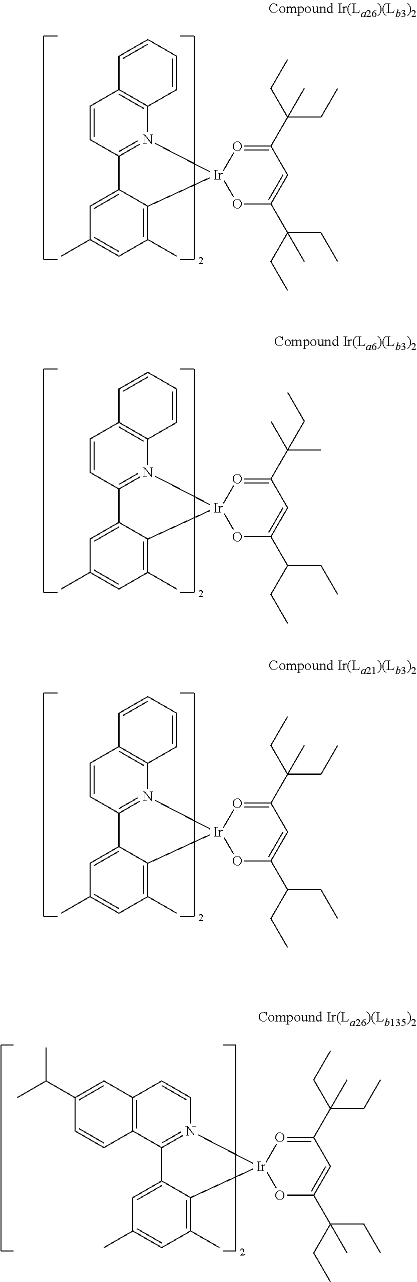

The IVL characteristics of the devices were measured at various current densities and voltages. The luminous efficiency (LE), external quantum efficiency (EQE), maximum emission wavelength (λₘₐₓ), full width at half maximum (FWHM), voltage (V) and CIE data were measured at 1000 nits. Sublimation temperature (Sub T) of material was tested.

TABLE 2
Device data

| | Sub T | | | FWHM | Voltage | LE | |
|---|---|---|---|---|---|---|---|
| Device ID | (° C.) | CIE (x, y) | λₘₐₓ (nm) | (nm) | (V) | (cd/A) | EQE (%) |
| Example 1 | 207 | (0.663, 0.336) | 618 | 56.4 | 3.58 | 28.83 | 22.44 |
| Example 2 | 195 | (0.662, 0.337) | 617 | 55.4 | 3.58 | 27.21 | 22.31 |
| Example 3 | 187 | (0.659, 0.340) | 617 | 55.5 | 3.72 | 28.29 | 22.3 |
| Example 4 | 188 | (0.660, 0.339) | 617 | 54.8 | 3.41 | 27.98 | 22.17 |
| Example 5 | 203 | (0.683, 0.316) | 625 | 48.0 | 4.09 | 22.83 | 26.63 |
| Comparative | 202 | (0.661, 0.338) | 619 | 57.3 | 3.63 | 26.57 | 21.91 |
| Example 1 | | | | | | | |
| Comparative | 226 | (0.683, 0.316) | 625 | 49.9 | 4.48 | 22.34 | 26.23 |
| Example 2 | | | | | | | |

### DISCUSSION

From the data in table 2, it can be clearly seen that device examples with compounds of the invention show several advantages over comparative compounds. Compared to comparative compounds, the inventive compounds have a narrower FWHM, higher EQE, and are able to produce a redshift effect. For example, Example 1 compared to Comparative Example 1, they all have the same quinoline ligand, but by means of the invention, Example 1 achieves a deeper red emission, EQE and LE are higher the same time. Example 5 compared to Comparative Example 2, they all have the same isoquinoline ligand, but by means of the invention, Example 5 only needs 2% red emitter material doping, and has reached the deep red color which is required by 3% red emitter material in the comparative example, at the same time, its EQE and LE are higher. In addition, metal complexes with isoquinoline ligand have higher sublimation temperature, but by means of the invention, the sublimation temperature of the red emitter material Ir(Lₐ₂₆)L_{b135})₂ of Example 5 is 23° C. lower than the red emitter material Compound B of Comparative Example 2.

It is understood that the various embodiments described herein are by way of example only, and are not intended to limit the scope of the invention. The present invention as claimed may therefore include variations from the particular examples and preferred embodiments described herein, as will be apparent to one of skill in the art. Many of the materials and structures described herein may be substituted with other materials and structures without deviating from the spirit of the invention. It is understood that various theories as to why the invention works are not intended to be limiting.

What is claimed is:

1. A metal complex comprising a ligand Lₐ represented by Formula 1: 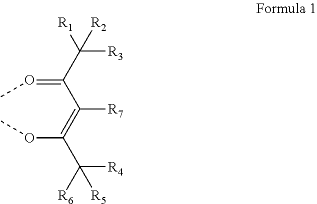
wherein R₁ to R₇ are each independently selected from the group consisting of hydrogen, deuterium, halogen, a substituted or unsubstituted alkyl group having 1 to 20 carbon atoms, a substituted or unsubstituted cycloalkyl group having 3 to 20 ring carbon atoms, a substituted or unsubstituted heteroalkyl group having 1 to 20 carbon atoms, a substituted or unsubstituted arylalkyl group having 7 to 30 carbon atoms, a substituted or unsubstituted alkoxy group having 1 to 20 carbon atoms, a substituted or unsubstituted aryloxy group having 6 to 30 carbon atoms, a substituted or unsubstituted alkenyl group having 2 to 20 carbon atoms, a substituted or unsubstituted aryl group having 6 to 30 carbon atoms, a substituted or unsubstituted heteroaryl group having 3 to 30 carbon atoms, a substituted or unsubstituted alkylsilyl group having 3 to 20 carbon atoms, a substituted or unsubstituted arylsilyl group having 6 to 20 carbon atoms, a substituted or unsubstituted amino group having 0 to 20 carbon atoms, an acyl group, a carbonyl group, a carboxylic acid group, an ester group, a nitrile group, an isonitrile group, a thiol group, a sulfinyl group, a sulfonyl group, a phosphino group, and combinations thereof;
two adjacent substituents can be optionally joined to form a ring or fused structure;
wherein between the group consisting of R₁, R₂, R₃ and the group consisting of R₄, R₅, R₆, at least one group is three identical or different substituents,
wherein the three identical or different substituents all contain at least one carbon atom,
wherein at least one of the three identical or different substituents contains at least two carbon atoms.

2. The metal complex of claim 1, wherein the metal is selected from the group consisting of copper, silver, gold, ruthenium, rhodium, palladium, platinum, osmium, and iridium; preferably, wherein the metal is selected from platinum and iridium.

3. The metal complex of claim 1, wherein R₁ to R₇ in Formula 1 are each independently selected from the group consisting of hydrogen, deuterium, fluorine, a substituted or unsubstituted alkyl group having 1 to 20 carbon atoms, a substituted or unsubstituted cycloalkyl group having 3 to 20 ring carbon atoms, a substituted or unsubstituted heteroalkyl group having 1 to 20 carbon atoms, and combinations thereof.

4. The metal complex of claim 1, wherein R₁ to R₇ in Formula 1 are each independently selected from the group consisting of hydrogen, methyl, ethyl, isopropyl, isobutyl, neopentyl, cyclobutyl, cyclopentyl, cyclohexyl, 4,4-dimethylcyclohexyl, norbornyl, adamantyl, fluorine, trifluoromethyl, 2,2,2-trifluoroethyl, 3,3,3-trifluoropropyl, 3,3,3-trifluoro-2,2-dimethylpropyl, and deuterated material of each of the above groups.

5. The metal complex of claim 1, wherein the metal complex has the general formula of M(Lₐ)ₘ(L_{b})ₙ(L_{c})_{q}, wherein L_{b} is a second ligand and L_{c} is a third ligand coordinated to M, L_{b} and L_{c} can be the same or different;
Lₐ, L_{b} and L_{c} can be optionally joined to form a multidentate ligand;
wherein m is 1, 2, or 3, n is 0, 1, or 2, q is 0, 1, or 2, m+n+q is equal to the oxidation state of M;
wherein L_{b} and L_{c} are each independently selected from the group consisting of: 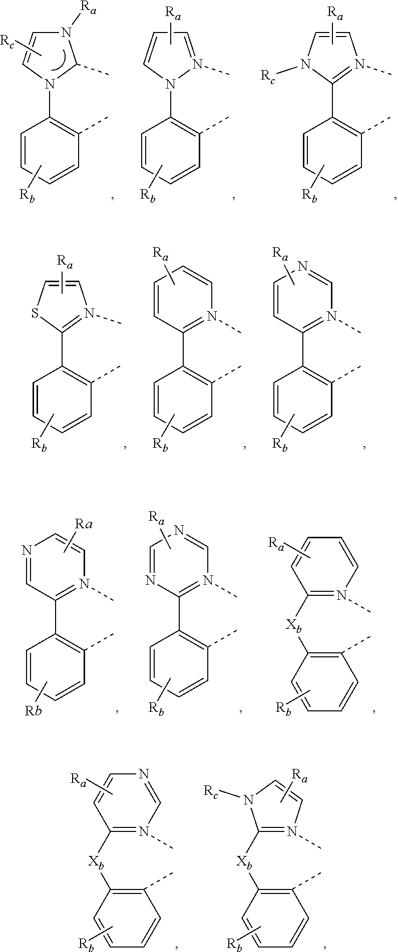
wherein
Rₐ, R_{b}, and R_{c} can represent mono, di, tri, or tetra substitution, or no substitution;
X_{b} is selected from the group consisting of O, S, Se, NR_{N1}, CR_{C1}R_{C2};
Rₐ, R_{b}, R_{c}, R_{N1}, R_{C1} and R_{C2} are each independently selected from the group consisting of hydrogen, deuterium, halogen, a substituted or unsubstituted alkyl group having 1 to 20 carbon atoms, a substituted or unsubstituted cycloalkyl group having 3 to 20 ring carbon atoms, a substituted or unsubstituted heteroalkyl group having 1 to 20 carbon atoms, a substituted or unsubstituted arylalkyl group having 7 to 30 carbon atoms, a substituted or unsubstituted alkoxy group having 1 to 20 carbon atoms, a substituted or unsubstituted aryloxy group having 6 to 30 carbon atoms, a substituted or unsubstituted alkenyl group having 2 to 20 carbon atoms, a substituted or unsubstituted aryl group having 6 to 30 carbon atoms, a substituted or unsubstituted heteroaryl group having 3 to 30 carbon atoms, a substituted or unsubstituted alkylsilyl group having 3 to 20 carbon atoms, a substituted or unsubstituted arylsilyl group having 6 to 20 carbon atoms, a substituted or unsubstituted amino group having 0 to 20 carbon atoms, an acyl group, a carbonyl group, a carboxylic acid group, an ester group, a nitrile group, an isonitrile group, a thiol group, a sulfinyl group, a sulfonyl group, a phosphino group, and combinations thereof;
two adjacent substituents can be optionally joined to form a ring.

6. The metal complex of claim 5, wherein the metal complex has the formula of Ir(Lₐ)(L_{b})₂.

7. The metal complex of claim 5, wherein the ligand Lₐ is selected from the group consisting of:

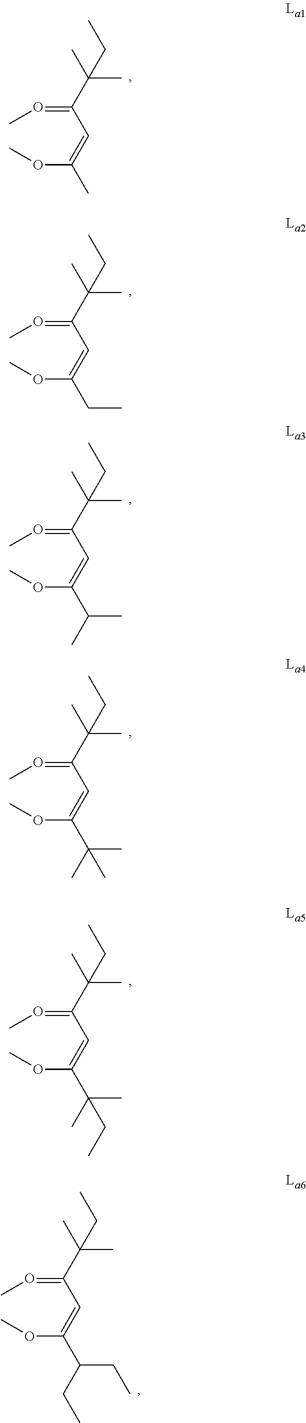

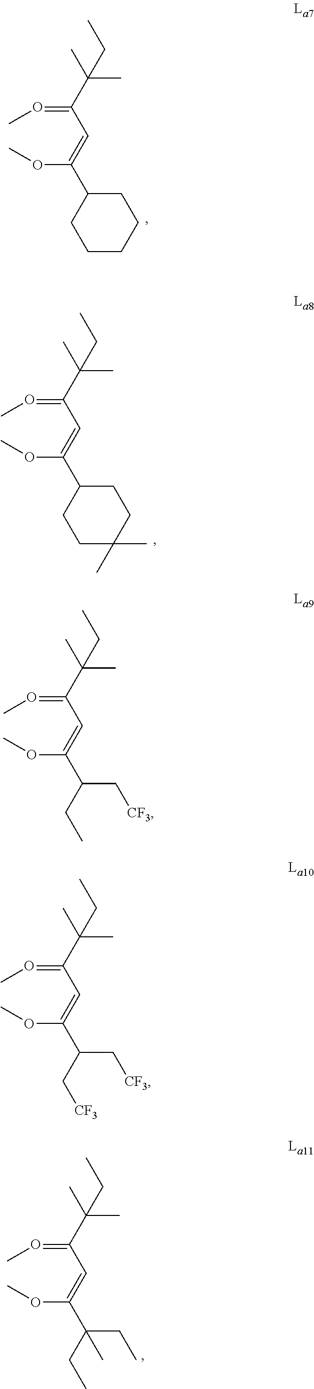

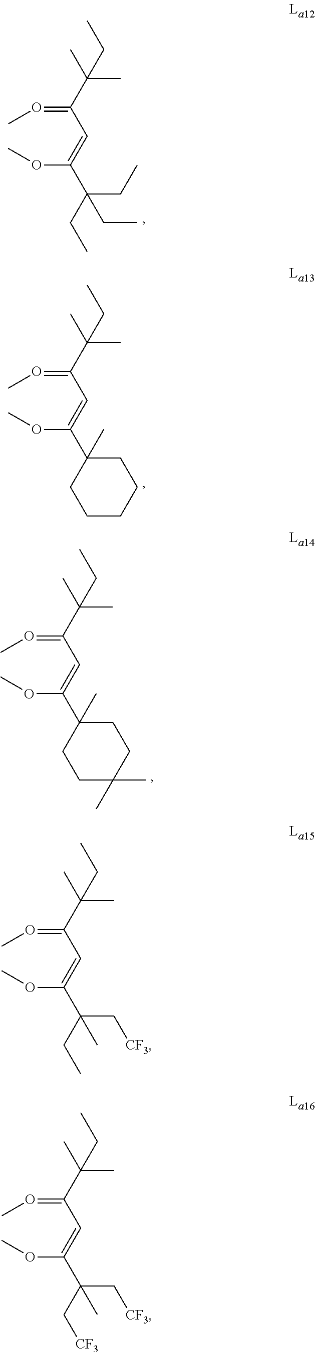

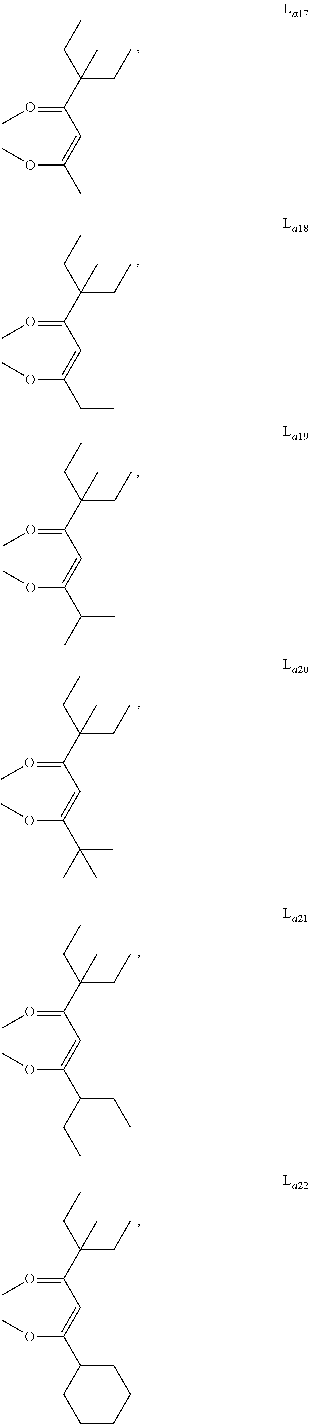

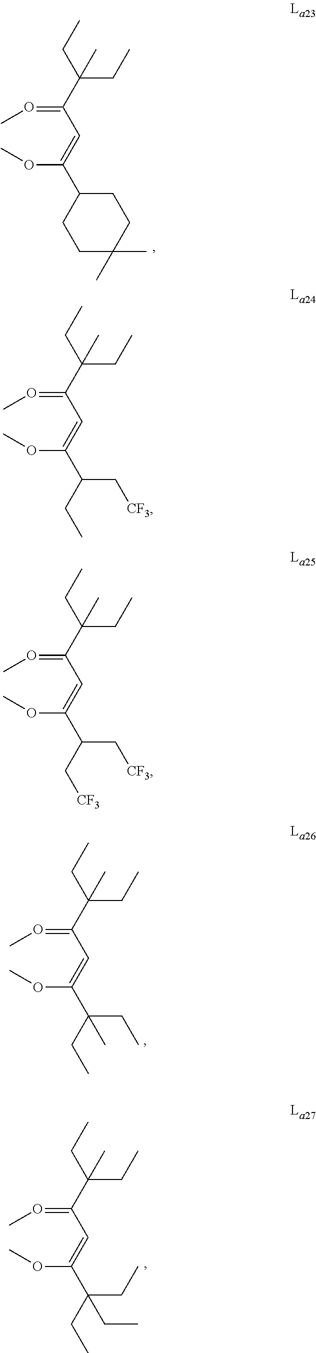

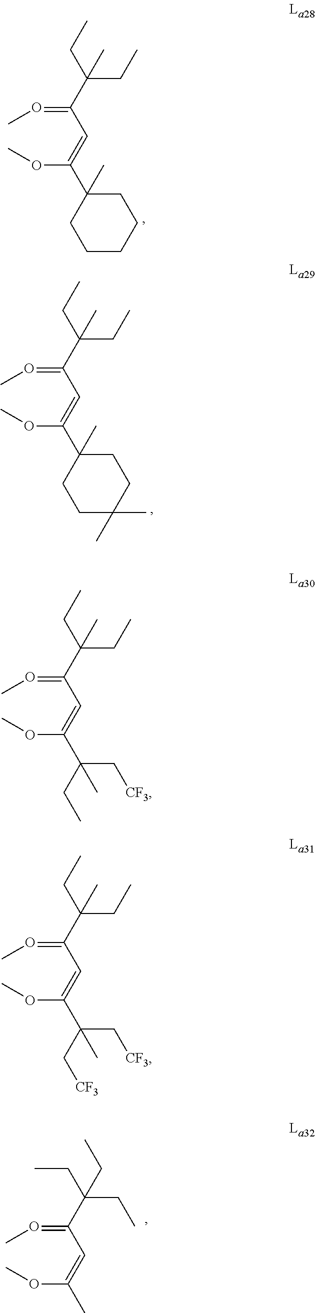

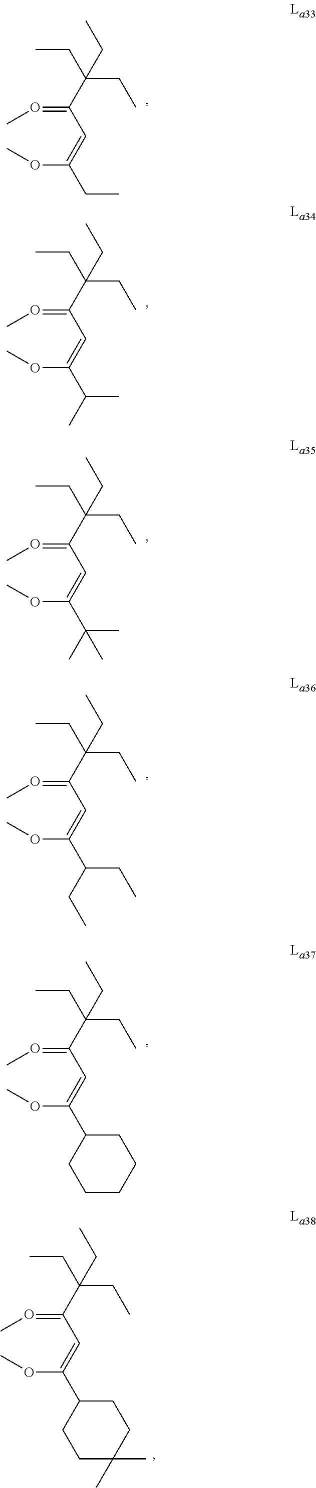

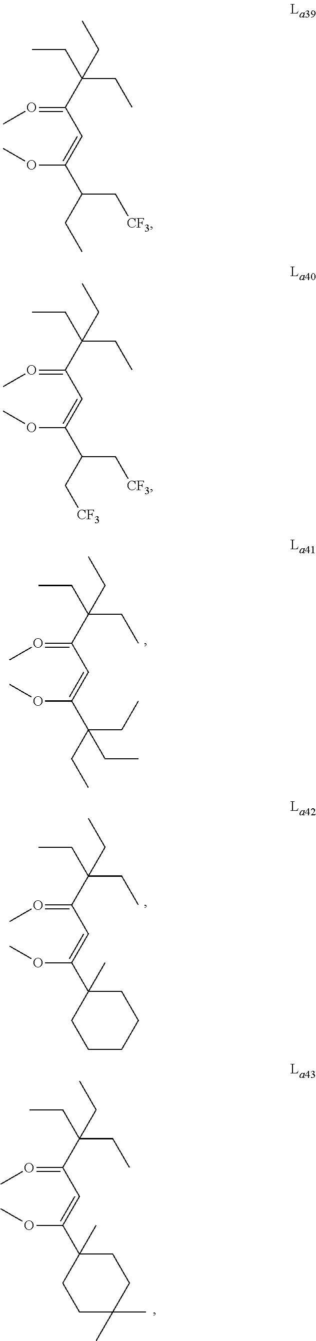

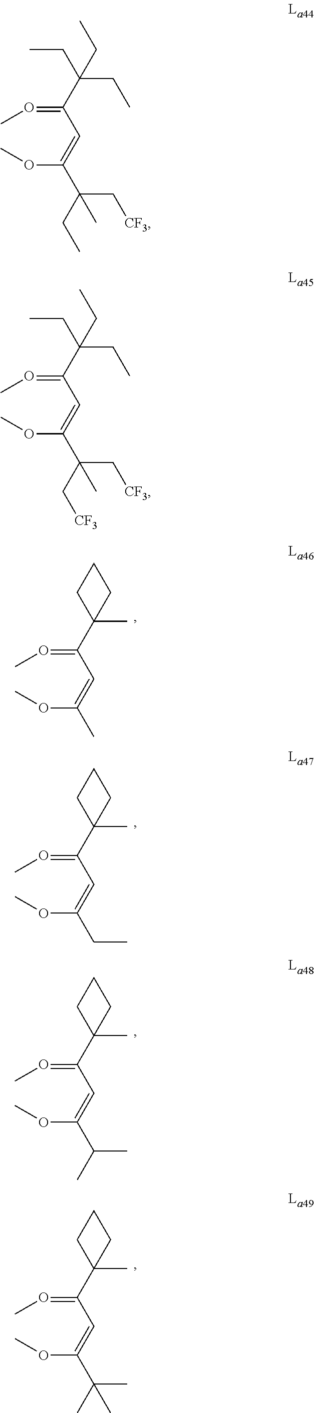

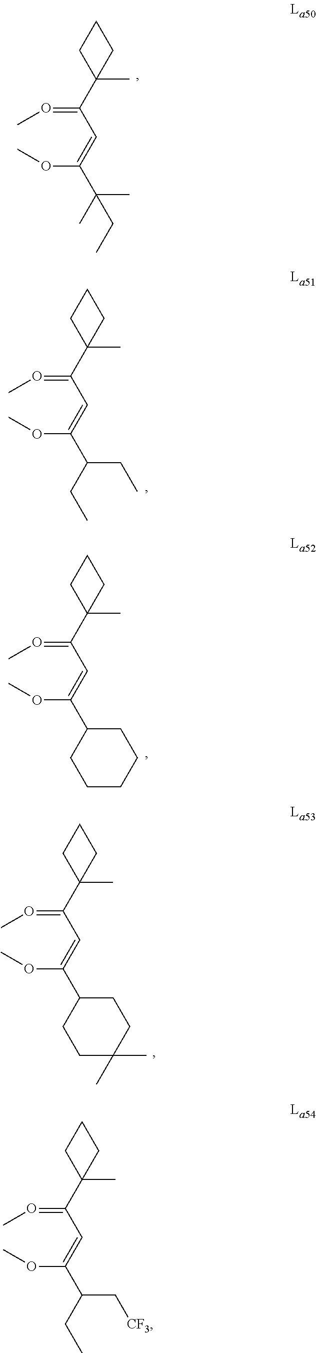

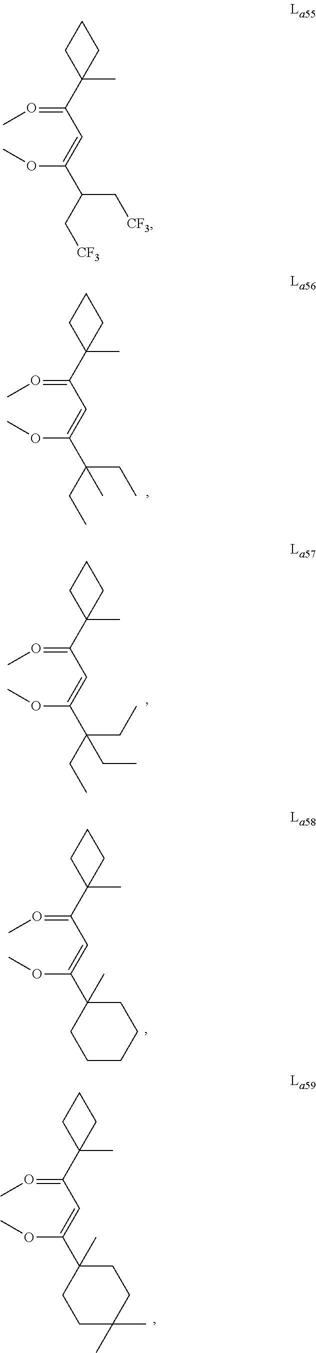

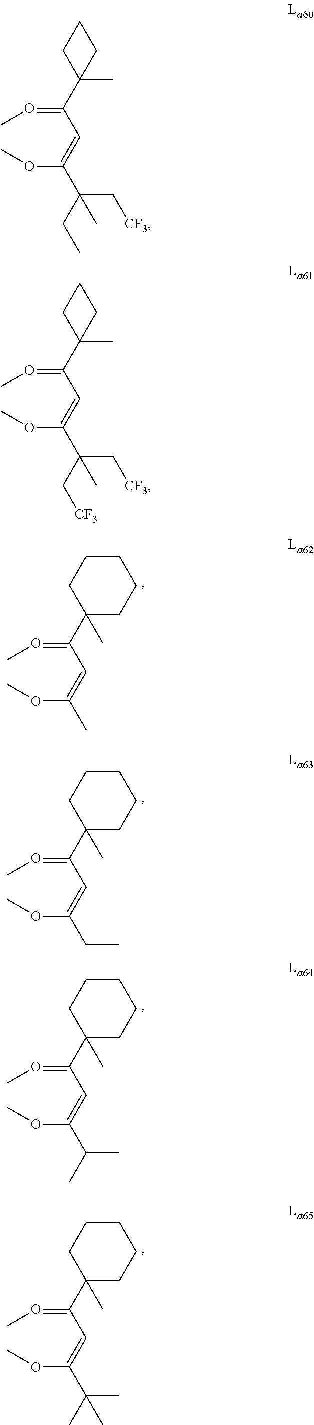

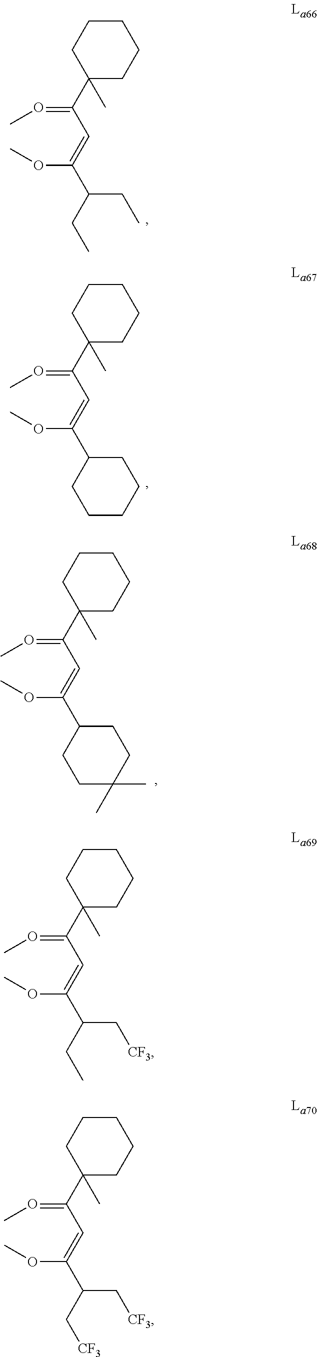

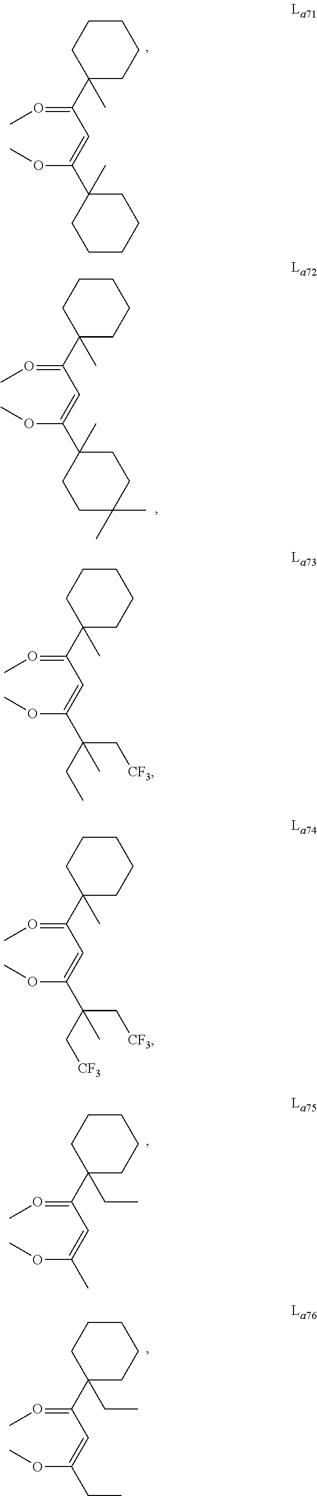

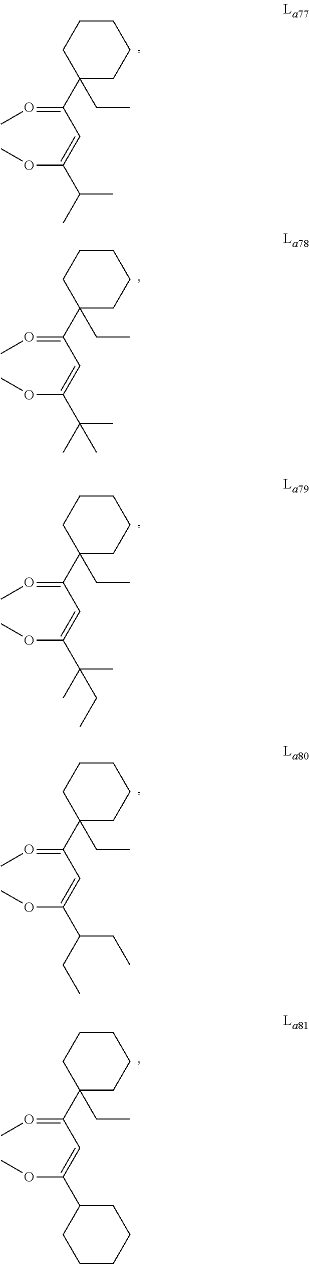

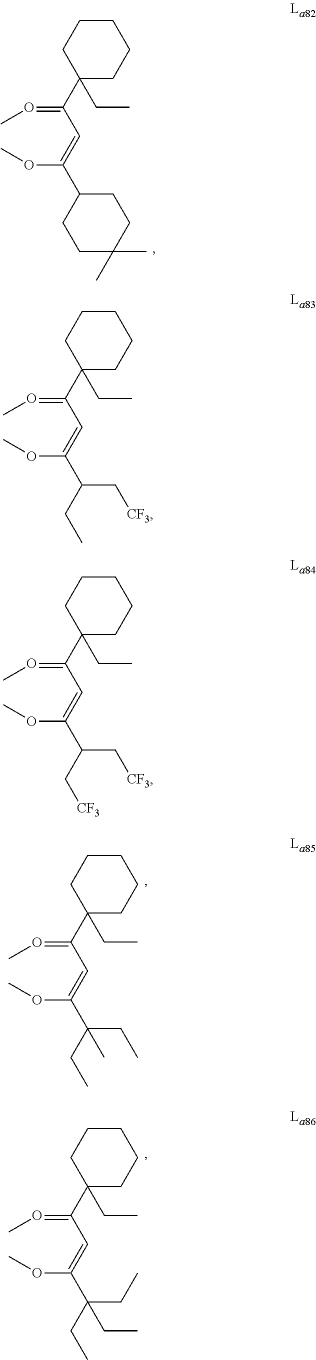

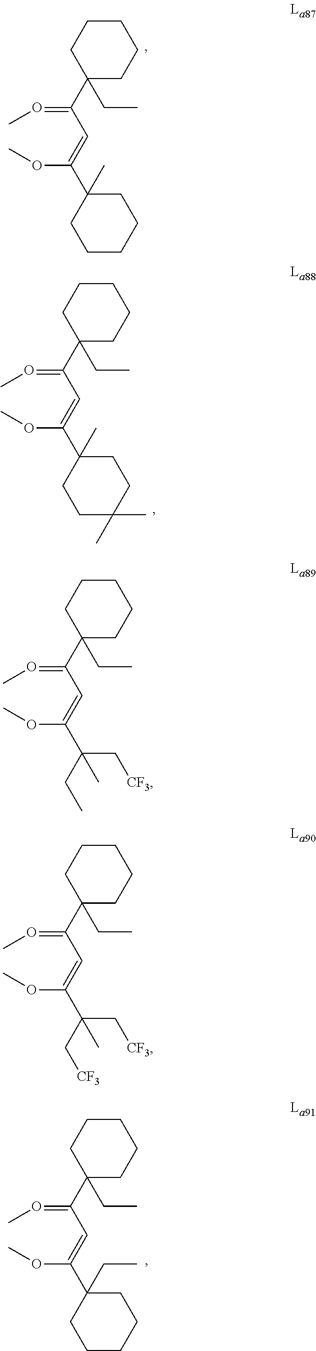

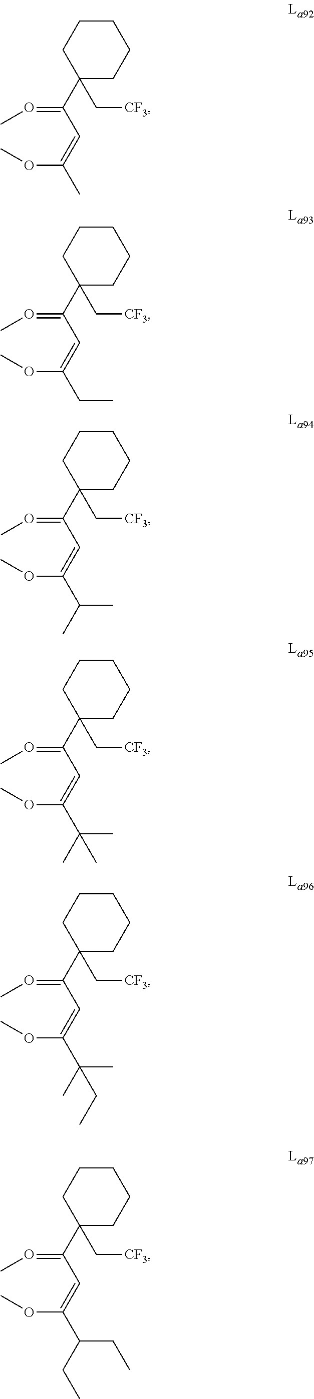

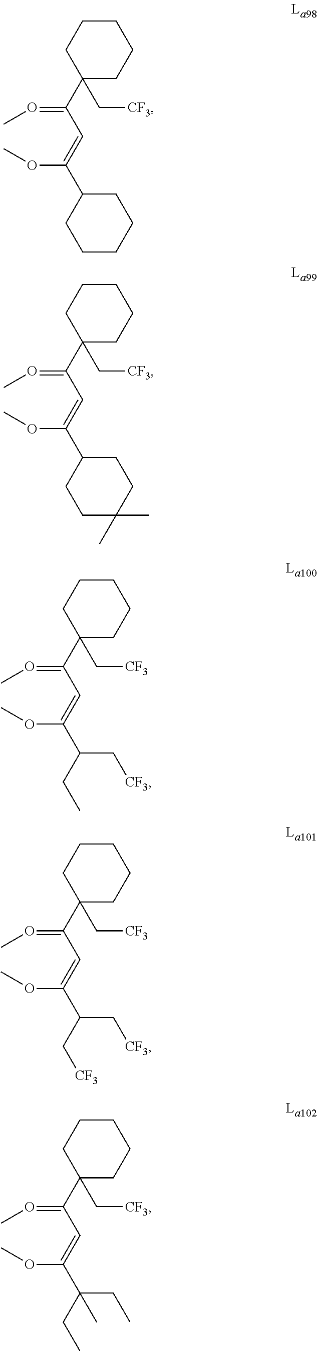

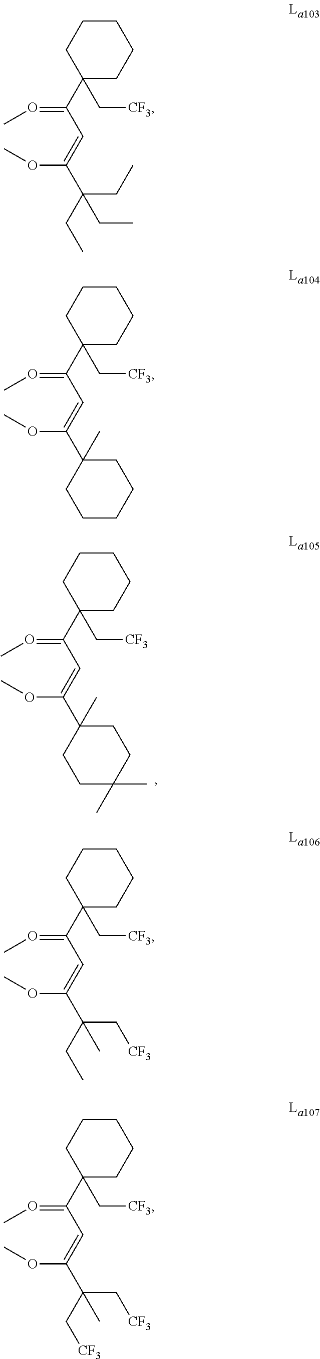

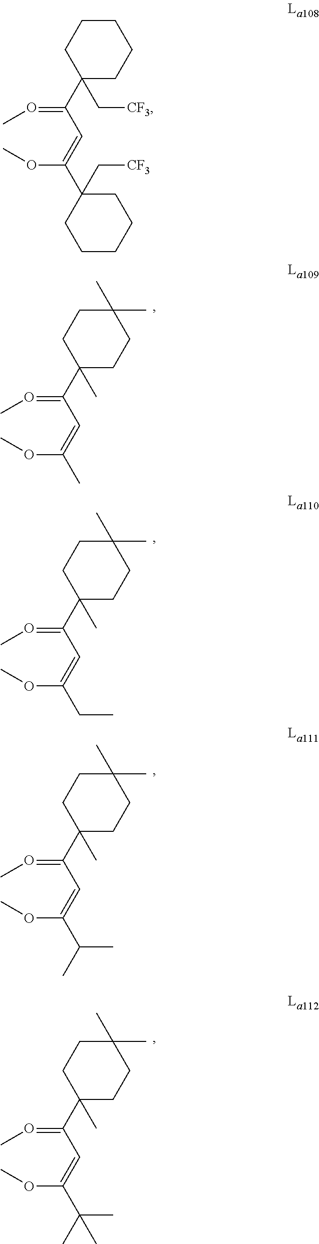

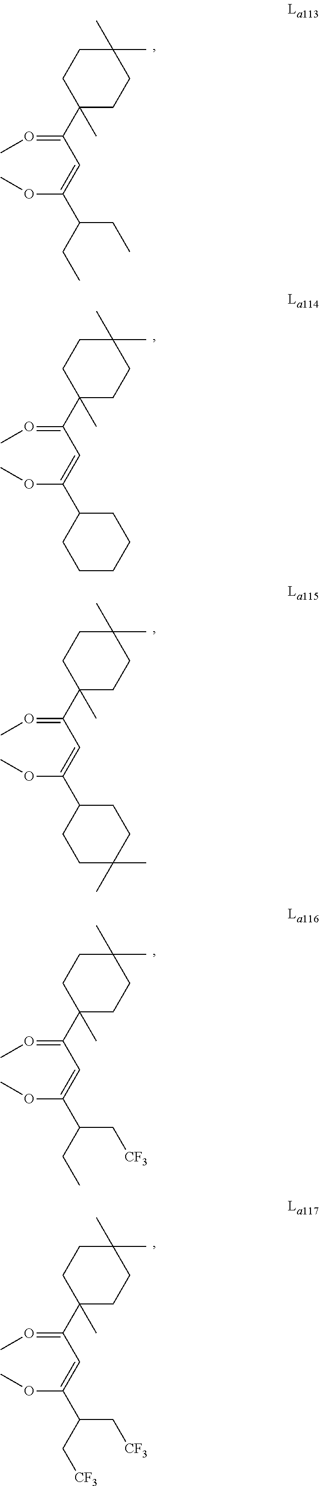

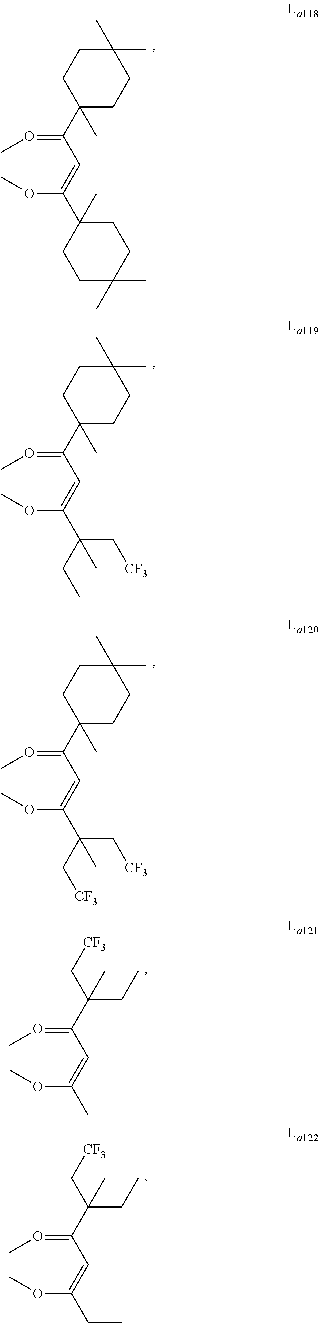

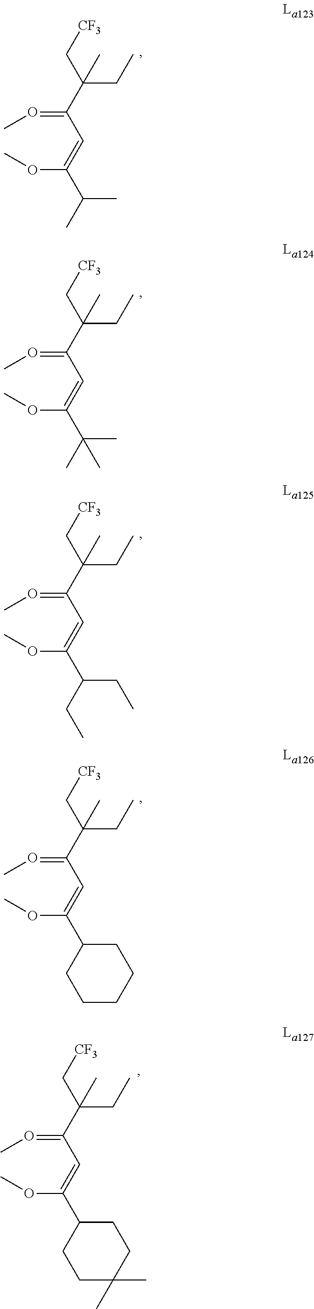

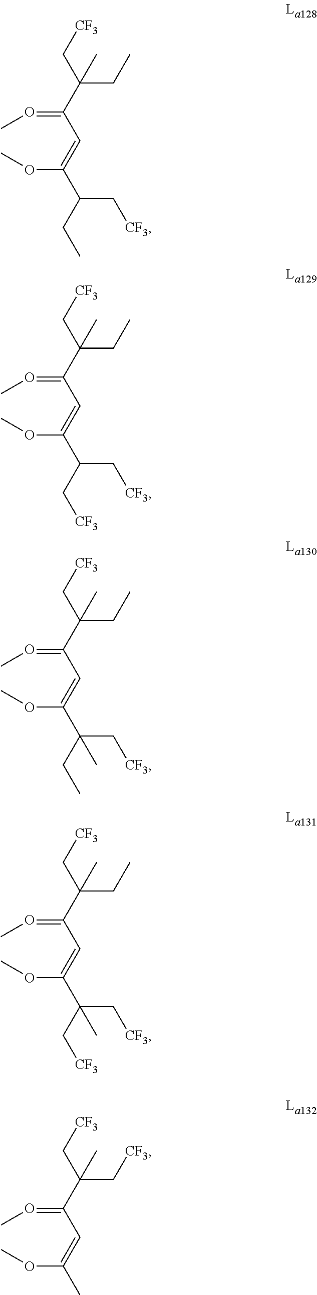

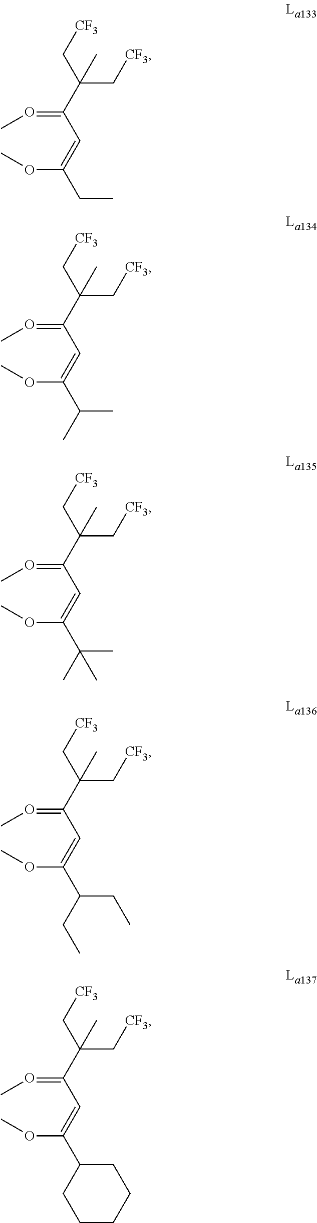

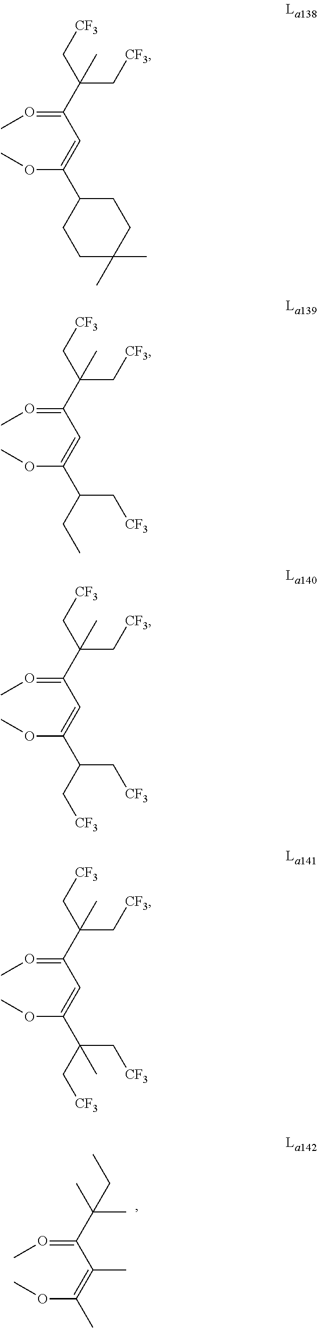

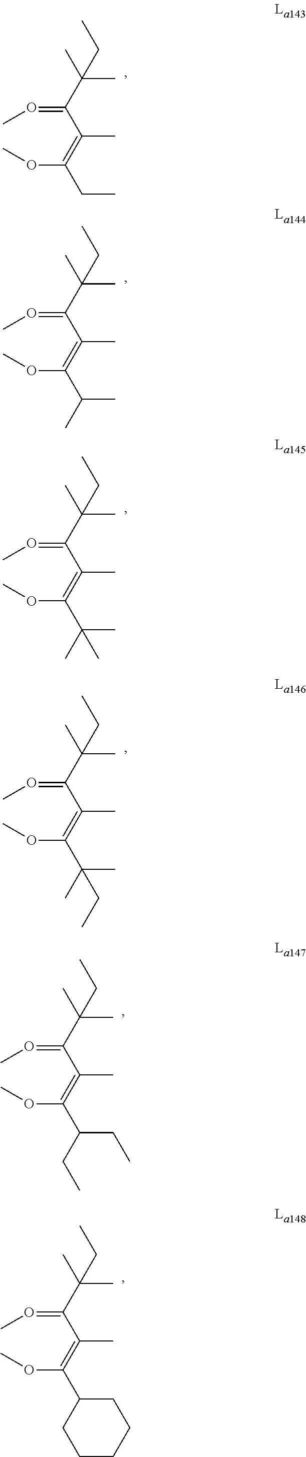

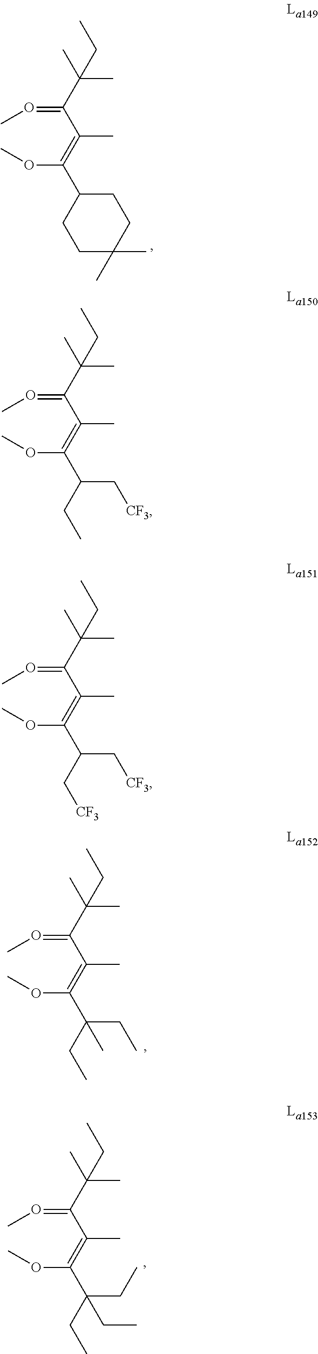

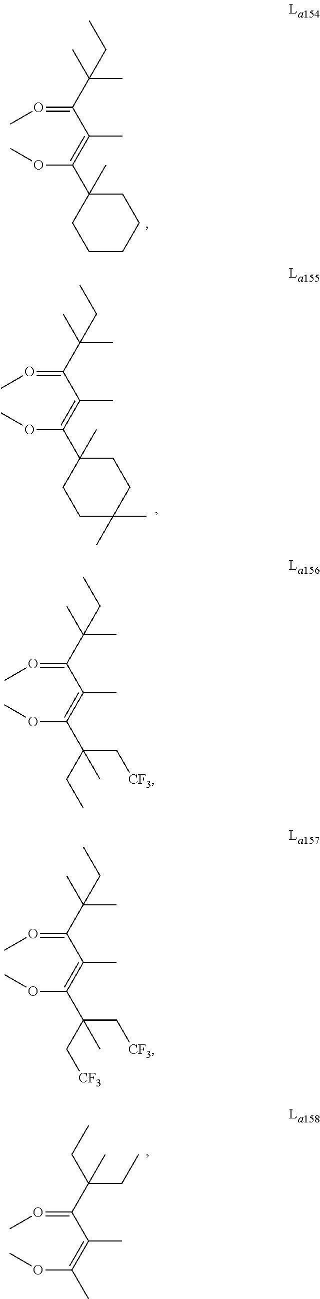

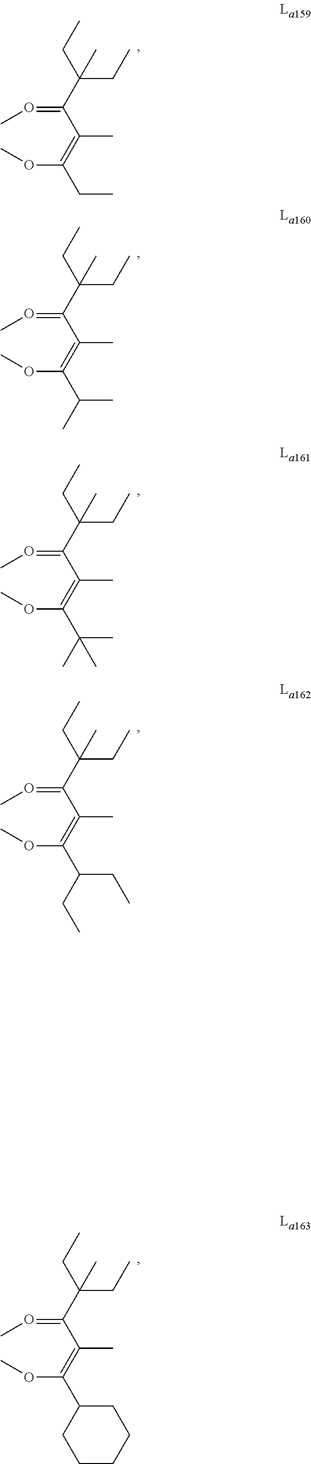

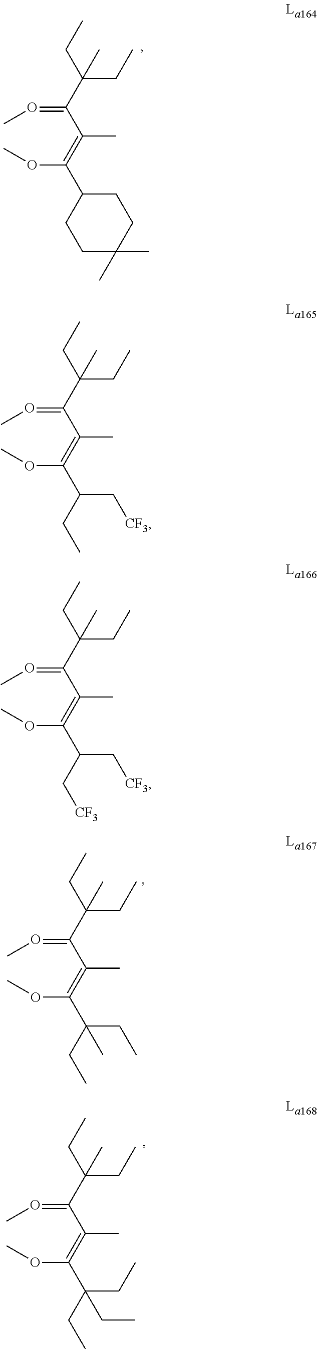

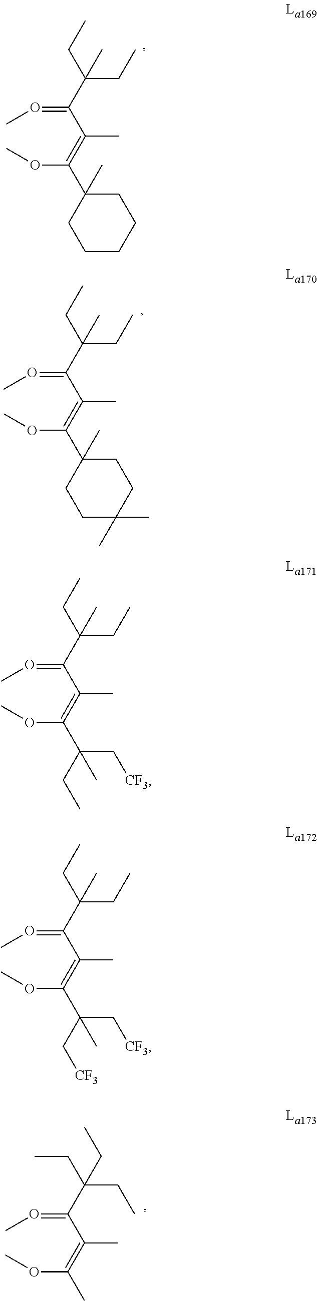

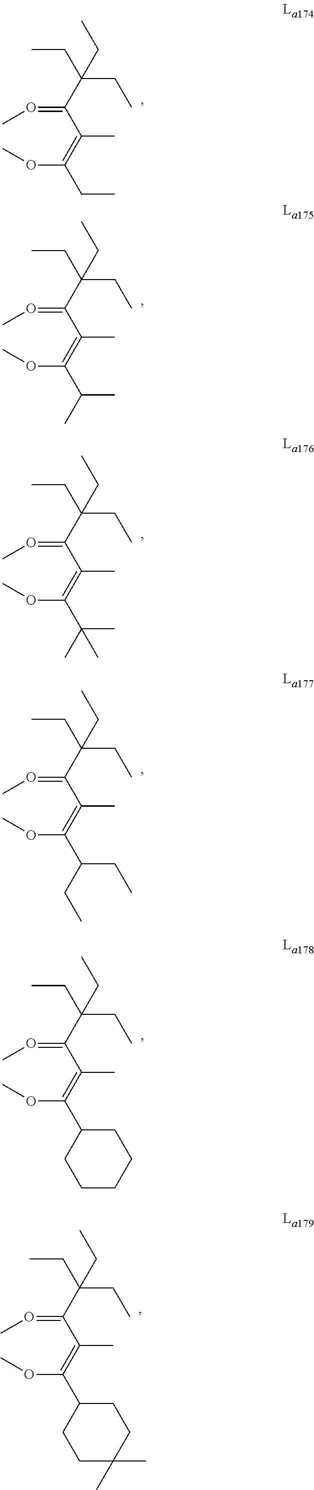

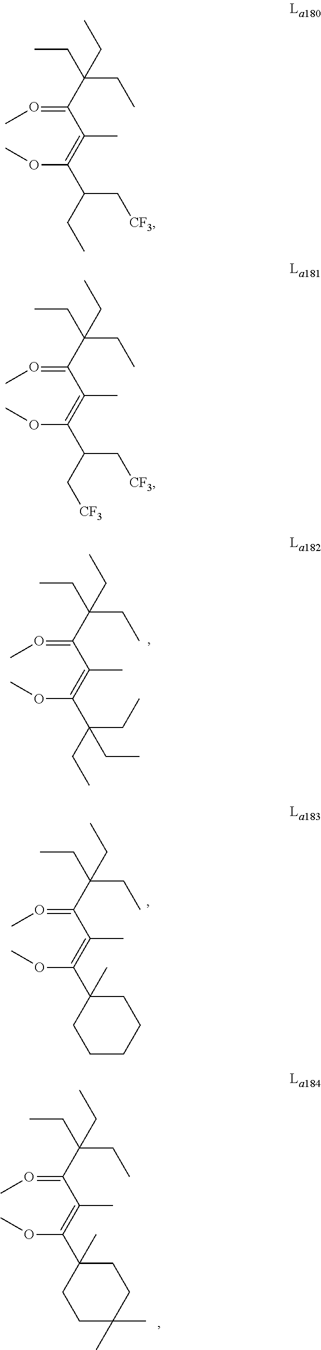

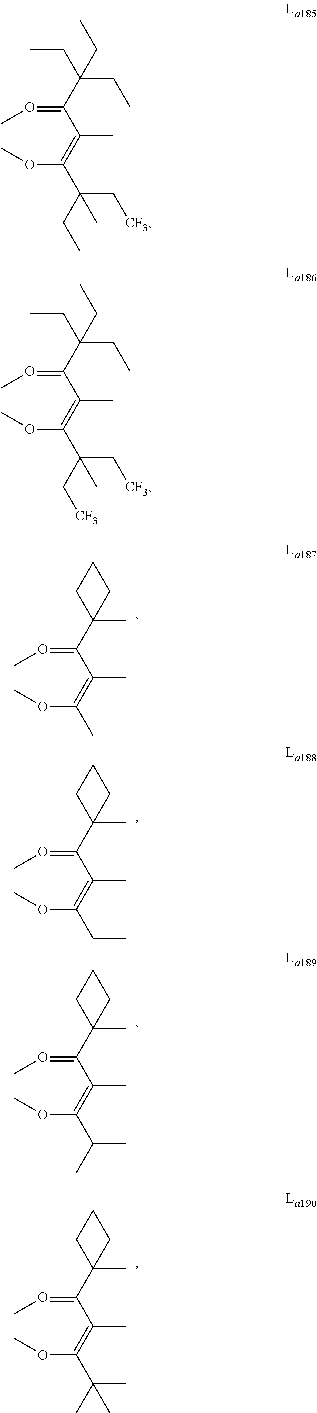

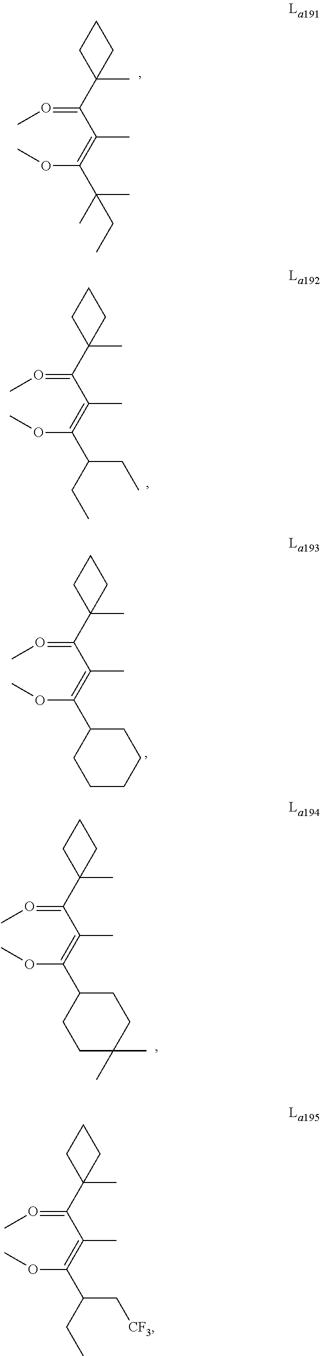

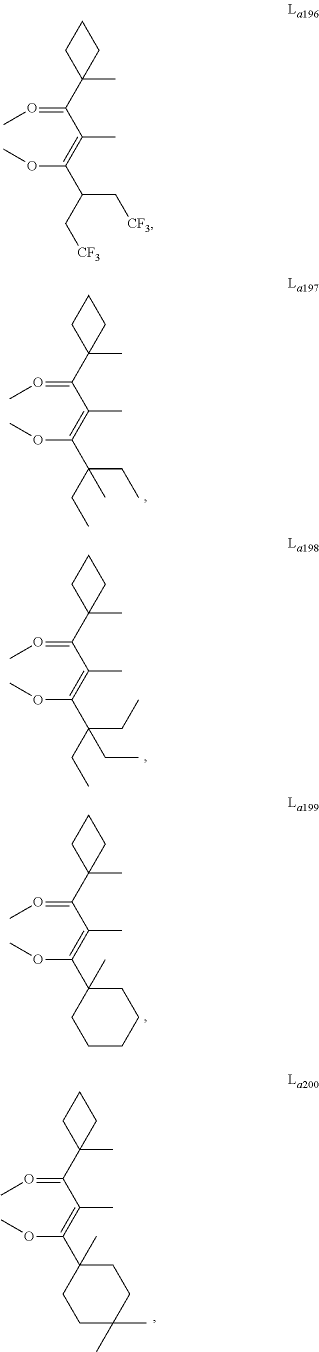

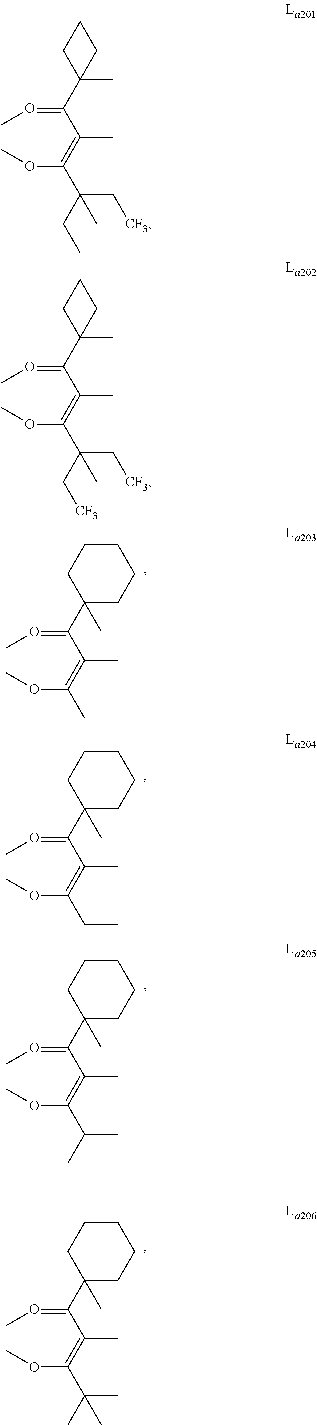

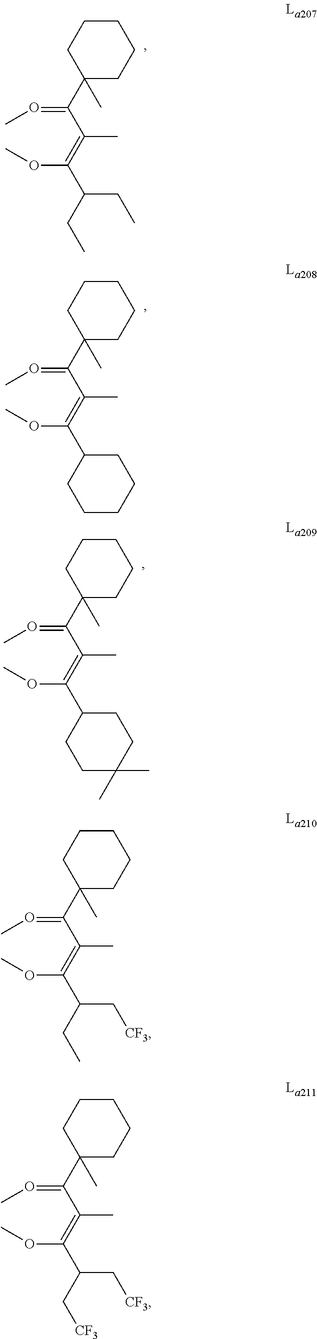

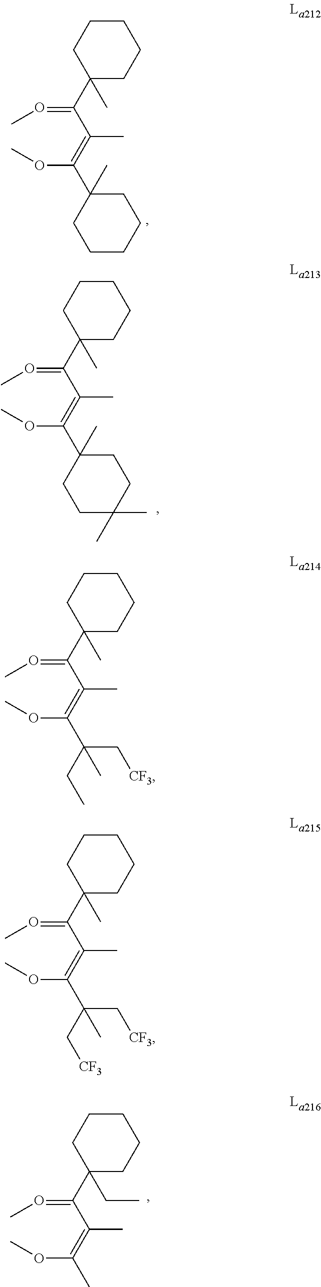

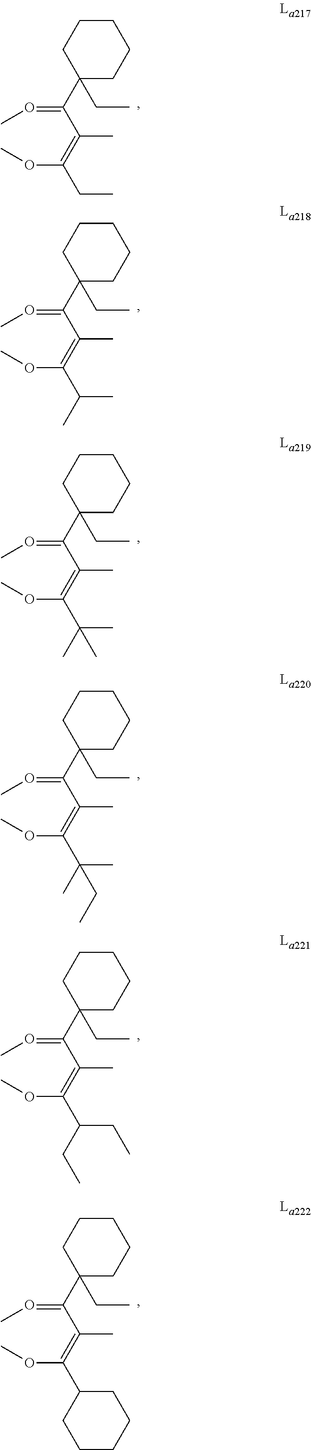

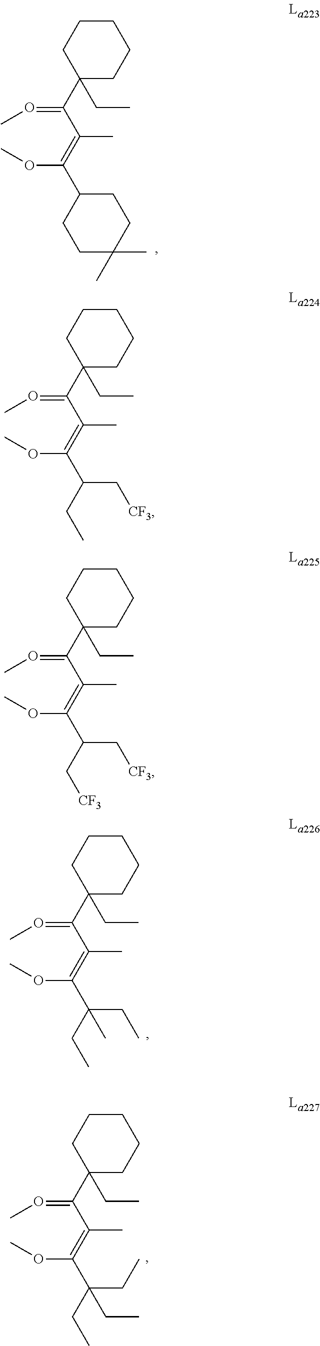

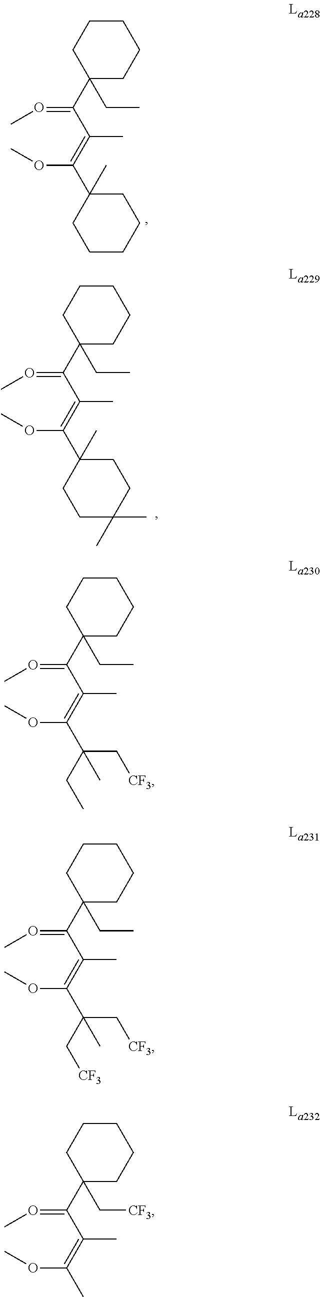

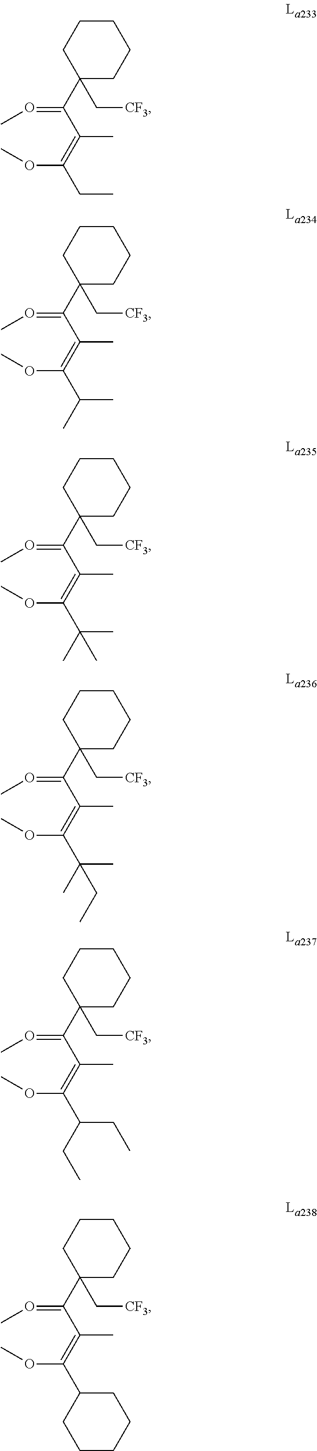

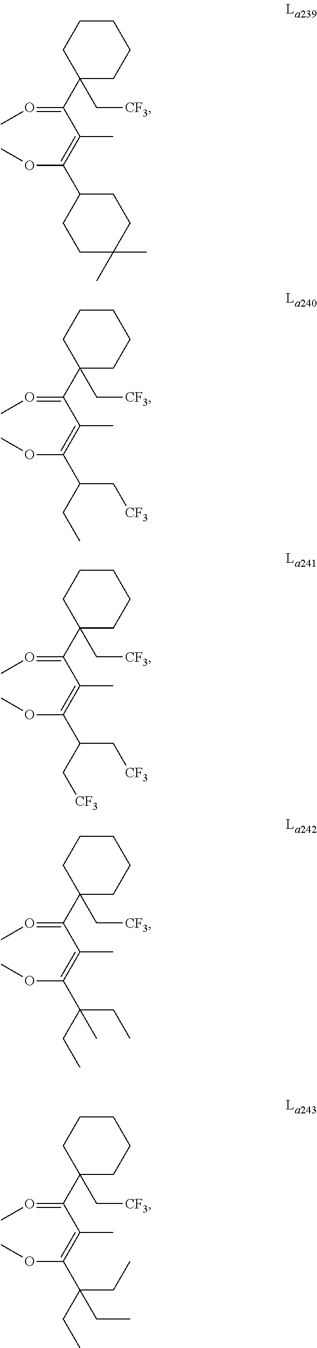

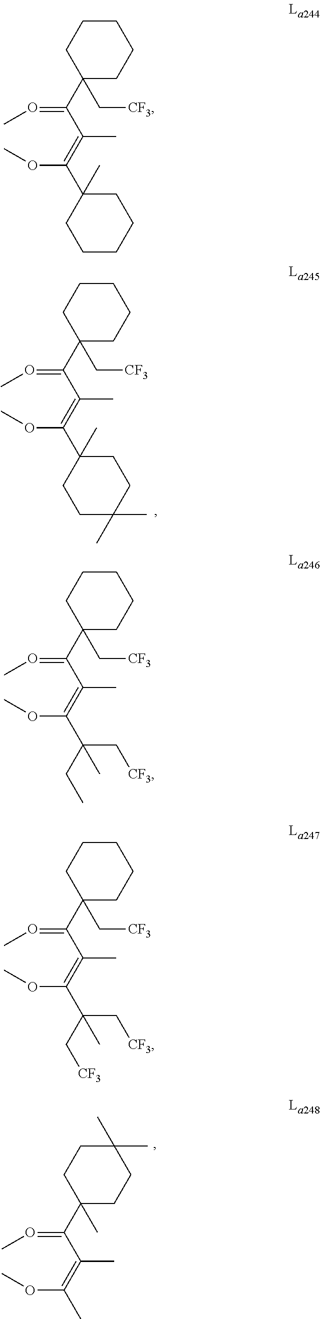

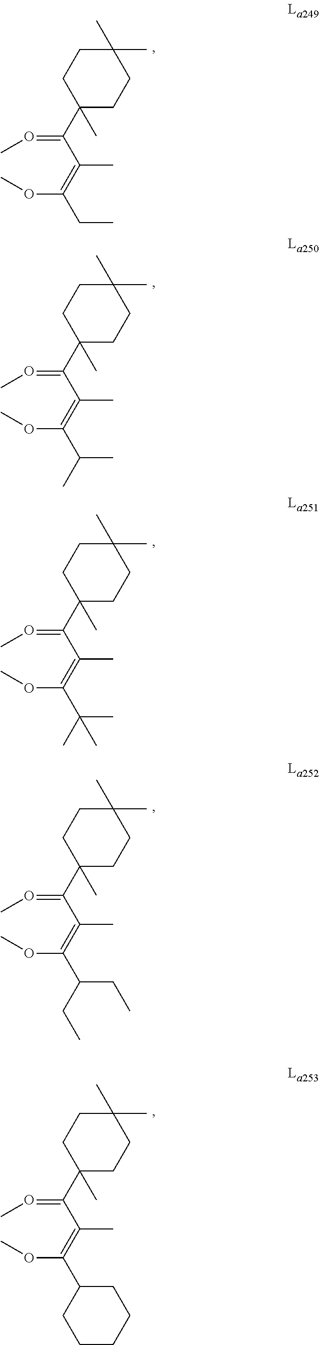

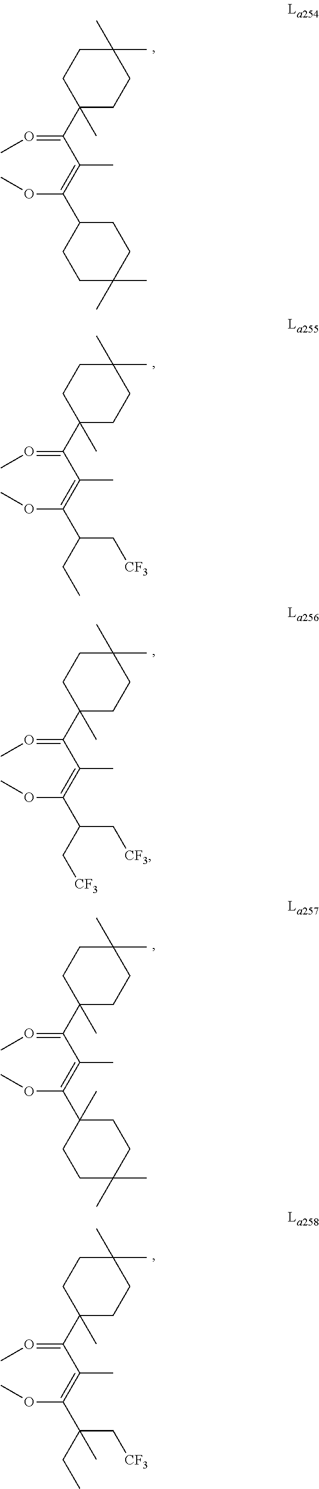

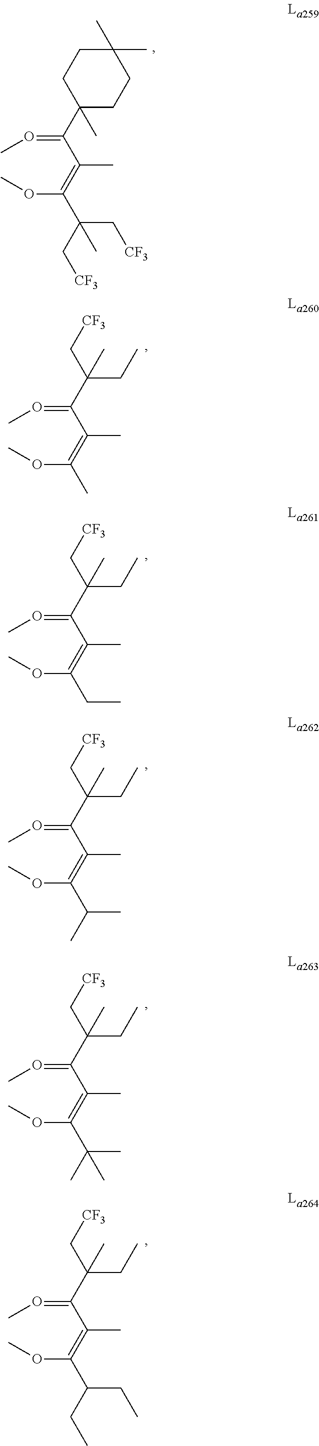

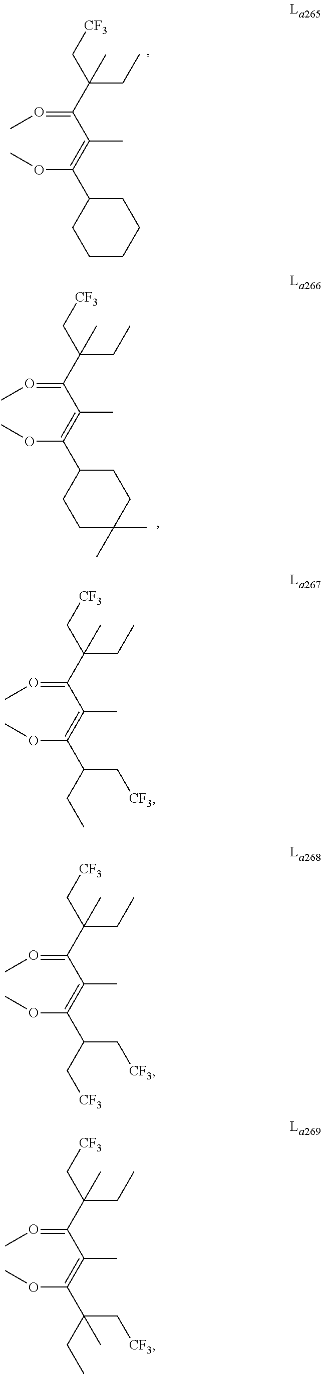

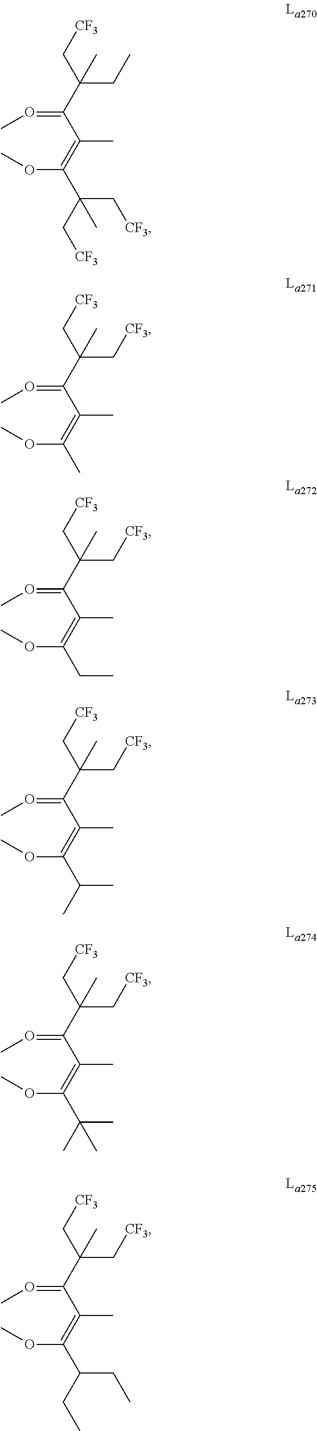

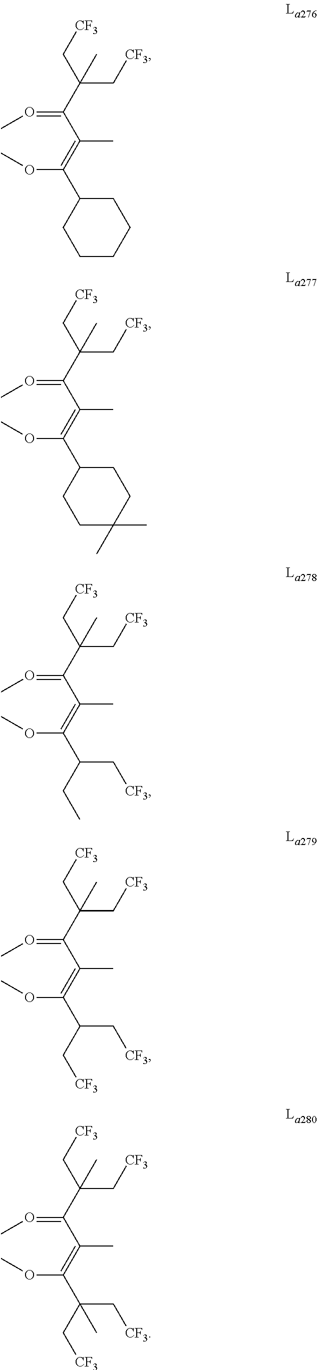

8. The metal complex of claim 5, wherein the ligand L_{b} is selected from the group consisting of:

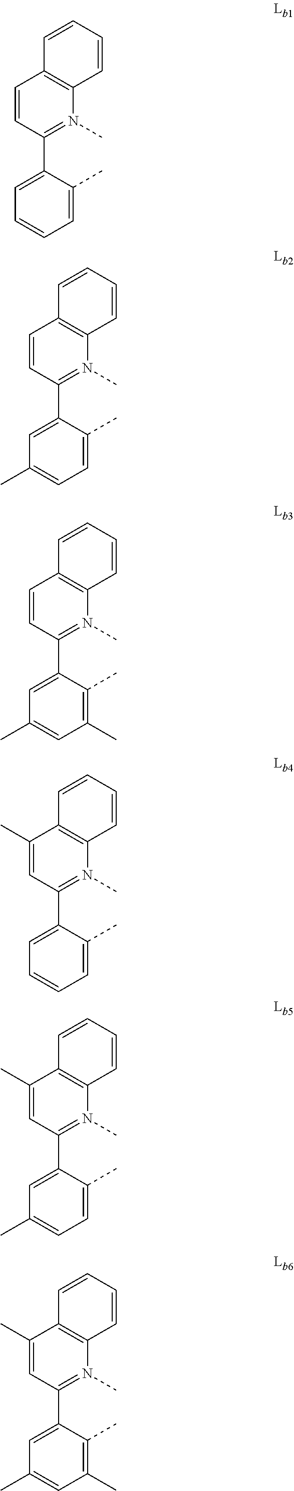

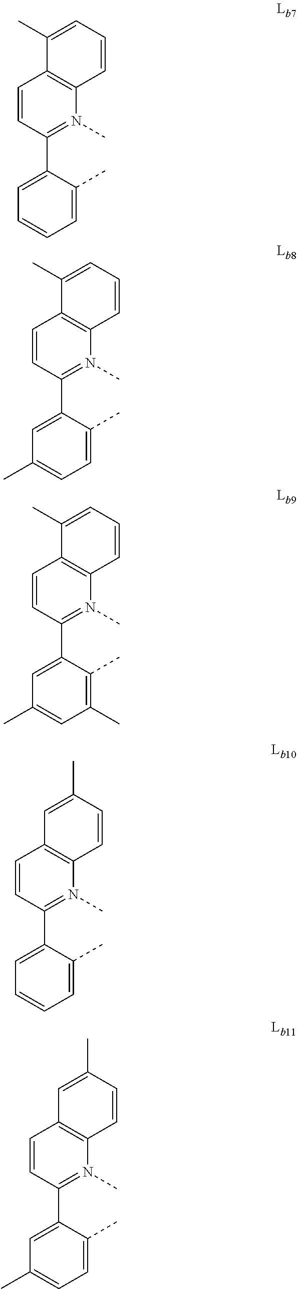

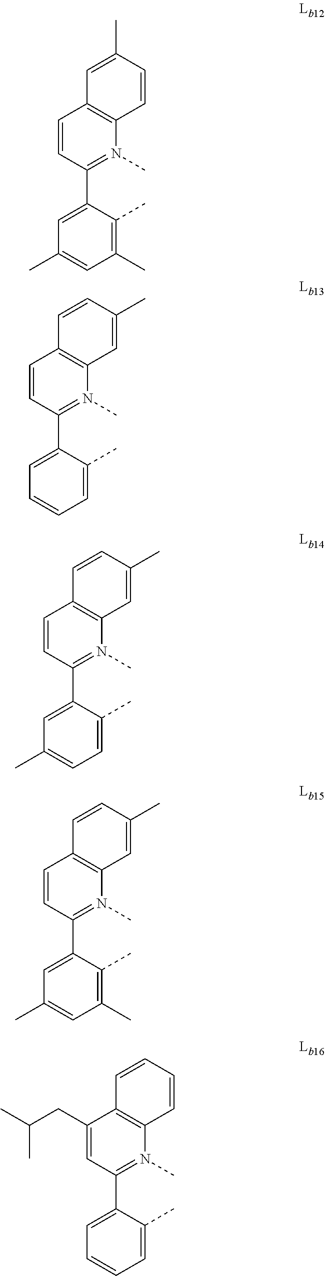

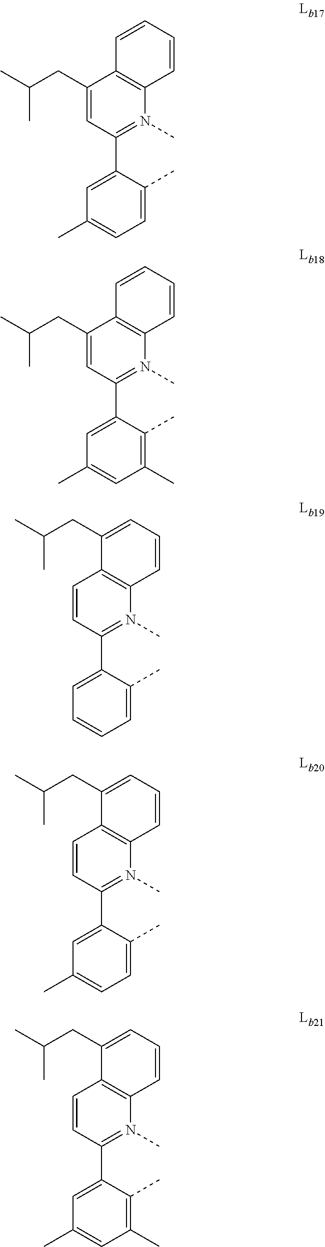

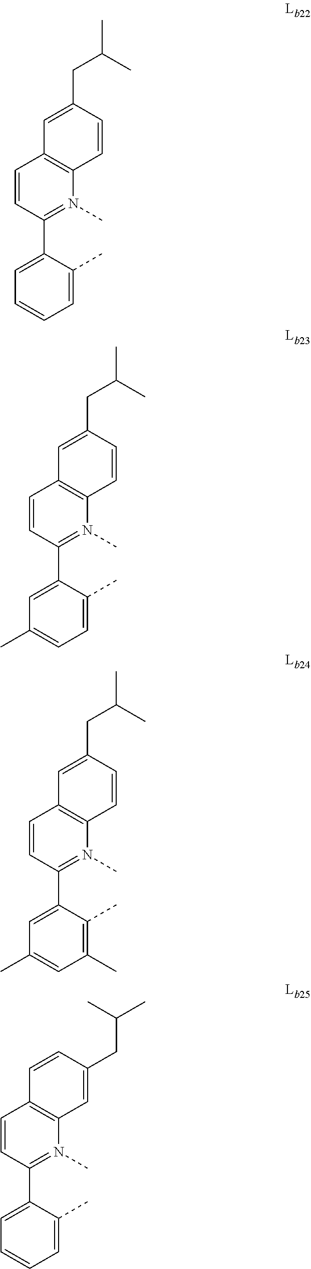

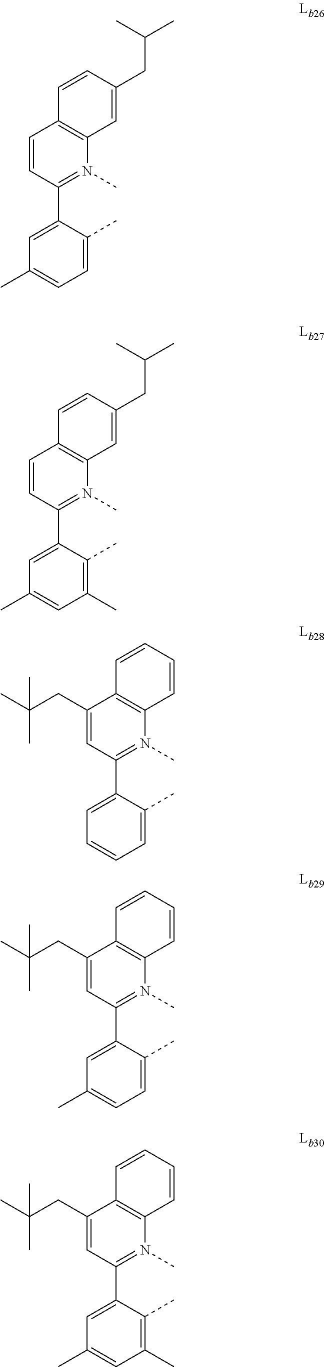

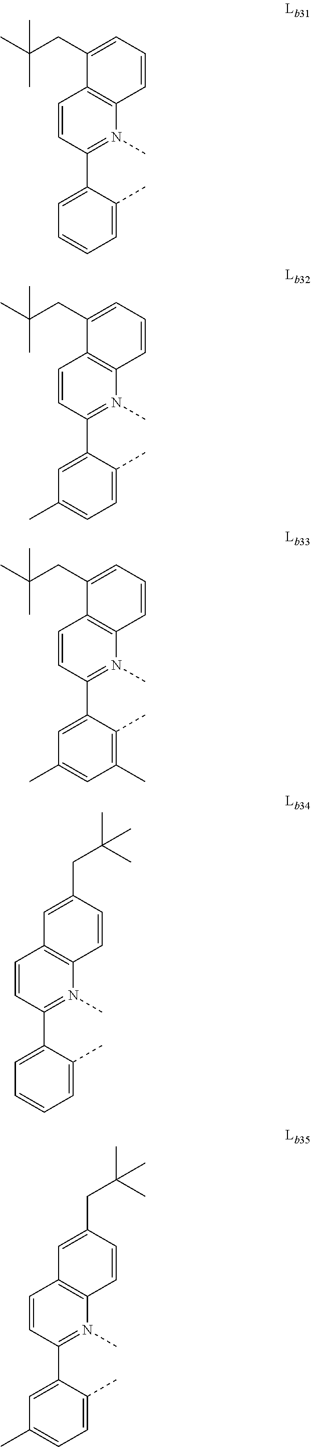

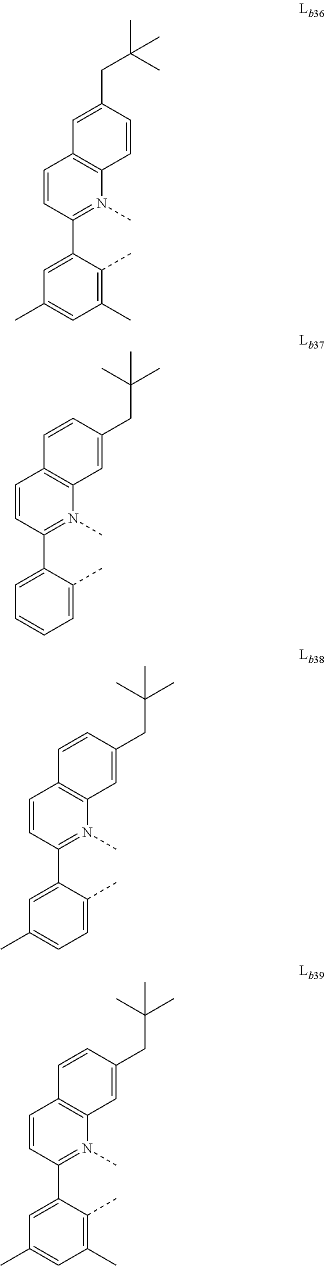

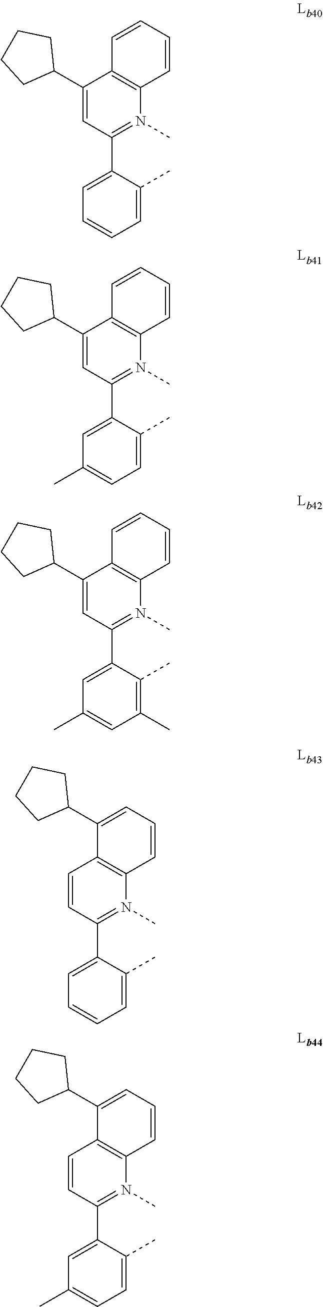

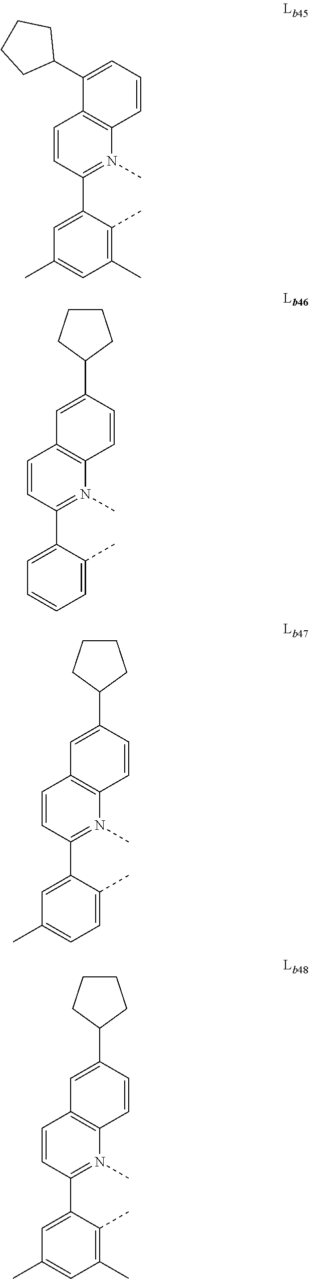

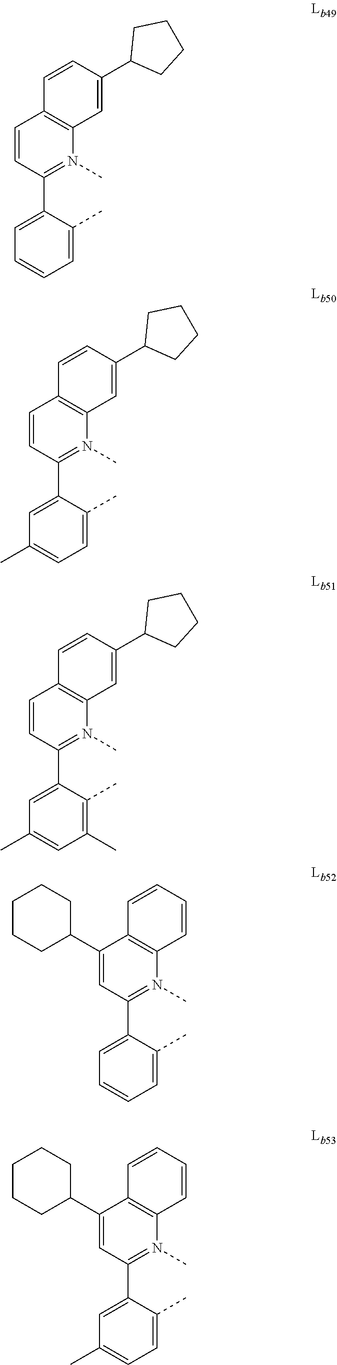

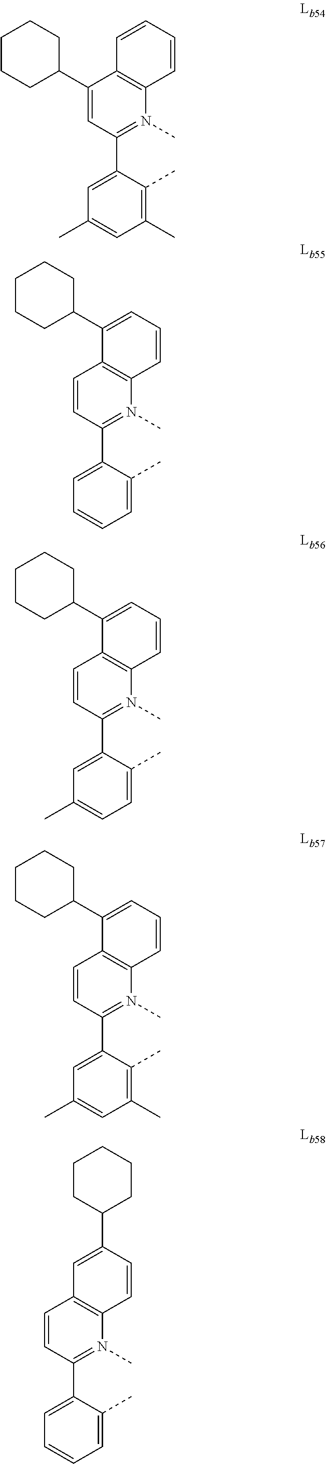

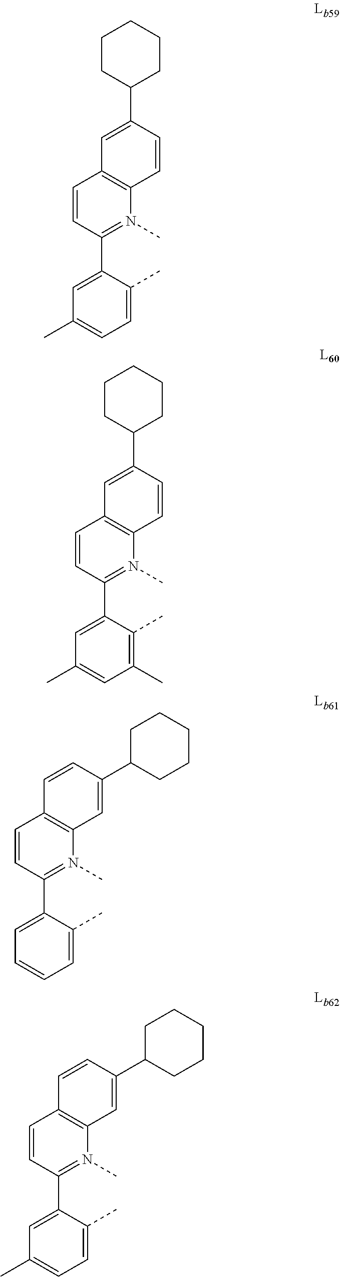

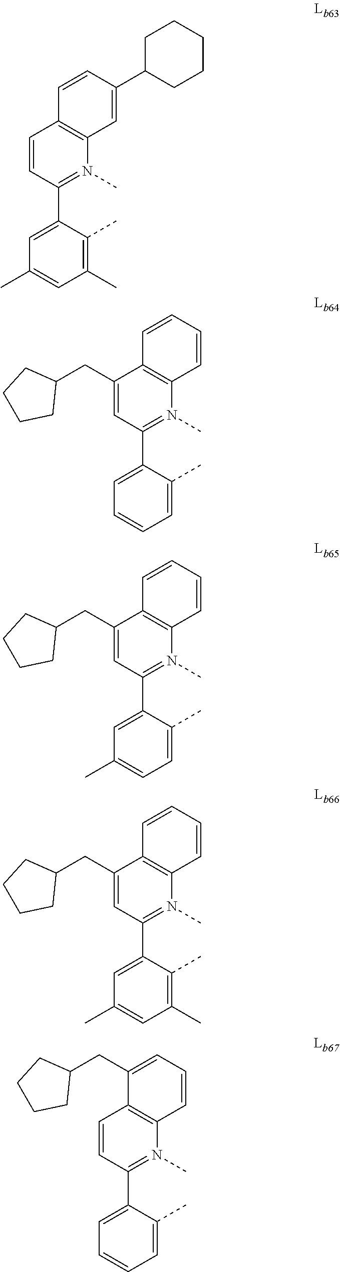

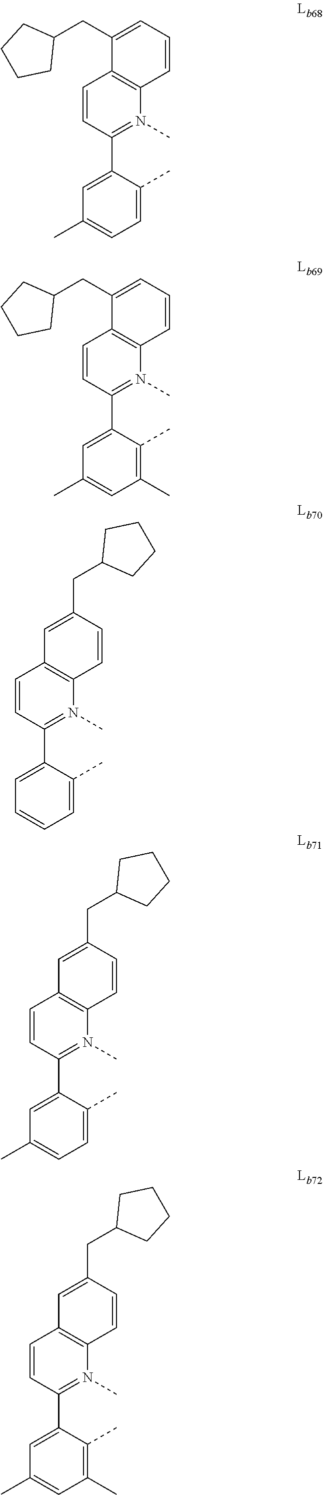

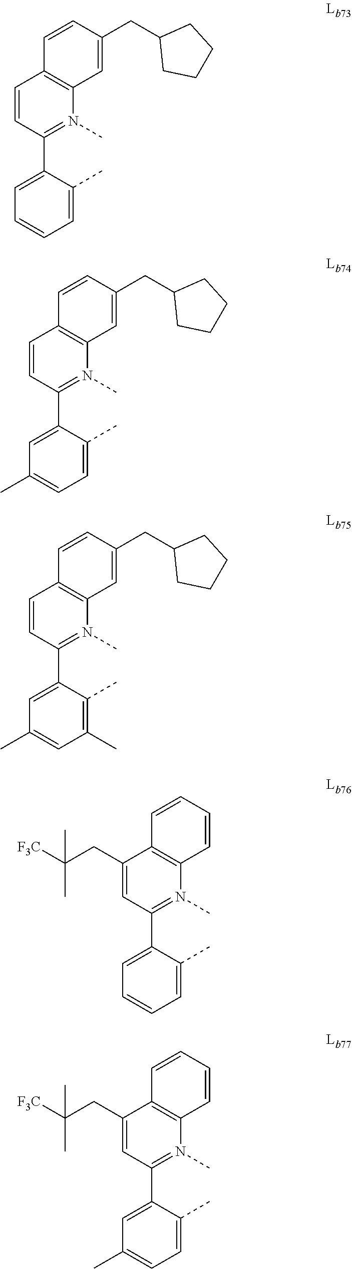

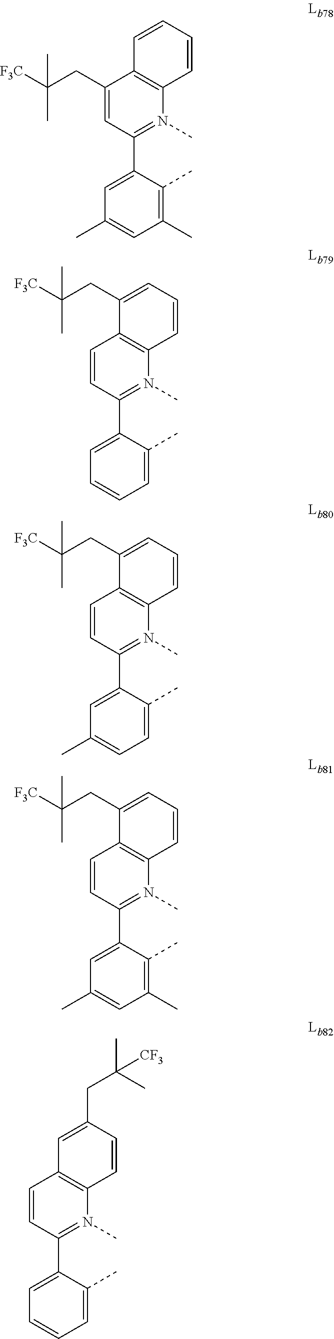

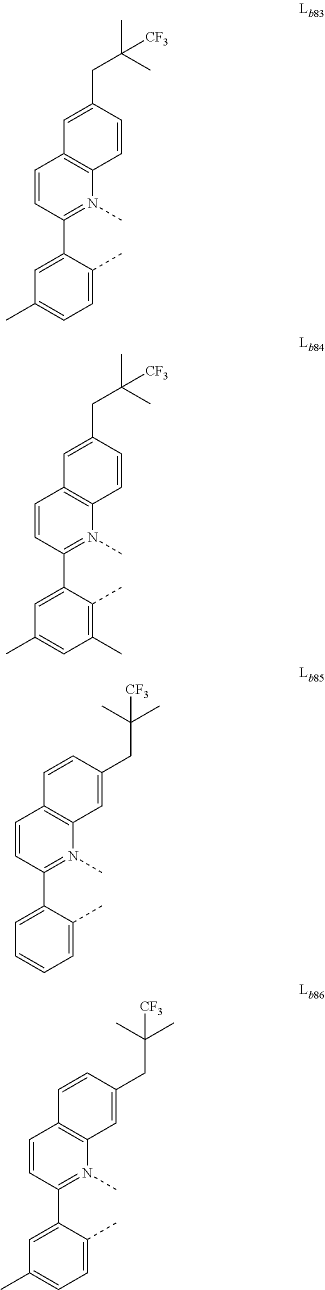

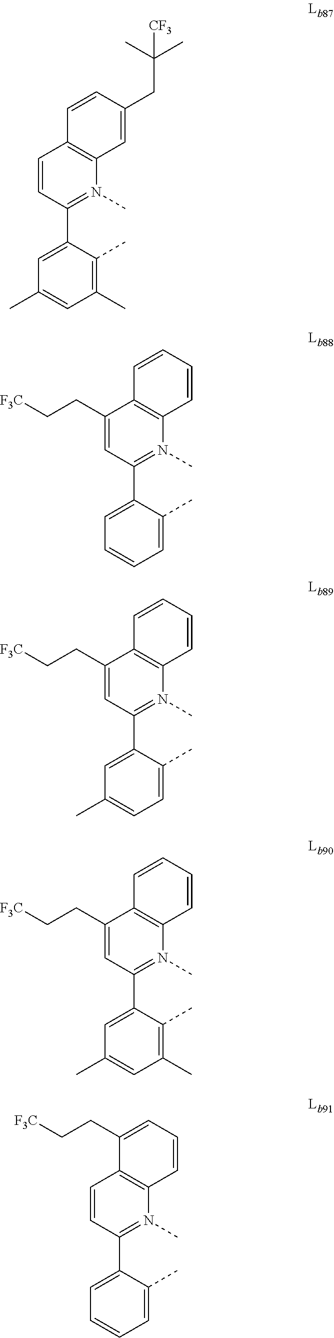

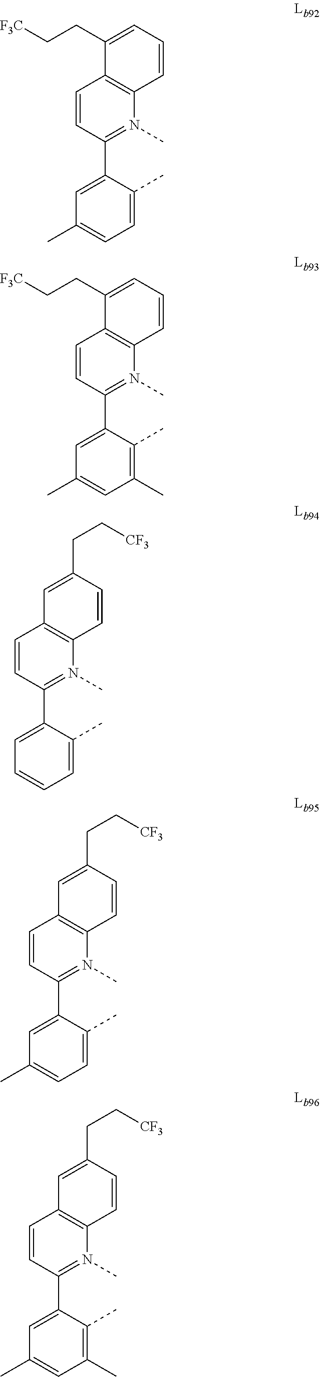

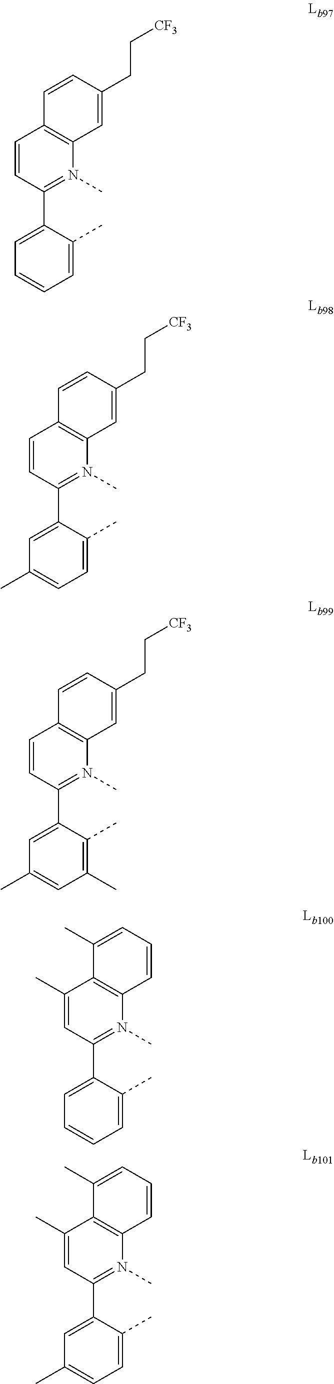

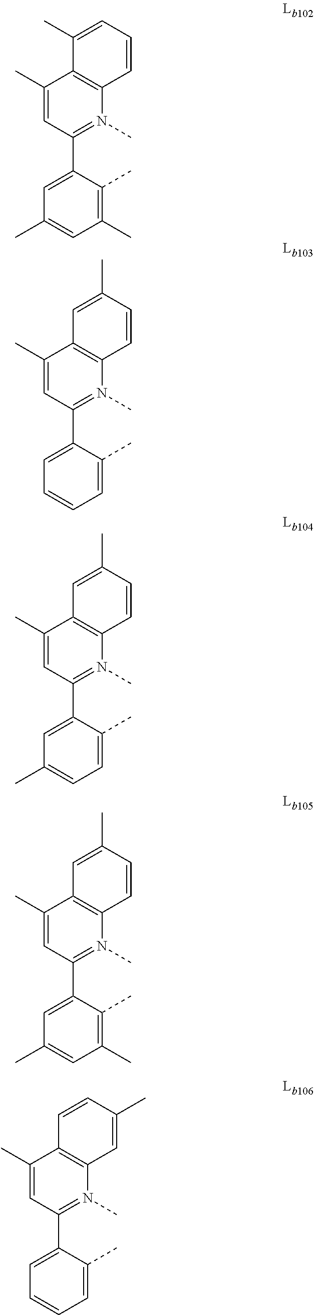

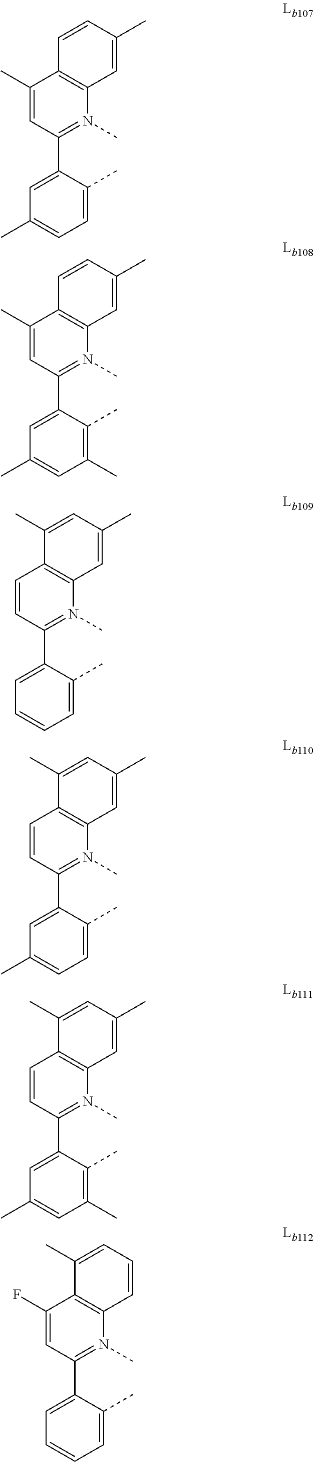

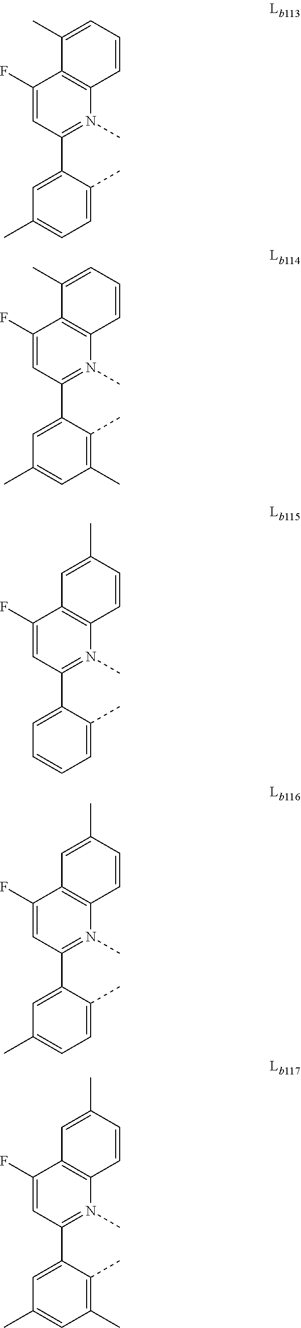

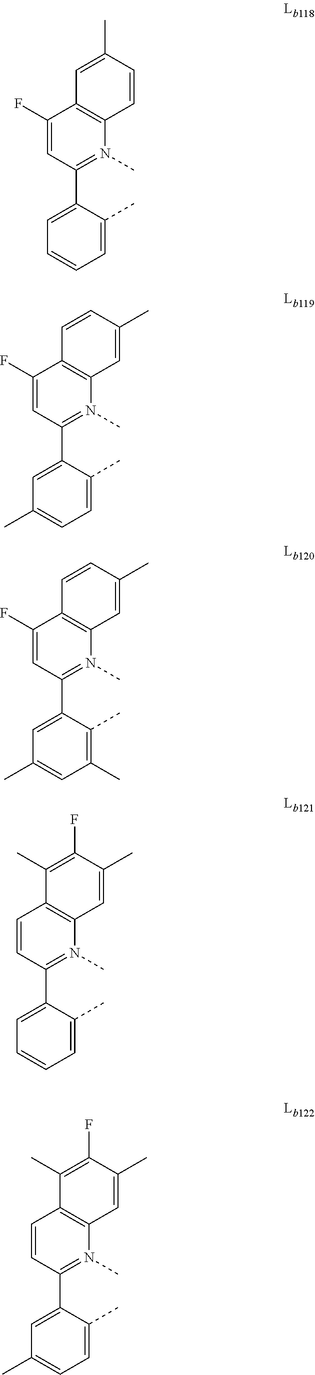

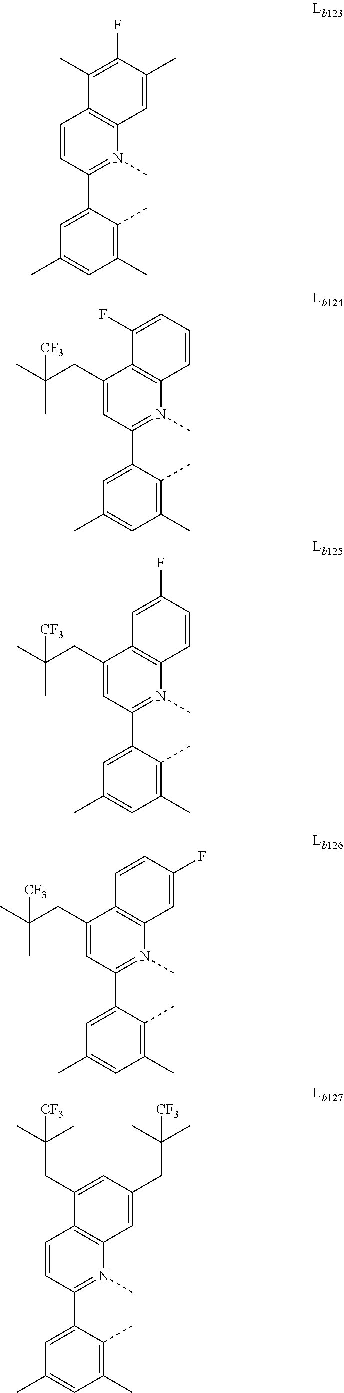

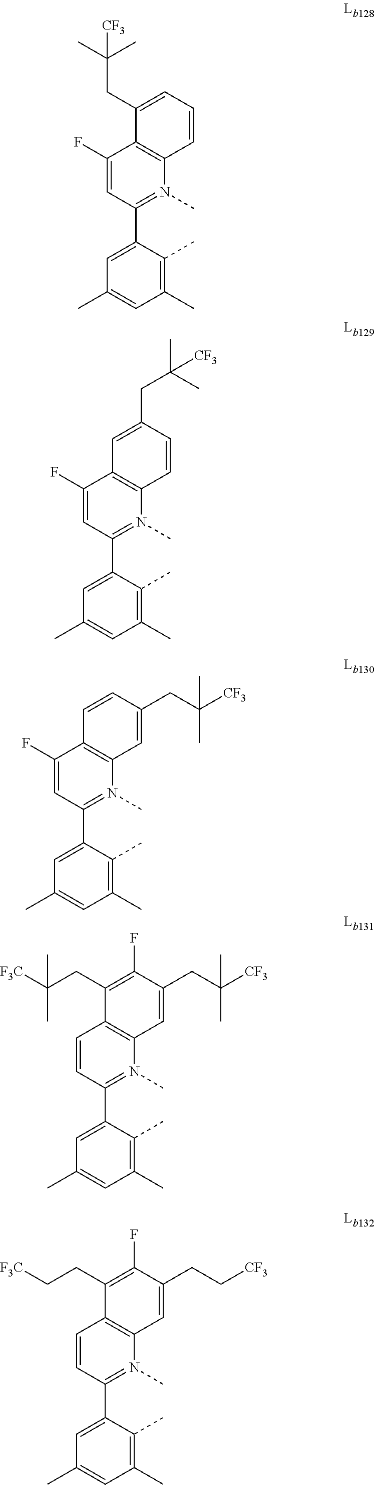

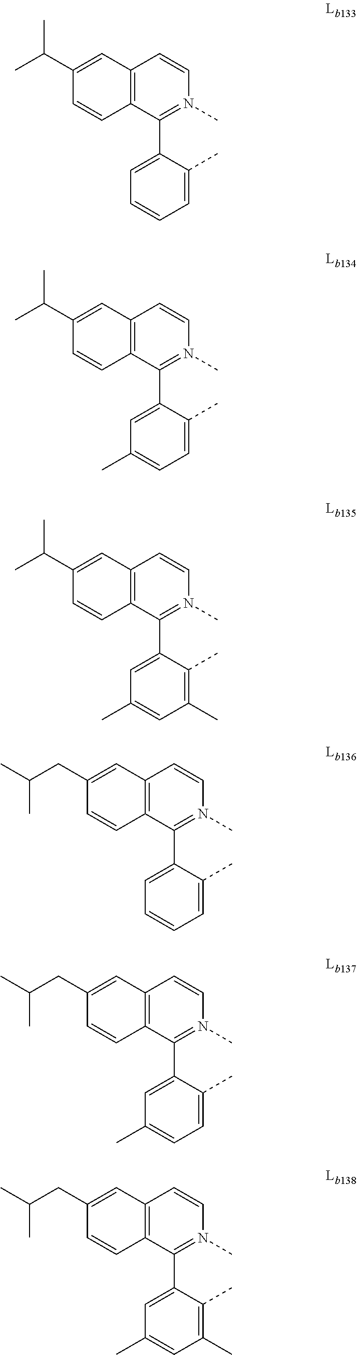

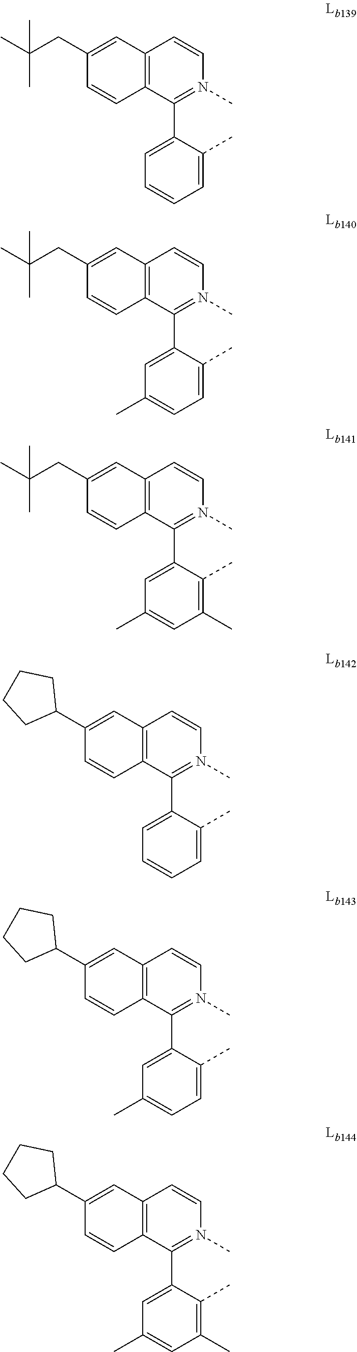

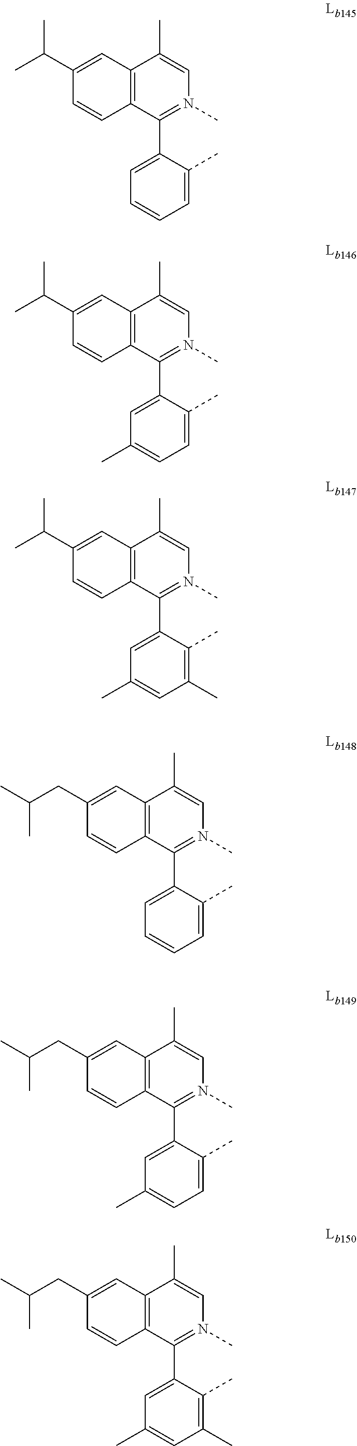

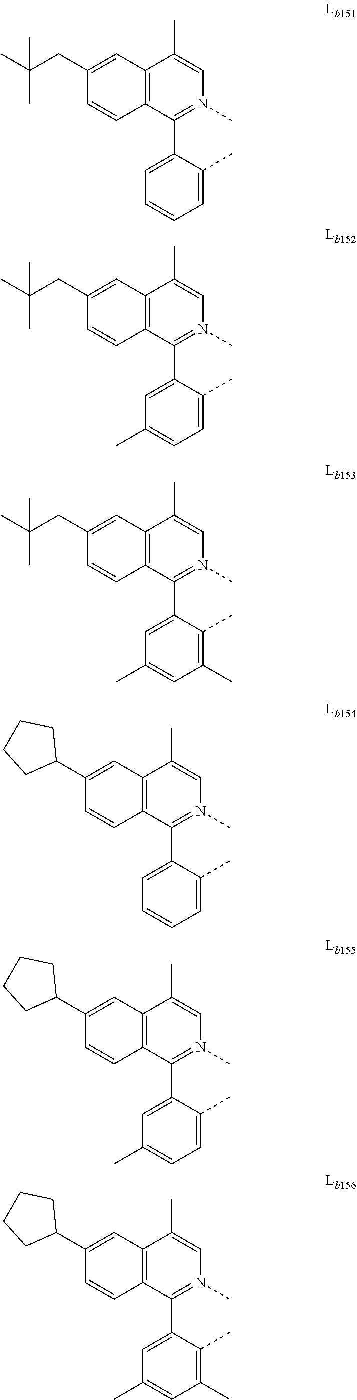

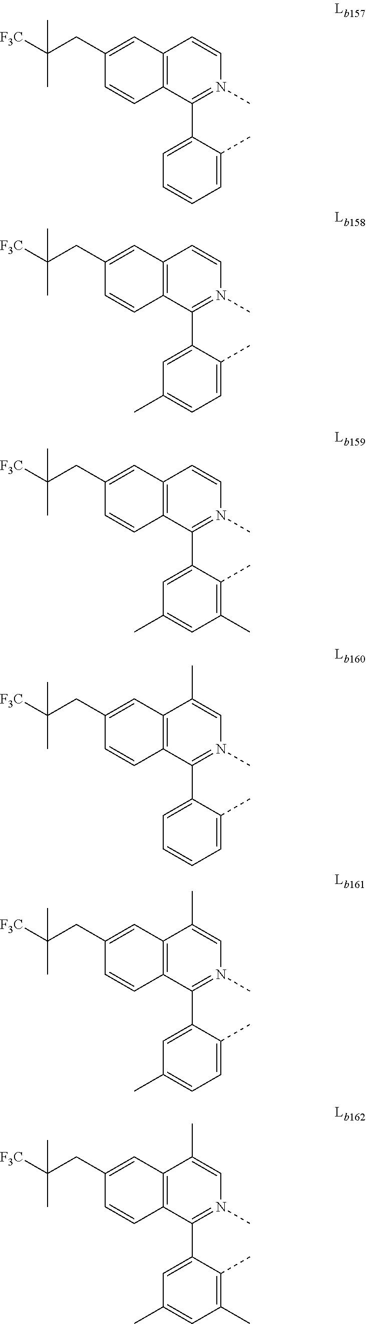

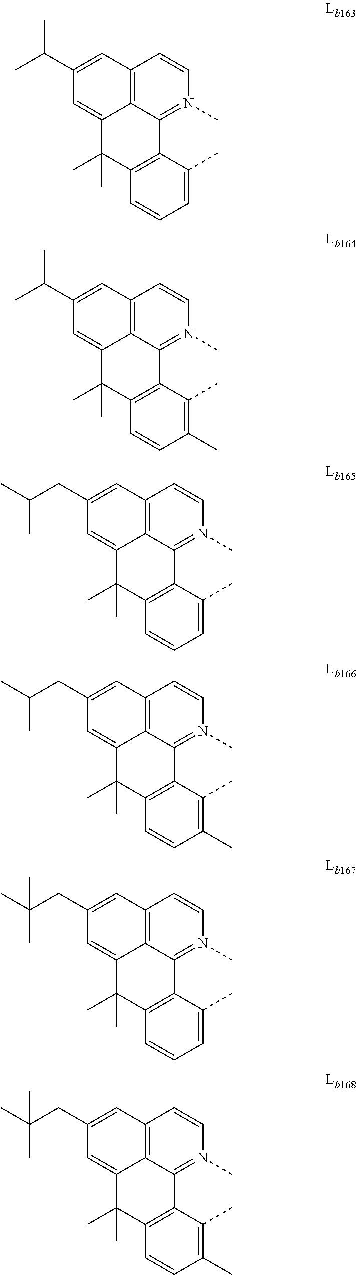

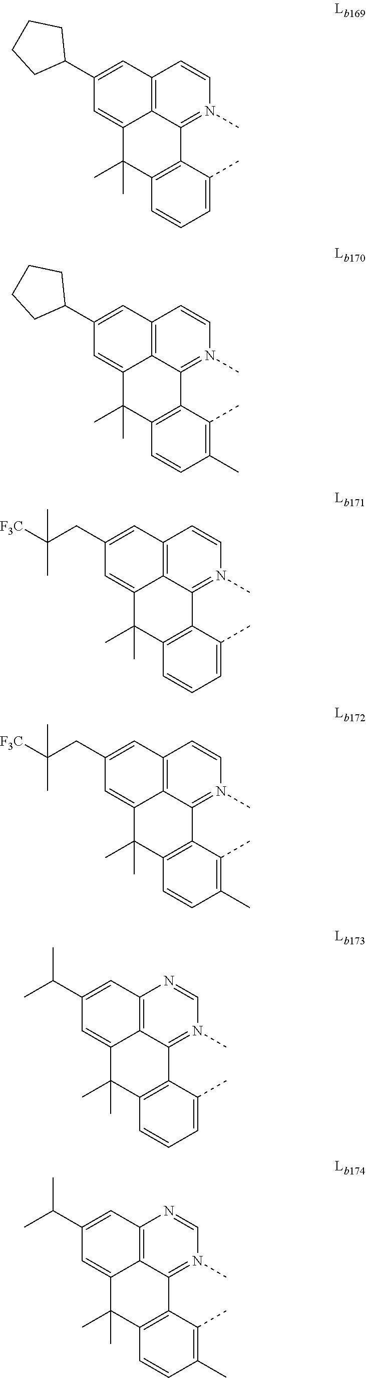

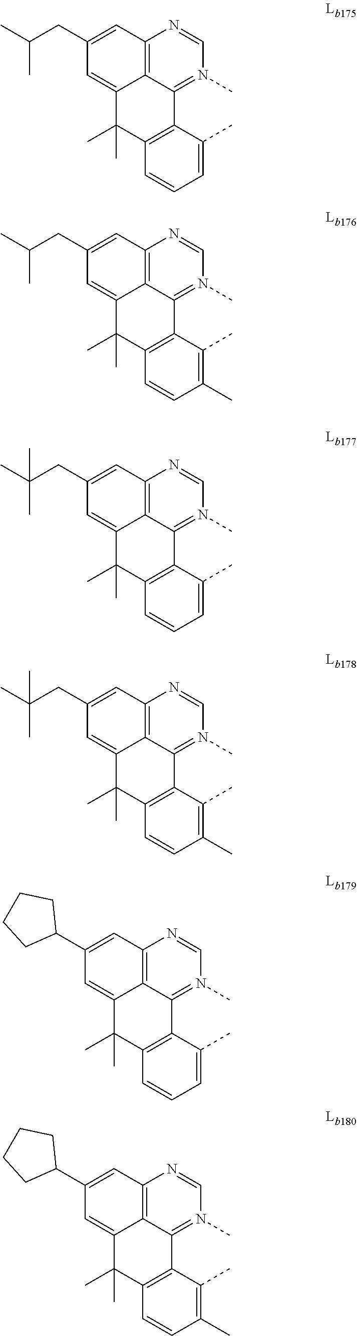

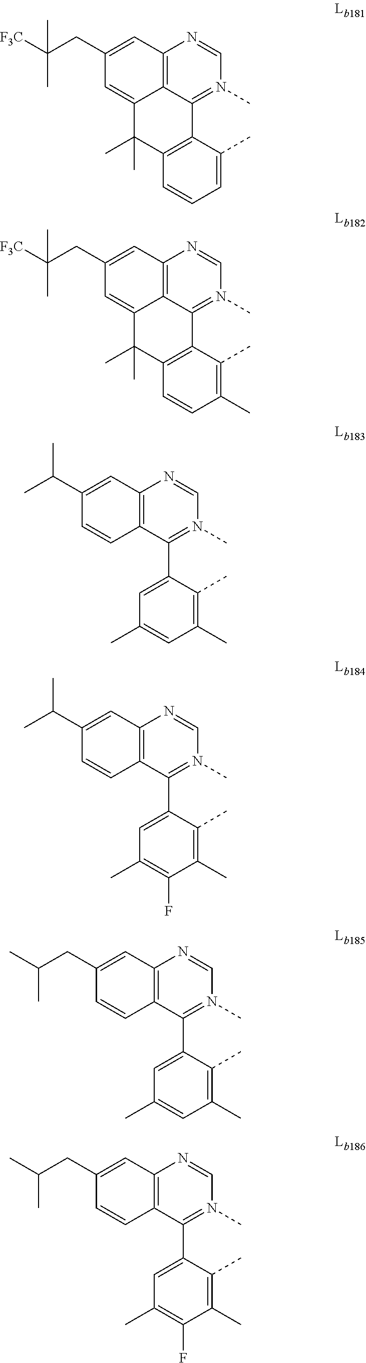

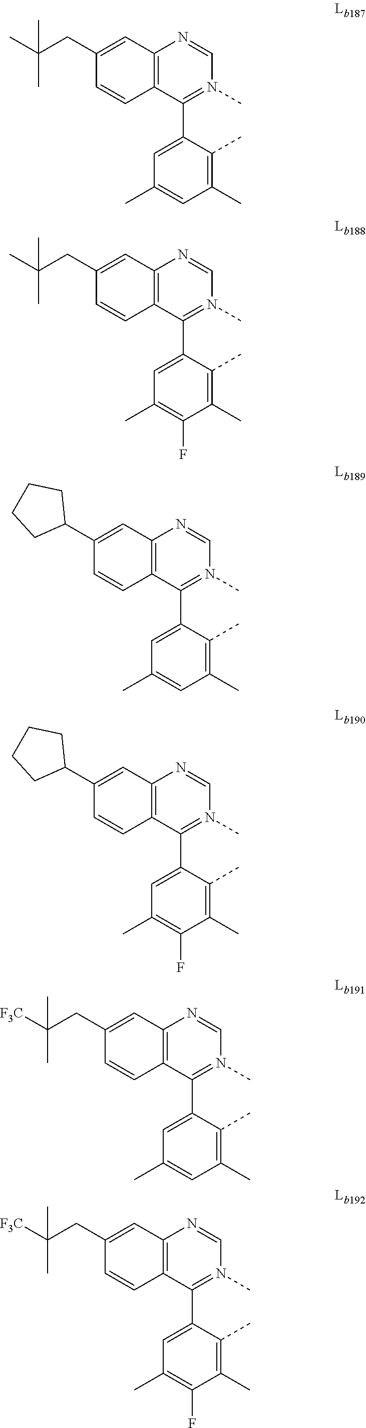

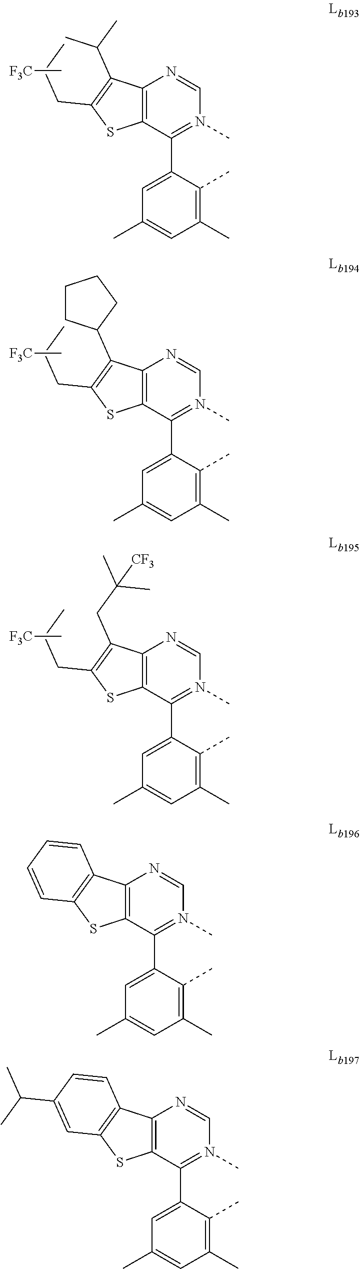

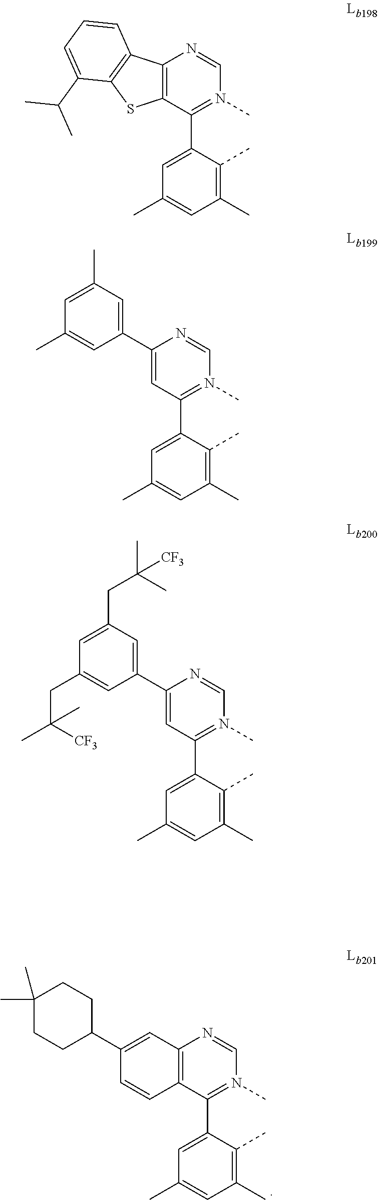

9. The metal complex of claim 5, wherein the ligand Lₐ and L_{b} can be partially or fully deuterated.

10. The metal complex of claim 6, wherein the ligand Lₐ and L_{b} can be partially or fully deuterated.

11. The metal complex of claim 7, wherein the ligand Lₐ and L_{b} can be partially or fully deuterated.

12. The metal complex of claim 8, wherein the ligand Lₐ and L_{b} can be partially or fully deuterated.

13. The metal complex of claim 5, wherein the metal complex has the formula of Ir(Lₐ)(L_{b})₂, wherein Lₐ is selected from anyone of the group consisting of Lₐ₁ to Lₐ₂₈₀, L_{b} is selected from anyone or both of the group consisting of L_{b1} to L_{b201}.

14. An electroluminescent device comprising an anode, a cathode, and an organic layer disposed between the anode and the cathode, wherein the organic layer comprising a metal complex comprising a ligand Lₐ represented by Formula 1: 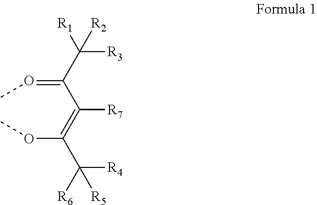
wherein
R₁ to R₇ are each independently selected from the group consisting of hydrogen, deuterium, halogen, a substituted or unsubstituted alkyl group having 1 to 20 carbon atoms, a substituted or unsubstituted cycloalkyl group having 3 to 20 ring carbon atoms, a substituted or unsubstituted heteroalkyl group having 1 to 20 carbon atoms, a substituted or unsubstituted arylalkyl group having 7 to 30 carbon atoms, a substituted or unsubstituted alkoxy group having 1 to 20 carbon atoms, a substituted or unsubstituted aryloxy group having 6 to 30 carbon atoms, a substituted or unsubstituted alkenyl group having 2 to 20 carbon atoms, a substituted or unsubstituted aryl group having 6 to 30 carbon atoms, a substituted or unsubstituted heteroaryl group having 3 to 30 carbon atoms, a substituted or unsubstituted alkylsilyl group having 3 to 20 carbon atoms, a substituted or unsubstituted arylsilyl group having 6 to 20 carbon atoms, a substituted or unsubstituted amino group having 0 to 20 carbon atoms, an acyl group, a carbonyl group, a carboxylic acid group, an ester group, a nitrile group, an isonitrile group, a thiol group, a sulfinyl group, a sulfonyl group, a phosphino group, and combinations thereof;
two adjacent substituents can be optionally joined to form a ring or fused structure;
wherein between the group consisting of R₁, R₂, R₃ and the group consisting of R₄, R₅, R₆, at least one group is three identical or different substituents,
wherein the three identical or different substituents all contain at least one carbon atom,
wherein at least one of the three identical or different substituents contains at least two carbon atoms.

15. The device of claim 14, wherein the organic layer is an emissive layer and the metal complex is an emitter.

16. The device of claim 14, wherein the device emits red light, or the device emits white light.

17. The device of claim 14, wherein the organic layer further comprises a host compound.

18. The device of claim 17, wherein the host compound comprises at least one of the chemical group selected from the group consisting of benzene, biphenyl, pyridine, pyrimidine, triazine, carbazole, azacarbazole, indolocarbazole, dibenzothiophene, azadibenzothiophene, dibenzofuran, azadibenzofuran, dibenzoselenophene, azadibenzoselenophene, triphenylene, azatriphenylene, fluorene, silicon fluorene, naphthalene, quinoline, isoquinoline, quinazoline, quinoxaline, phenanthrene, azaphenanthrene, and combinations thereof.

19. A formulation comprises the metal complex of claim 1.
